(19) United States
(12) Patent Application Publication
(10) Pub. No.: US 2012/0305076 A1
(43) Pub. Date: Dec. 6, 2012

(54) LENS SYSTEMS FOR SOLAR ENERGY SOLUTIONS

(76) Inventor: Tyler Sims, Keizer, OR (US)

(21) Appl. No.: 13/323,470

(22) Filed: Dec. 12, 2011

Related U.S. Application Data
(63) Continuation-in-part of application No. 12/454,542, filed on May 19, 2009.
(60) Provisional application No. 61/128,113, filed on May 19, 2008.

(51) Int. Cl. H01L 31/0232

(52) U.S. Cl. 136/259

(57) ABSTRACT

An integrated solar lens and lens system that may be active, a hybrid, or a self-powered system. A solar lens is fabricated and configured to concentrate received solar energy onto a solar sensor material, whereby a medium is provided between the lens and the solar sensor material, such as a fluid and a fluid including micro or nano components including transparent microemulsion balls, and ionized particles. Such balls and particles improve the transducing of the solar energy to heat, and which heated fluid can be circulated throughout a system.

### CLAIM OF PRIORITY

This application is a continuation-in-part of U.S. patent application Ser. No. 12/454,542 filed May 19, 2009 entitled LENS SYSTEMS FOR SOLAR ENERGY SOLUTIONS, which claims priority of U.S. Provisional Application Ser. No. 61/128,113 filed May 19, 2008 entitled FULLY INTEGRATED LIGHT VALVE the teachings of which are included herein.

### FIELD OF THE INVENTION

The present invention is generally related to solar cells and systems, and more particularly to solutions for capturing and converting solar energy, and circulation of such collected energy.

### BACKGROUND OF THE INVENTION

Solar energy is typically collected by solar cells, which solar cells operate as a transducer to convert solar energy into electricity, heat, or some other energy medium. For instance, solar cells may comprise of p-n semiconductor junctions which are configured to emit electrons as electrical energy when bombarded with solar energy. This electrical energy is in the form of electrical current, and is conventionally accumulated in battery cells to store such created energy.

Over the years, a variety of solar cell technologies have been designed with the goal of providing a low cost, highly efficient mechanism that is practical for use in a variety of applications. Some would argue the near term goal is to meet the performance level of producing one Watt of energy for every dollar of solar cell material, commonly referenced to as the buck-a-watt goal.

One such known solar technology developed in the 1990's is the spheral solar cell technology developed by Texas Instruments Corporation of Dallas, Tex. An array of silicon spheral balls were created and doped to create a plurality of p-n junction cells arranged in an array, resembling an egg crate structure. These solid spheral balls were typically comprised of fused silicon powder or particles, doped and etched to create a p-n junction.

Other solar cell solutions include solar ribbons, such as those developed by Seimens Corporation.

There is a continued need to achieve more efficient solar energy transducers at an affordable cost.

### SUMMARY OF INVENTION

The present invention achieves technical advantages as an integrated solar lens and lens system that may be passive, active, a hybrid, or a self-powered system. A solar lens is fabricated and configured to absorb energy within the structure of the lense, and concentrate received solar energy, such as onto a solar sensor material, whereby a medium is provided between the lens and the solar sensor material, such as a fluid or solid that may contain micro or nano components including transparent microemulsion balls, and ionized particles. Such balls and particles improve the transducing of the solar energy to heat or charge solutions, and which heated or charged fluid can be efficiently circulated throughout a system.

### BRIEF DESCRIPTION OF THE DRAWINGS

FIG. 1 depicts a diagram of a fluid-filled lens configured to direct received solar energy to a solar sensor material;

FIG. 2-7 show a method forming a lens using molds;

FIG. 8 is a first design showing the lens of FIG. 7 including a first absorption layer plus dichroic layer created on the lens, and a second absorption layer below the sensor;

FIG. 9 is a second design showing the lens of FIG. 9 including a first absorption layer and an antireflective layer created on the lens, along with a second absorption layer below the sensor;

FIG. 10 shows a third design including a first absorption and or transparent layer and a reflective layer formed upon the lens of FIG. 7;

FIGS. 11-13 shows a top down orientation option for the lens of FIG. 10;

FIG. 14 shows an integrated lense, fluid and electrostatic stage systems into an active scanning example;

FIG. 70-75, 82-86 show a stage system with a fixed set of offset electrodes that when a voltage is applied will move them into alignment thus move the gimbal and tilt the lense towards or away from the powered side of alignment given the bias difference between the top and bottom electrodes. The top side of the electrode is powered when sunlight hits a diode layer. The bottom side can float, be attached to ground, or have a DC offset bias place on it. In active driven scan systems the electrodes can have waveforms placed across them to quickly move the system and do raster scanning to minimize heat and beam steer the light to a larger active surface area or 3d beam steering. Besides the electrodes the gimbals to the lense have miniature solar cells elements that allow sunlight to strike and charge them. These electrodes can follow the gimbal and stage for the lense frame or can be attached to the transparent flexible substrate allowing for greater surface area. With either solution as the sun rises it hits one side of the lense charging up these electrodes on the closest side. The farthest side from the lense is “shaded” by the lense which pulls the light down in the system. As the sun comes over head both sides charge and the system is aligned to its rest position. Then as the sun crosses in the evening the far side of the lense is “shadowed” and the gimbaling pulls the lense toward the past noon sun side. This misbalance of charge allows for the lense to “track” the sun without any outside input. This allows for self-tracking with the sun with this gimbaled lense design. If needed mirrored standoffs can be shaped around the sensor below the lenses to reflect the off angled steered light back to the center sense else that light can be moved to additional sensors, fluid charging, heating, etc.

FIGS. 15-69, 76-81, 87-94 depict additional preferred embodiments of the invention.

FIGS. 95A-135 depicts additional preferred embodiments of the invention.

FIG. 95B shows a cross pole design in which the lenses are framed by a metallic hollow tube. This allows for connection to the positive and negative terminals of the device without interference with the surface without shadowing. Cells, layers, fibers, or strips of transducing material can be put on the substrate in this design. Reducing material usage, cost and improving cell performance given the full use of the material for absorption given the thinner layers and the reduced path length through the substrate for connections. In addition UV to VIS range solar cell layers are present on the top and or bottom of the design optionally for enhancement of absorption in that range. As noted a mirrored surface can be placed on the bottom of the tube with a nanotextured and reflective coating or a 2^{nd} lense port for external trough like mirrored reflections of the light in two directions within the cross pole.

FIG. 95C shows a textured design that allows nanotubes, nanofibers/microwires of transducing material to be rolled into the substrate notches. Planarizing materials such as cyclotene from Dow Chemical are used as a dielectric example and Zinc Tin oxide and ITO materials are used as electrode connecting and window covering materials with Aluminum and or similar metals in non-light blocking areas to reduce the resistance of the electrodes. The lenses and the aluminum are intentionally layed out to guide the light to the sides of the semiconducting material beside the electrodes as well as the top of the material to increase charge output. The semiconductor materials are tongue and groove connected with the nonconductive holders to allow for easy assembly and planarization. Metals are used as a back reflector or a lense replaces the backreflector and antireflective coatings are placed on the lense with nano-moth like antireflective structures to trap the light from the two axis of entry into the guide.

FIG. 95D shows a multi junction based cell design based on the designs of FIG. 95C for a non-tube bases shape such as a multi leveled trapezoid tongue and grooved design. In this design the trapezoid allows for maximum packing density and 6 jcn devices to be built in the design.

FIG. 95E shows a waveguide design in which light is guided from the top or bottom or both (reflected or transmitted through the bottom of the tube back up into the tube). Additional nanotexturing with moth eye structures is put in to reduce reflections. On the top and or the bottom UV/VIS sensor is put in place to maximize the recovery of this energy. The tubes can be either designed for the diameter for only a certain wavelength range or via the material, or both options can be used. These tubes are built for having maximum efficiency in a particular wavelength range. The tubes can be used to absorb all the same range or as in this case absorb different wavelengths of light for different tubes. These tubes do not have to be nanotubes but can be microtubes, or woven microcords, given the waveguide constraints for the 300 nm to 2500 nm solar window. A lower index and transparent material is put around the tubes in the guide. Surrounding this guide is the metal top or bottom electrode for the tubes. On either side of these tubes will be transparent electrodes for electrical connection of those cells in the tube and on the UV/VIS's bottom electrodes.

FIG. 96 shows an are lense design in which three solar cell lenses are stacked within each other to maximize the absorption energy that is collected through the set. Each lense has a particular wavelength range that its best suited to absorb. Each lense has back and front nanotexturing to grade the index on the lense to air, or lense to lense interfaces thus reducing reflections. In addition resins (cyclotene from Dow Chemical), adhesives (silicones from Dow coming), or direct bonding can be done between layers to prevent reflections. In addition flexible substrates that can be cured can be attached in place in a flat design and then inflated or pulled upwards to a domed shape and cured in place. Given the dome shape the maximum angle for nanotexturing will be below the point for light to diffract off and the maximum transmission will occur through the multiple stacked lense design. In addition diffuse light and tracking system needs will be much or not at all needed in this design.

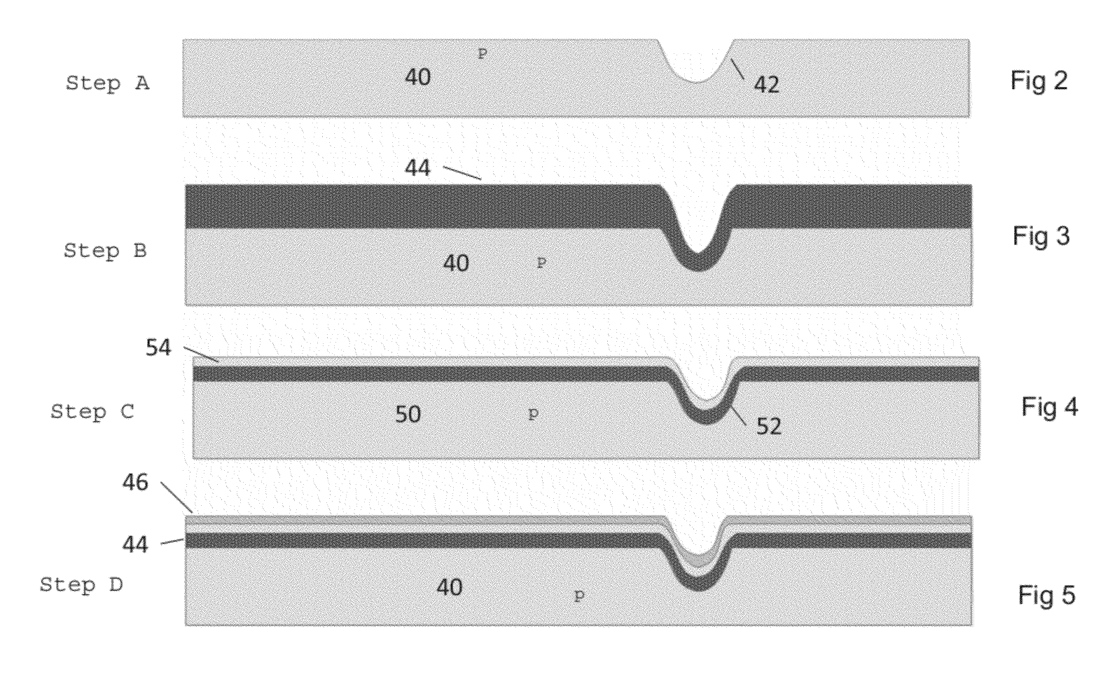

FIG. 97 shows the design in FIG. 2 where each layer will have a lense (dome or other shape with nanotexturing) between it and the bottom layer of the previous structure and the next transducing materials. At the bottom of this repeated stacking will be a space for liquid/nanoshells to be flown through the system and cavity.

FIG. 98 shows the design in FIG. 2 except in this design each layer will only be connected by a direct bond or a thin connecting layer and only one lense will be on the top and or not shown an addition lense could be put on the bottom of the stacked solar cells. Liquid/nanoshells will be flown under this stack.

FIG. 99 is a representation of the perceived design for FIG. 4 for three solar cell layers (multiple junctions possible per layer)

FIG. 100 shows a representation of the perceived design for FIG. 5 for three solar cell layers (multiple junctions possible per layer)

FIG. 101 shows a cone or parabola like structure between the lenses of the previous figures. These transparent cones purpose is to deflect materials from hitting the lenses and from dust and or water touching the surfaces. These standoffs are not drawn to scale and can be beside the lenses or between microlenses on each of the lenses. Each of these designs can be active, passive or a hybrid and the outer skins can be crystalline junctions instead of a lense. In addition the outer surface of the entire cells can be a transparent environmental strong surface in which the lense bond to or stand or revolve within allowing beam steering for power and alignment optimization tracking during the day and night usage.

FIG. 102 shows a biological ommatidum design in nature. The insect's eye has four prominent features. The First is an outer light focusing or collecting lense. The Second a focusing or coupling lense that is graded in material to created light trapping, Third a waveguide to guide and contain the light. Fourth a rhabdomere to transduce the light and a means to collect the charge that is transduced.

FIGS. 104-108 show a means to construct an ommatidum like system. The substrate has holes in it. The top materials is a stretchable and curable material and the lense is attached to the top of this material and or cured in place as part of the stretchable material. When a delta of pressure is placed on either side of the design the structure is stretched upwards creating the design of FIG. 105. Based on this theme, FIGS. 106, 107, and 108 show a method to pre-attached to the base of the waveguide semiconducting materials that will transduce and energy and guide light out the guide and into the substrate attached materials. The waveguide and lense do not have to be made of stretchable material and instead can be preformed into the flexible materials prior to the pressure expansion and cure is done. As seen in FIG. 106, 107 and FIG. 108 prior to this happening the back side connection to the substrate must be removed to allow the film to flex upwards. The platforms designs as listed in FIG. 104-108 can be assembled on a second layer that will allow this layer to be flexed into a dome like shape to mimic the ommatidum on an insect. This will maximize light transmission from dawn to dusk, be ideal for diffuse light and maximize nanostructuring on the lenses for reducing reflections given the grazing angle of light will be much smaller than a flat plate design.

FIG. 109a shows a pizza pie way of stacking one layer or stacked layers, with the same or a different top layer present as you travel the circumference of the transducing layers. On numerous stacked levels within the guide similar substrate materials, or grown layers, of said materials in close proximity to each other and the inner radius will be used to transfer energy out of the guide. This inner radius is the location of the waveguide and the lenses focusing zone for peak light. By nanotexturing the ends of these fingers to match the wavelengths of light they are trying to absorb and optimal transferrance of light and energy will occur. Given the 3d and gap between layers in vertical direction the nature of the structure light will hit all faces of these probes and increase the charging ability greatly beyond a top down design. Given the narrow tips focus on index matching and wavelength matching dimensionally. Optimal transference will occur.

FIG. 109b shows a maximum dome lense packing design for spherical lense. Each edge becomes a hexagon in this packing scheme.

FIG. 109c shows the waveguides with the circumference of the tube covered by absorbing materials of the same (not shown) or different wavelength absorbing materials (shown by different colors of attached materials) The focus point is above the point in the waveguide so that you cannot see in the inner connections within the guide.

FIG. 110A shows a beam of light bouncing within a waveguide based on the principle of total internal reflection (TIR)

FIG. 110B shows a design to pertibate TIR and bring the light from the guide and into the micro/nanoconnections on the guide to create optimal energy transfer and trapping within the waveguide and solar cell transducers along the guide.

FIG. 111 shows a design in which blocks of substrate materials with micro/nanostructures protruding from these different wavelength absorbing designs. The center pillar is the waveguide that this individual blocks will be in contact with or stick their probes within.

FIG. 112 shows a design in which blocks of substrate materials with nanostructures protruding from these different wavelength absorbing designs. The center pillar is the waveguide that this individual blocks will be in contact with or stick their probes within.

FIG. 112-117 shows different construction strategies of FIG. 111's components and similar components.

FIG. 112 shows on one end of the tube a conductive or charge transferring coating with a top guide entrance and side coating between the nanostructures and the side walls of the guide. This will allow for a non-charge transferring waveguide (insulating material) to act as one of the electrodes to the sidewalls of the guides light transducing design. The bottom of the guide in this design is a reflector to keep the light in the guide. Optionally a second bottom lens and an antireflective coating could be used to increase the amount of light into the guide. The outer bulk semiconducting material thus has the second semiconducting contact electrodes coming from it for the 2^{nd} terminal of the device.

FIG. 113 shows a conductive or semiconducting waveguide allowing for two positive transparent electrodes to be placed on top and bottom of the guide. This is done to reduce resistance. The nanostructured features attached within or on the surface of the guide therefore can be a semiconducting material. The junction of these two will allow charge to flow from the guide and out through the outer substrate material and the contact electrode to collect charge, or charge transferring coating with a top guide entrance and side coating between the nanostructures and the side walls of the guide.

FIG. 114 shows FIGS. 112 and 113ths structures and suggests methods to create these structures and tune the bandgap of the structures and the substrate that is attached to them. In addition the doping, implant, QD's, patterning, etching, photolithography, etc. can be used on the waveguide.

FIG. 115 shows FIGS. 112 and 113ths structures and suggests methods to have a stacked layer of junctions of materials to allow for maximum energy transfer per substrate block.

FIG. 116 shows FIG. 112 and FIG. 113ths structures and suggests methods to put the same substrate on all levels of a guide. Else to put as shown in this drawing a block representing the absorption of a certain band of light at each level of the guide.

FIG. 117 shows the design of FIG. 115 from a top down viewpoint. This top down viewpoint would be similar for all the represented designs. The core waveguide shows the path of the light and the electrodes point into the substrate show the location of light escape and energy transference out of the guide.

FIG. 118 shows the design of the proposed thinfilm junction stacks. Noted here Germanium has a strong index match across the spectrum for the stack. In addition there is missing a UV to blue junction that is proposed with the MgZnOS or BeZnOS or BeGaInP systems. In addition a lower cell built on GeSn or GeSiSn is suggested as the film choice for merging with all the designs in the FIG. 118 to 127 systems. Addition Cu2S, In2S3 and other sulfide, Cupric, or indium and nitride systems are considered for the top junction and top window.

FIG. 119 shows the design of the proposed thinfilm junction stacks for a split spectrum or multi exit light path (see FIG. 120-130. A GaAs and InP based stack is suggested to build two different stacks on allowing for independent Nano structuring that cannot be done on one substrate for maximum transmission and light trapping

FIG. 120 shows a nanostructured lightpipe. The outer semisphere lense has the option for a graded lense to increase the magnification/concentration of light into the guides. Light within the bottom core guide is pulled into the side walls by nanostructureing and inserts into the guide as shown in the previous drawings (FIG. 120-130). The exit of the guide allows in this case to focus into a tube with nanoparticles. The guide can be lined with nanotubes/fibers for collecting charge in the system. As the particles are exposed to light they will heat and or collect energy. Cs doped particles can then reemit charged particles and down converting particles can readmitted Red light energy which can be collected on the wall charging the solution and walls.

FIGS. 121-124 are top down versions of FIGS. 124-127. In these designs the guides have both a through transmitting guide and a redirecting multilegged light pipe. FIGS. 121-127 show a nanostructured lightpipe. Different example patterns are explained on each drawing for optimizing pitch/density and processings for integrated solar cells within the pipes themselves or techniques for attaching or bonding in place external solar cells. The skin based solar cells found within the primary patent can't be placed at the top or bottom of these designs.

FIG. 124-127 show cross section views of the possible light paths and light guides/traps. The light paths allow for direct illumination of the film or substrate materials. The light pipes/trapping legs allow for increased absorption for light pipes made of junction materials or multi emitting, reflecting and absorbing structures for increase efficiency of the cells.

FIG. 128-131 show integrated hybrid systems that allow for thermal energy to be collected in FIG. 128-131 in a hybrid storage and or heat system at night at high efficiencies by the retraction of the IR cells into a hot environment. Secondly it allows for the previously fluid charged members to be evacuated and charged to act as buffer for charge transfer the loading that occurs at night.

FIG. 132-135 show integrated hybrid systems that allow for energy to be collected by multiple cells (same or greater spectrum coverage) with minimal loss by optics but with maximum magnification. Multiple thin cells (˜90% output of std cells for efficiency) at low cost can be used in this design thus allowing for greater power output per module node at the same cost of a std single cell. Repeated in this design is the ability for thermal acoustic or other pressure, charge (nanoparticles, fluid, Cs doped particles), etc energy generation and regeneration options.

### DETAILED DESCRIPTION OF THE PREFERRED EMBODIMENTS

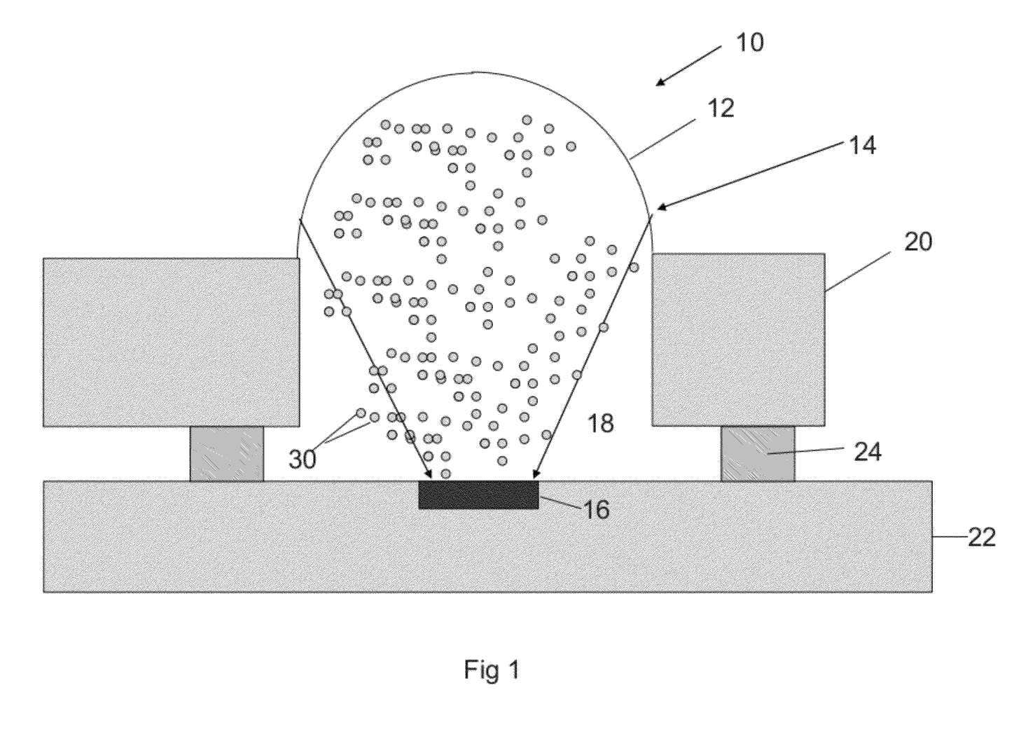

Referring now to FIG. 1, there is generally shown at 10 a solar cell seen to include a spheral lens 12 configured to absorb, direct and/or focus received solar light 14 to a solar sensor material 16. The lens 12 is configured over a chamber 18 formed within a frame 20, this frame 20 being sealed to a substrate 22 via a hermetic seal 24. This chamber 18 is filled with a fluid, or solid, and which fluid, or solid, may include transparent microemulsion balls 30, semiconductor materials, and/or ionized particles. These balls are extremely small, and may have diameters ranging from one micron to one millimeter, although limitations to these dimensions is not to be inferred as nano and micro balls/particles are contemplated, as well the shapes of these particles may not be spherical but oblong, or have other symmetry for a cavity design, and thickness to absorb light, and have a uniform coating, core, or doping around its surface. These balls and/or ionized particles are configured to efficiently transduce light to heat, charge the balls or particles, or both. These balls and particles may also be circulated to transmit heat from the substrate, and through a system. These balls and particles can also be used to create battery-like storage and charge transfer. The charged solution can be circulated to increase the charge in solution and aid in the active surface area that can be drawn from.

The balls or particles 30 may comprise of TiO2 powder, silicon, semiconducting materials, multiband semiconductor balls (i.e. heterojunctions, dopings,), quantum dots, ionic charge particles, or other particles, and may, if desired, have a reflective core or an antireflective coating, such as aluminum, or a graded antireflective coating. Energy not collected in the lenses and its antireflective coating. Ideally the graded coating is preferred to match the liquid/ball filled interior with an index matching filled media, or of a greater index to focus the light with different demagnification to a low cost matched optical focused area sensor at the base of the interior of the system. This sensor can be optional and the entire base can be reflective in the range of wavelengths that are passed through the lense into the media. The same base outside of the sensor should be reflective for the range of light passing through the lense to increase the energy absorption of the particles/balls in the media. The aformentioned types of particles with a greater density offer the ability to tune the lens to liquid index matching. Those particles/balls with a combinational semiconducting nature and ionic nature will allow for a battery charge flow to occur. Those particle/balls solutions with graded or other antireflective coating or reflective cores allow for resonance or charge creation to create heat. This heat in turn heats the liquid medium and creates a flow through the tube to circulate the collected heat to areas where this energy is used to create steam from water.

FIG. 2 shows the first of several steps for forming an integrated solar lens. Of note the photo negative off this process can be used and the substrate flipped upside down so that a solid dome is started with and the interiors removed and coated to look similar to the final single or stacked lense designs. Step A is shown in FIG. 2 and depicts a semispherical shaped mold 40 comprised of a p-layer having a semispherical recess 42. This semispherical recess 42 may be formed by an isotropic etch (such as dry, wet, plasma, ash, etc) into the p-substrate layer 40. This layer 40 may be coated, printed, liftoff deposited, doped, implant/cleave deposited, etc. Optionally, the p-layer can be etched using a non-isotropic process, which can be done for non-semispherical shaped molds.

FIG. 3 depicts Step B which comprises a front side implant or diffusion of n-doped material into the p-type base layer 40 to create an n-layer 44 along the surface of the substrate 40 and along the curved surface 42 as shown. This n-layer prevents release of layers and release of top film. This n-layer 44 can also be used for the multiband base layer that can be doped into the later stack. Optionally a n-layer can be deposited on the surface

Step C depicts an n-substrate 50 with a recess 52, similar to the process shown in FIGS. 2 and 3, whereby a p-layer 54 is formed on top of the n-layer 50 from front side doping or a p-layer deposition process. Optionally, a multiband doping maybe provided to protect from back side release wet etches.

FIG. 5 depicts multiple options and steps that can be performed, these options include:
1) dichroic+transparent top electrical p contact coat.
2) antireflective layer+top p contact coat, antireflective+transparent top p contact, top p contact, antireflective+p contact layer.
3) reflective layer+top p contact electrode, reflective top p contact layer

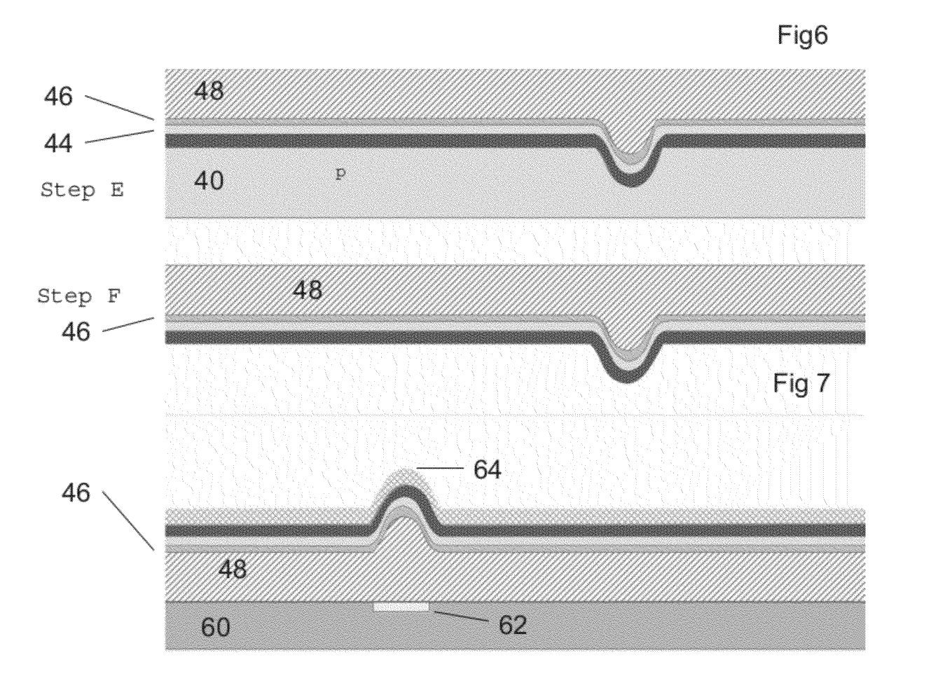

FIG. 6 depicts Step E, whereby after Step D shown in FIG. 5, the mold is filed in for strength with a material, with either a transparent material: polymer/polymide, silicone, resin, a hybrid layer, ceraset, oxide, etc, and then planarized as shown.

FIG. 7 shows Step F where the back side layer 40 layer is released. Thereafter, optional process paths may be performed including:
1) Opt for diffractive circular grating
2) Opt for IR antennas
3) Opt for n-type antireflective or reflective contact layer
4) As applicable, lens can be integrated into arrays, passive, self-powered, and actively powered stages.

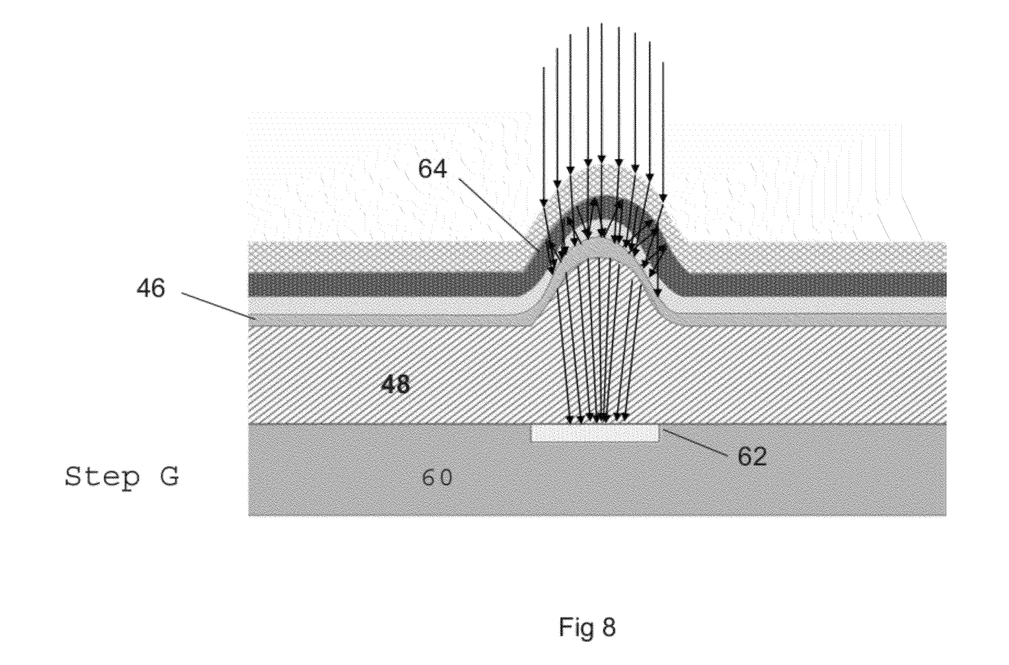

FIG. 8 shows a Step G according to a first design whereby a second sensor layer 60 is attached and includes a sensor 62 positioned proximate a focal point of the lens structure formed and generally shown at 64. An optional transparent top coat may be provided for physical strength and reliability. FIG. 8 shows a first design whereby the resulting structure includes a first absorption layer, a dichroic layer and lens. A second lower cost absorption layer may be provided for tuned wavelengths. As shown in FIG. 8, incident solar light directed on the lens assembly is configured such that a desired colored light is passed, focused and directed through layer 48 onto sensor 62. Non-desired colored light is reflected from the lens structure as shown. Optionally one or several additional lenses can be stacked below each other and within the cavity and recess to increase the light absorption capabilities. The additional stacked lenses can be inserted during Steps D through E.

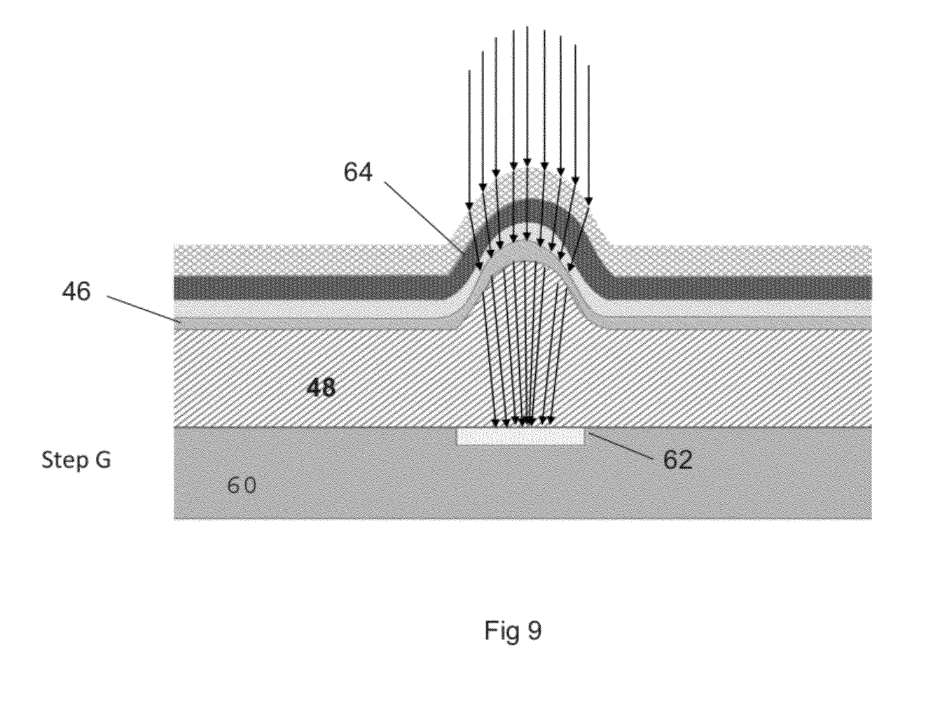

FIG. 9 depicts a second design for Step G whereby the lens structure is provided with a first absorption layer and an antireflective coating upon the lens. In this embodiment the received full spectrum of incident light on the lens structure is allowed to be directed upon sensor 62. Optionally one or several additional lenses can be stacked below each other and within the cavity and recess to increase the light absorption capabilities. The additional stacked lenses can be inserted during Steps D through E.

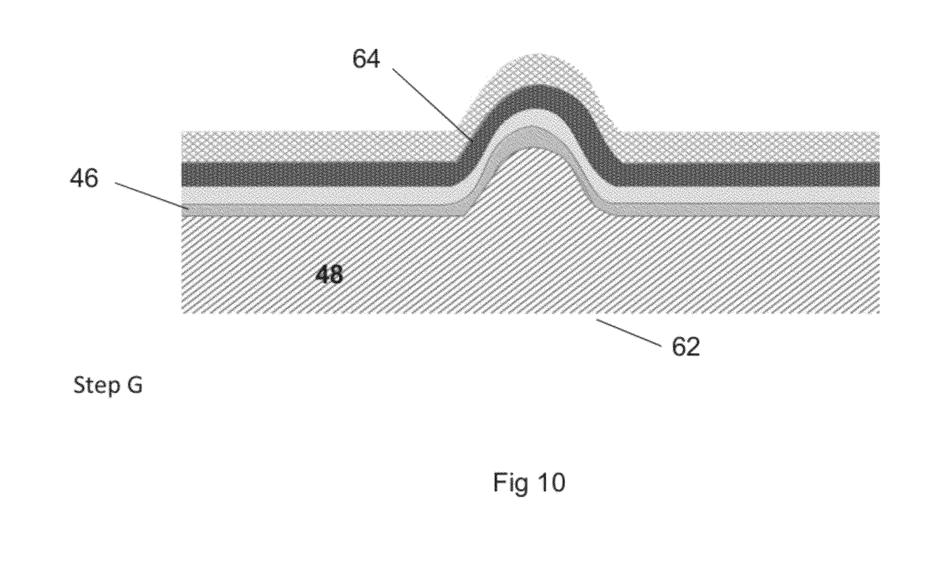

FIG. 10 depicts a third design for Step G, where a first absorption layer and a reflective layer is disposed upon the lens structure. The optional transparent top coat can be applied to all designs for physical strength and reliability if desired. Optionally one or several additional lenses can be stacked below each other and within the cavity and recess to increase the light absorption capabilities. The additional stacked lenses can be inserted during Steps D through E. In this design a reflective layer should only be used on the very top lense or the very bottom lense and the light path should come from the opposite direction of this reflective coating.

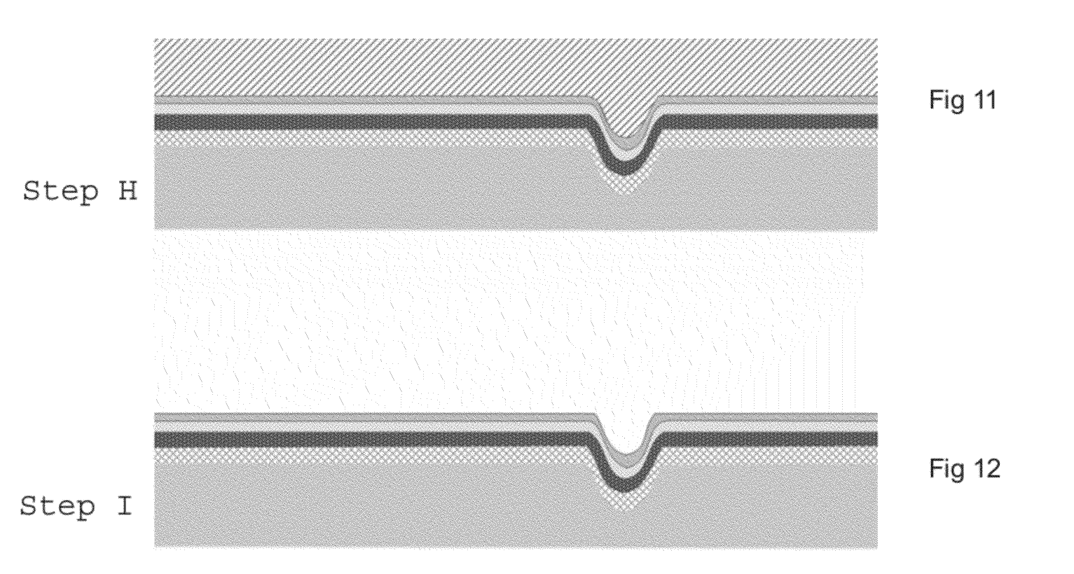

Turning now to FIG. 11-13, there is shown an additional three steps for the first design of FIG. 8 that may be provided in a top down orientation. Shown in FIG. 11 is Step H, whereby a top coat is applied for structural fill and strength to complete the following processing stages.

Shown in Step I in FIG. 12 is selective removal of the material filling the lense cavity. Optionally one or several additional lenses can be stacked below each other and within the cavity and recess to increase the light absorption capabilities. The additional stacked lenses can be inserted during Steps D through E. In this design a reflective layer should only be used on the very top lense or the very bottom lense and the light path should come from the opposite direction of this reflective coating.

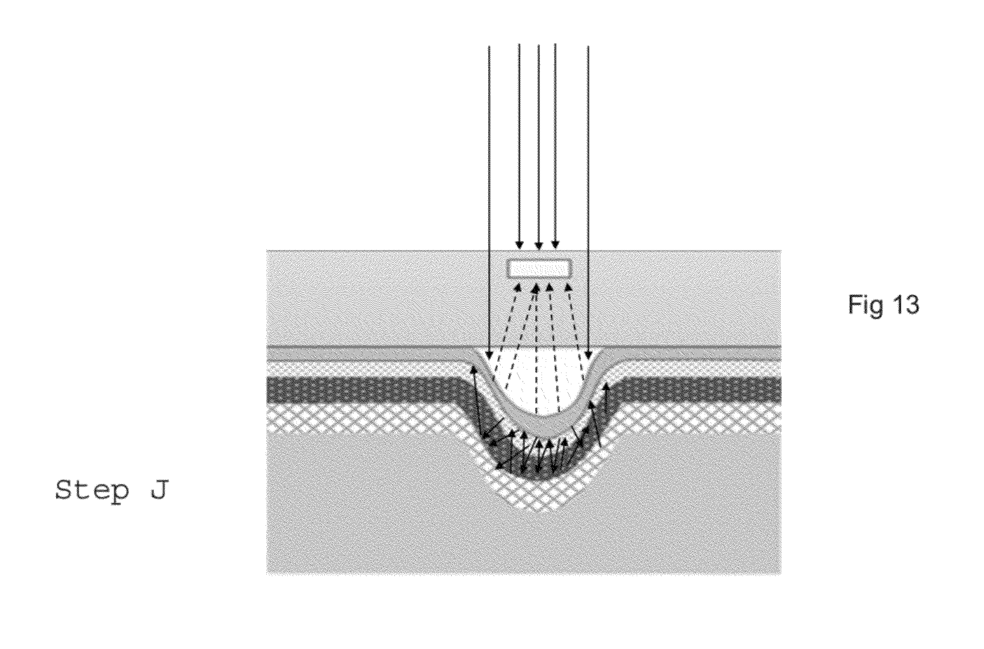

Shown in Step J of FIG. 13 is the completed top down design. The lense is designed and manufactured upside down to the std process. The advantage is to allow a second structurally strong but transparent wafer to be bonded to the lense backing. This wafer will have one or more solar cells attached to it. This thick substrate aids in alignment for the attaching of these two substrates and for hermetic sealing. Not shown in this figure are any additional nanostructured moth eye features, AR coatings, or a spherical lenses, for minimizing reflections and better focusing the light into the cavity. In this scenario the micro lense acts both as a focusing reflector and an absorber of light. A dichroic layer can be placed as the top surface of the reflector design. Additionally the handle wafer offers environmental protection to the system from external weather, integrated into the design. Optionally one or several additional lenses can be stacked below each other and within the cavity and recess to increase the light absorption capabilities. The additional stacked lenses can be inserted during Steps D through E. In this design a reflective layer should only be used on the bottom layer or the very bottom lense and the light path should come from the opposite direction of this reflective coating. But the dichroic(s) can be placed on one or many between solar cell interfaces.

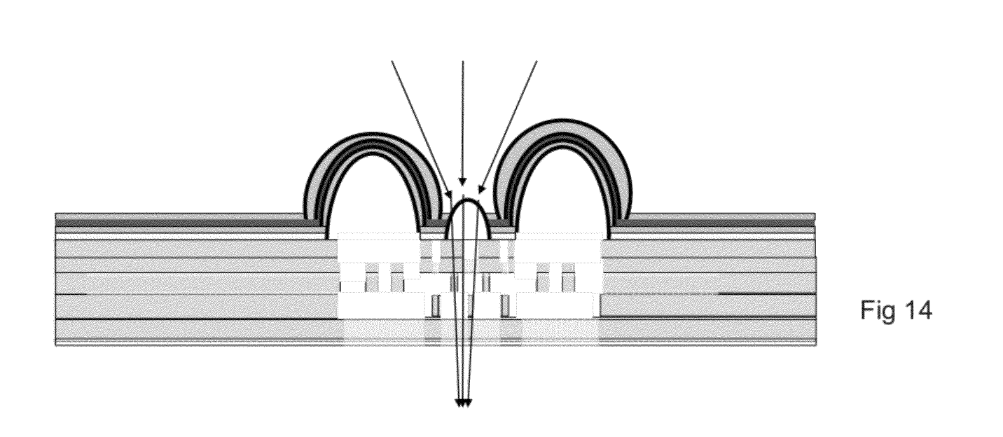

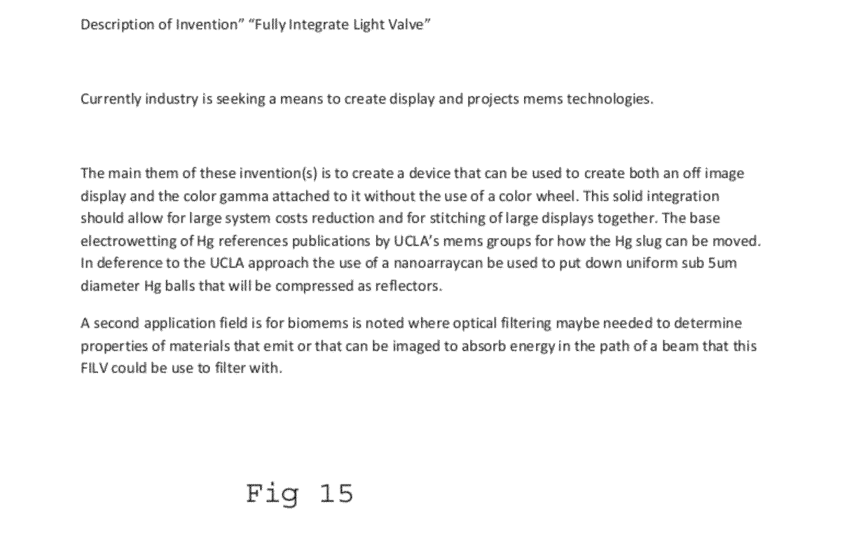

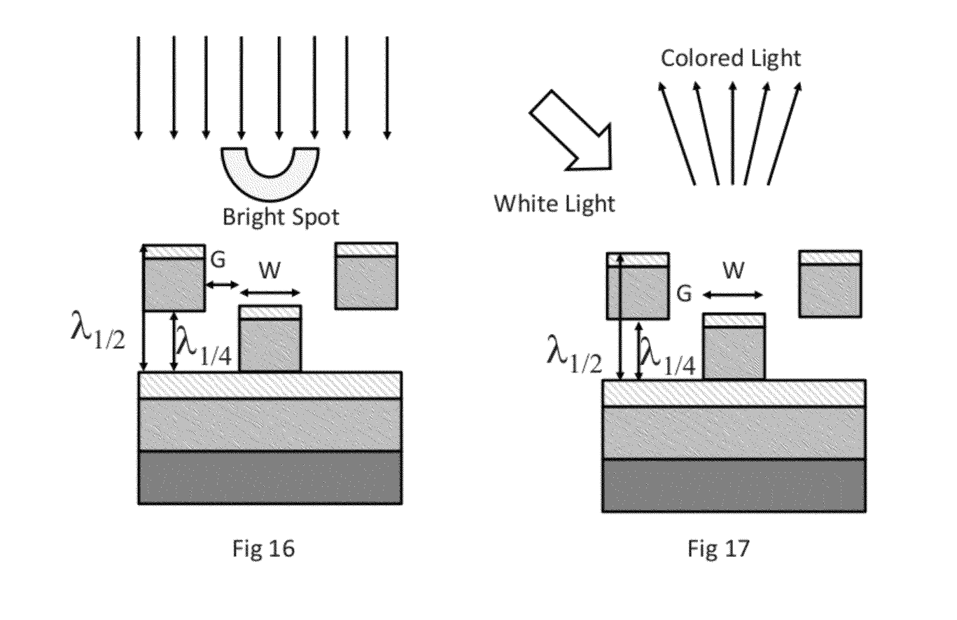

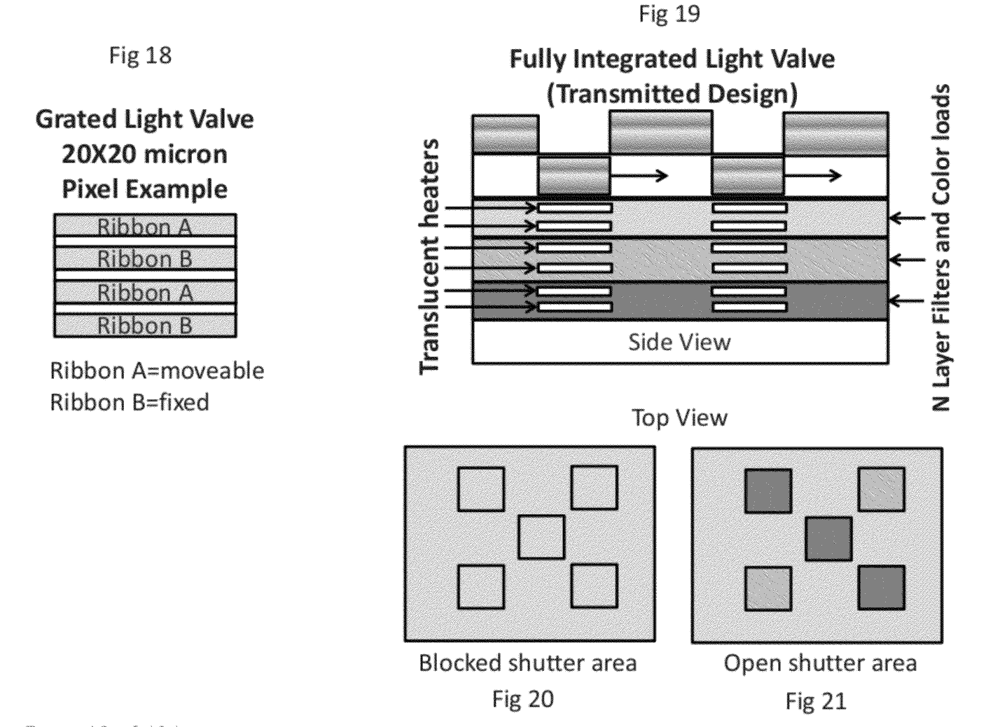

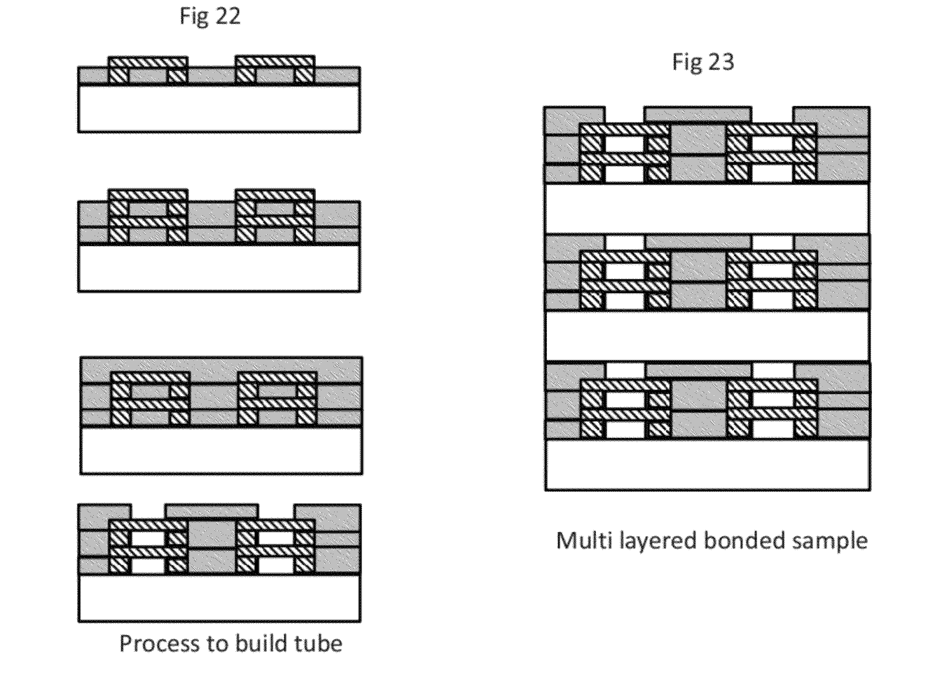

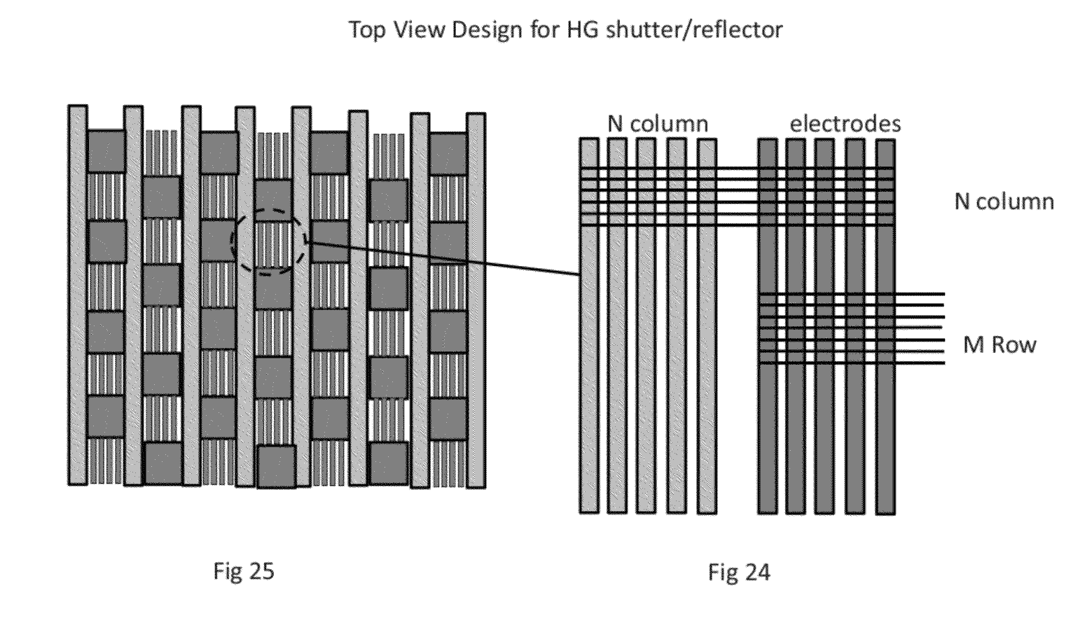

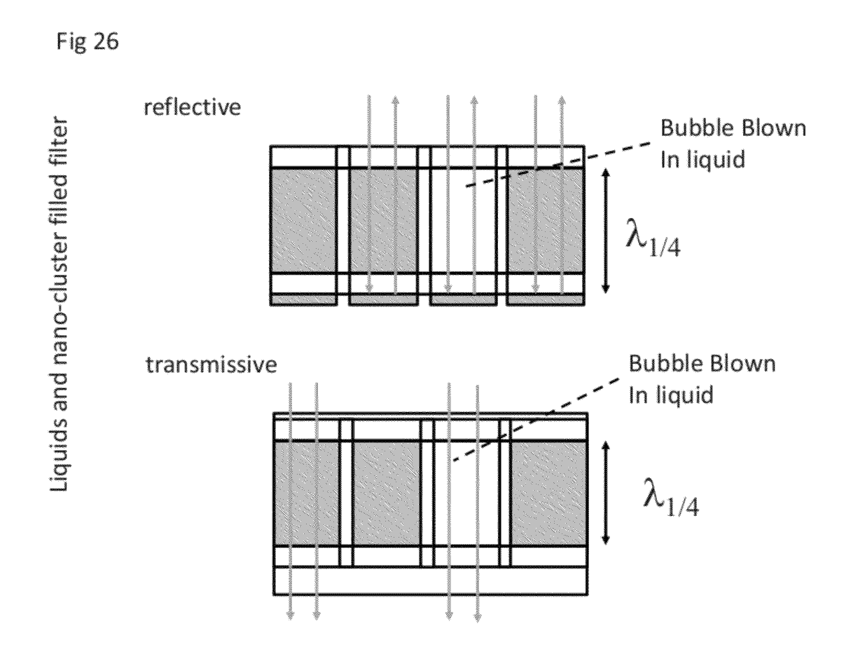

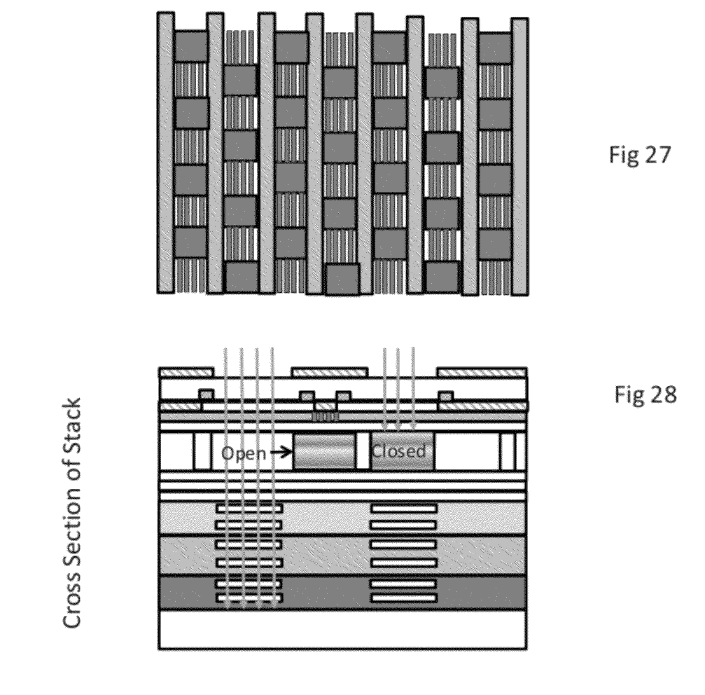

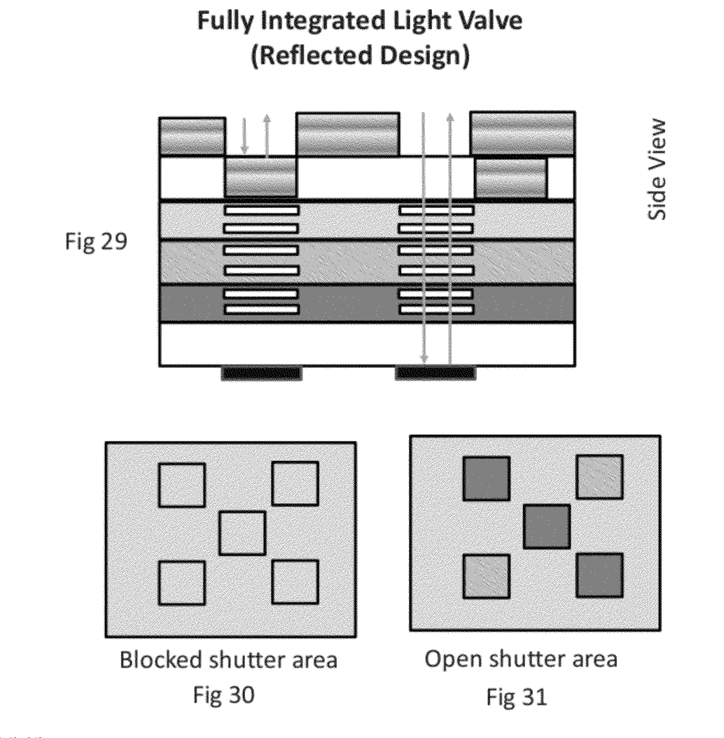

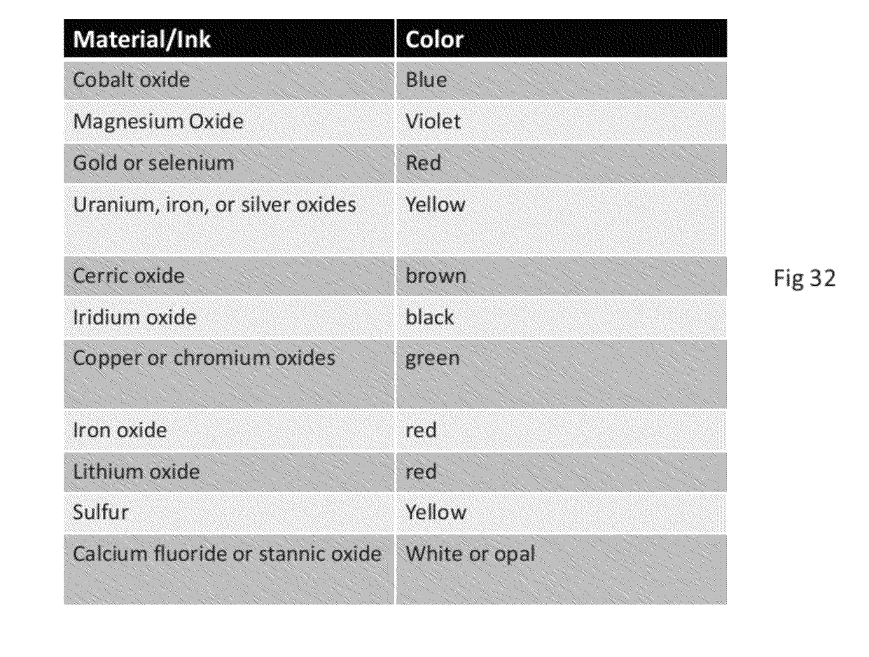

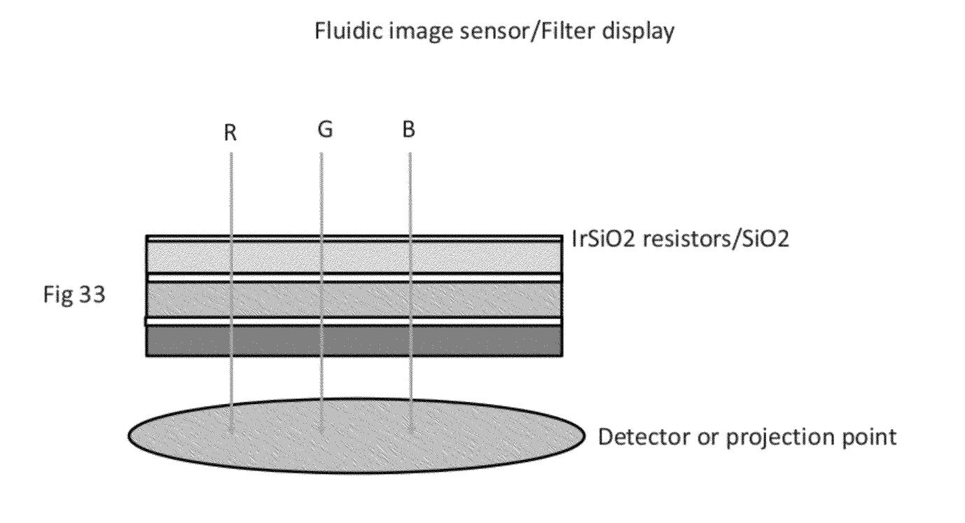

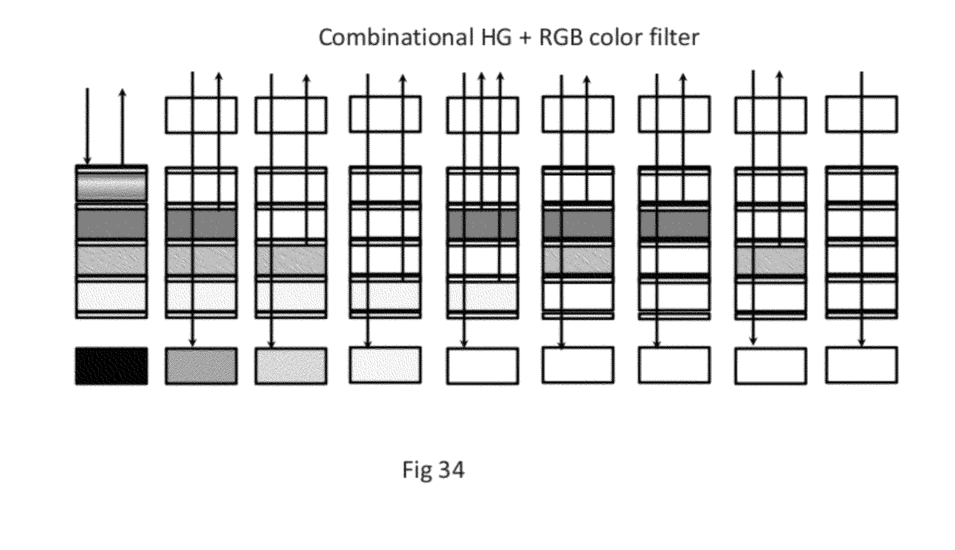

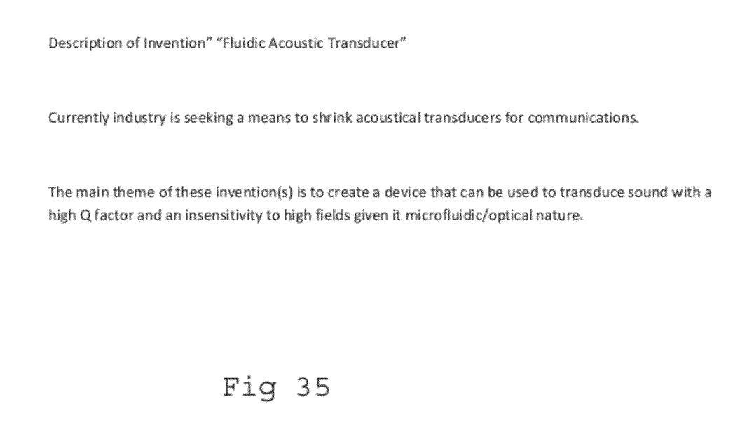

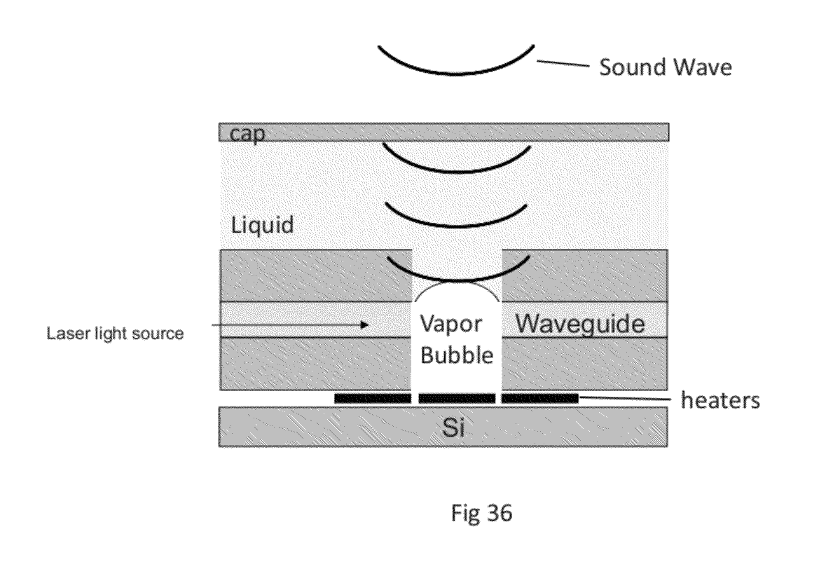

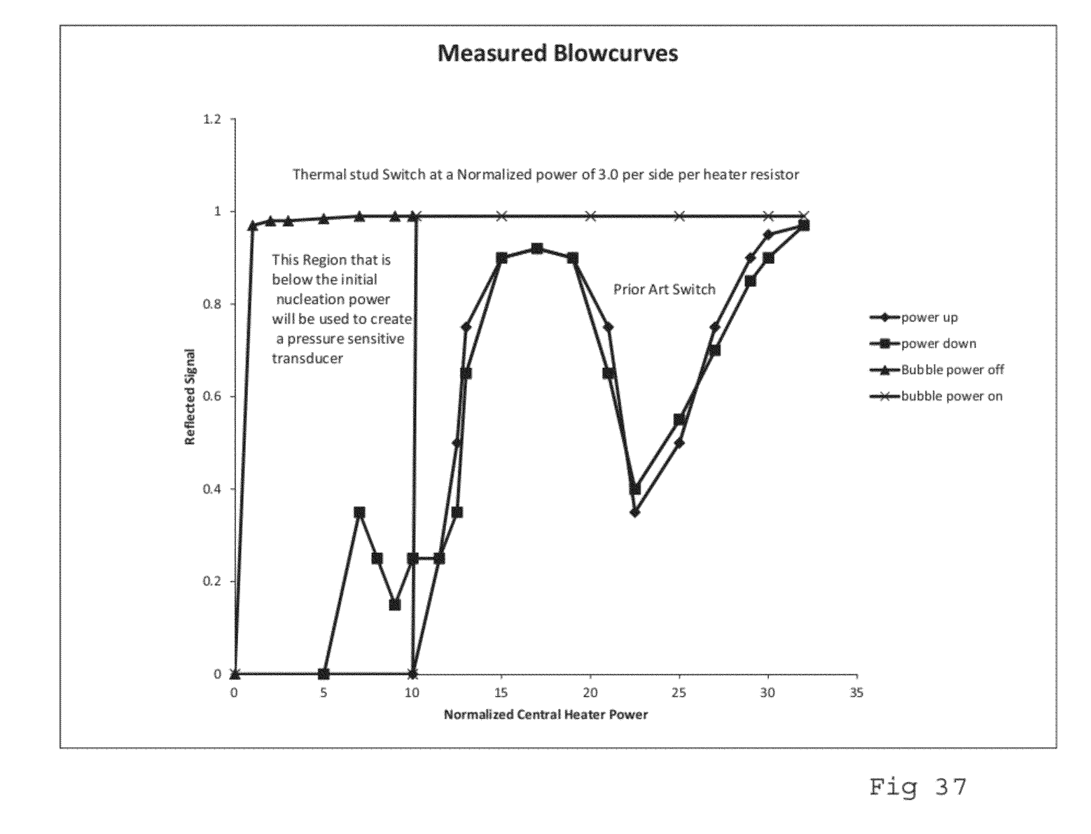

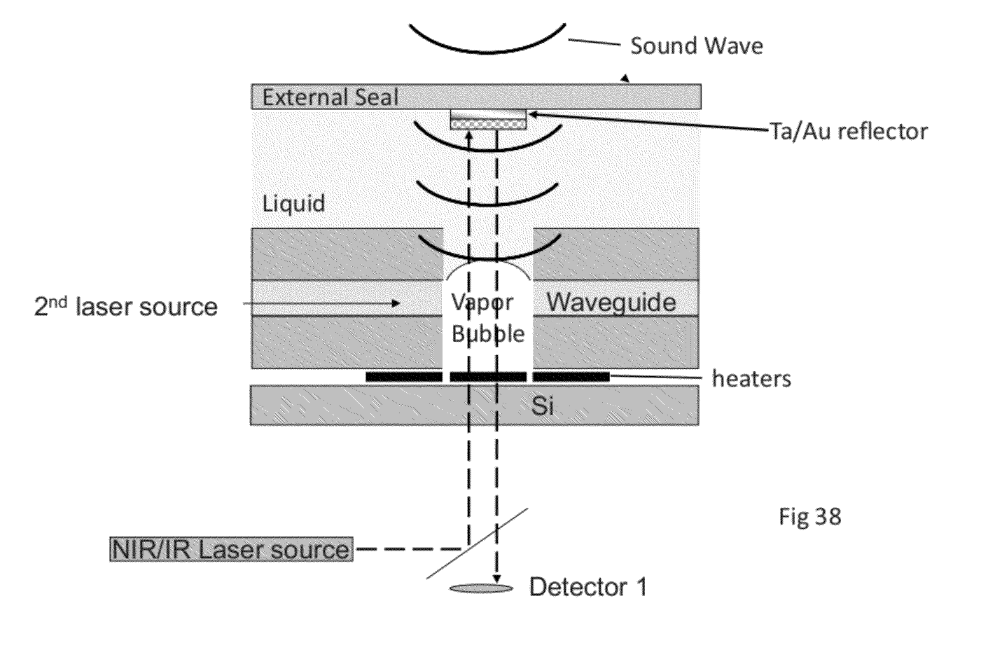

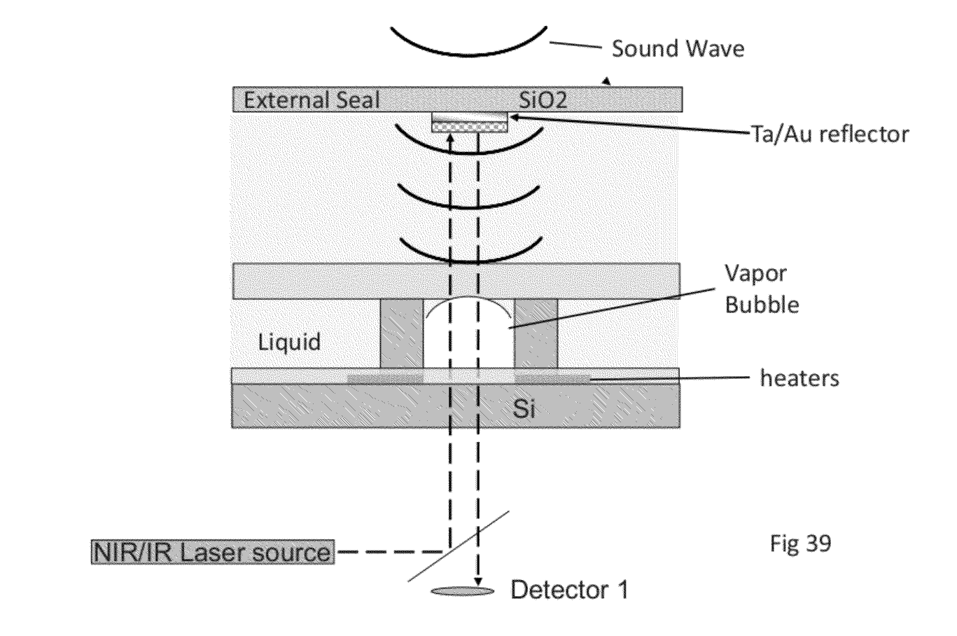

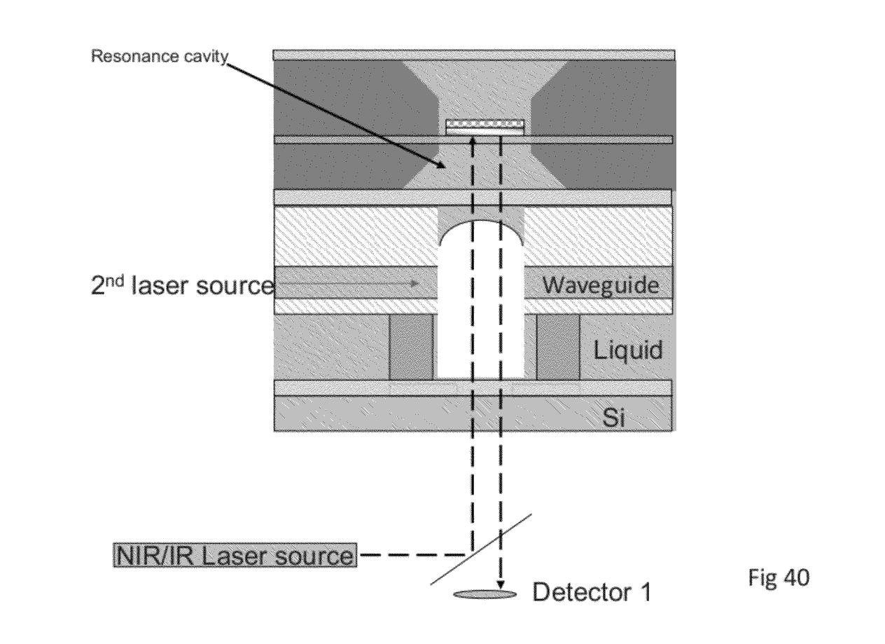

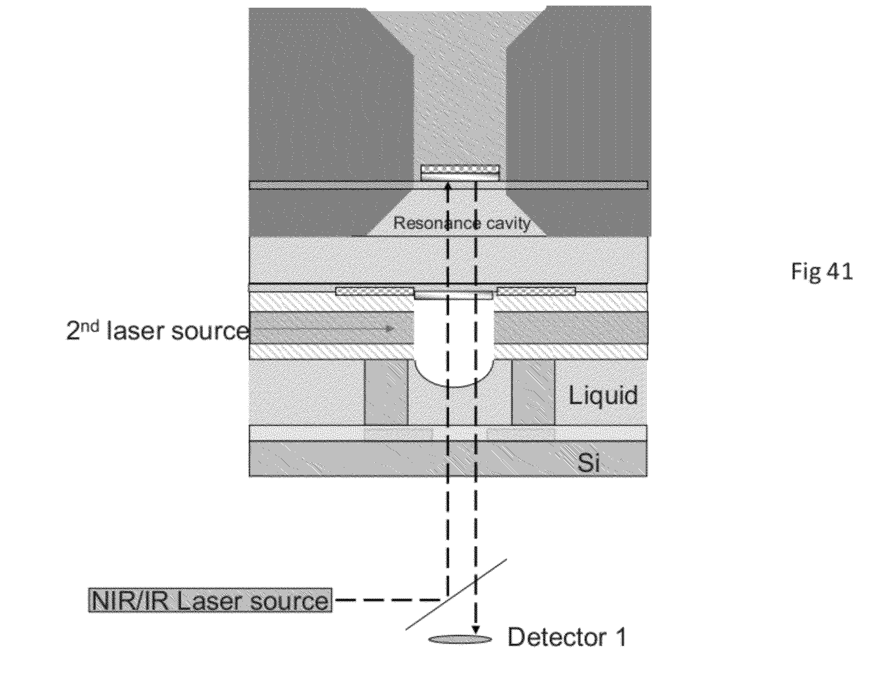

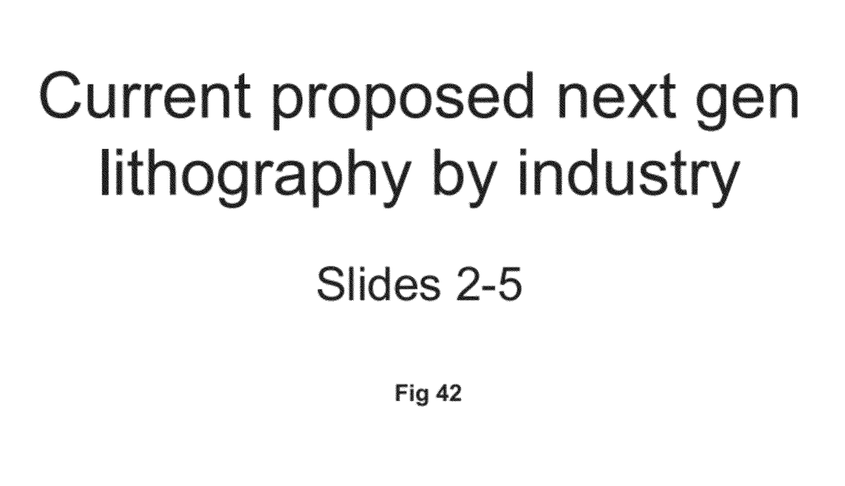

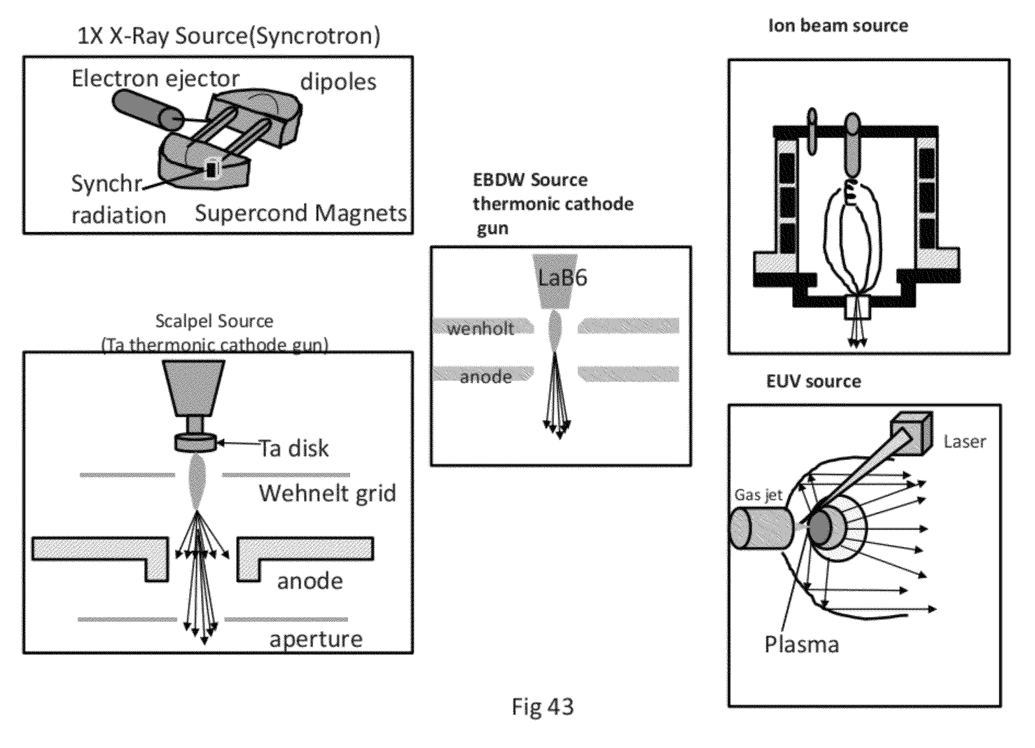

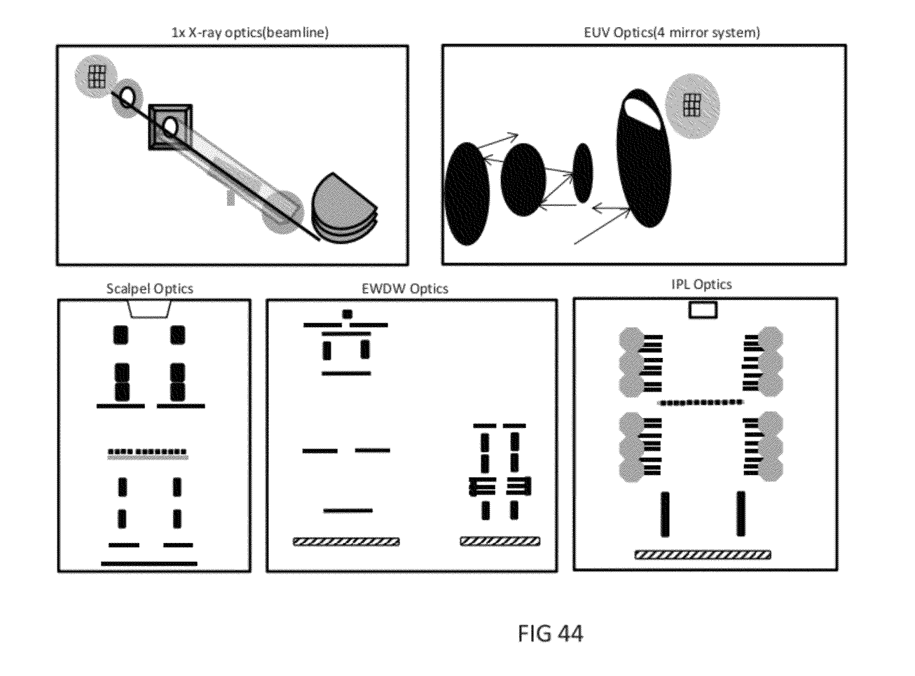

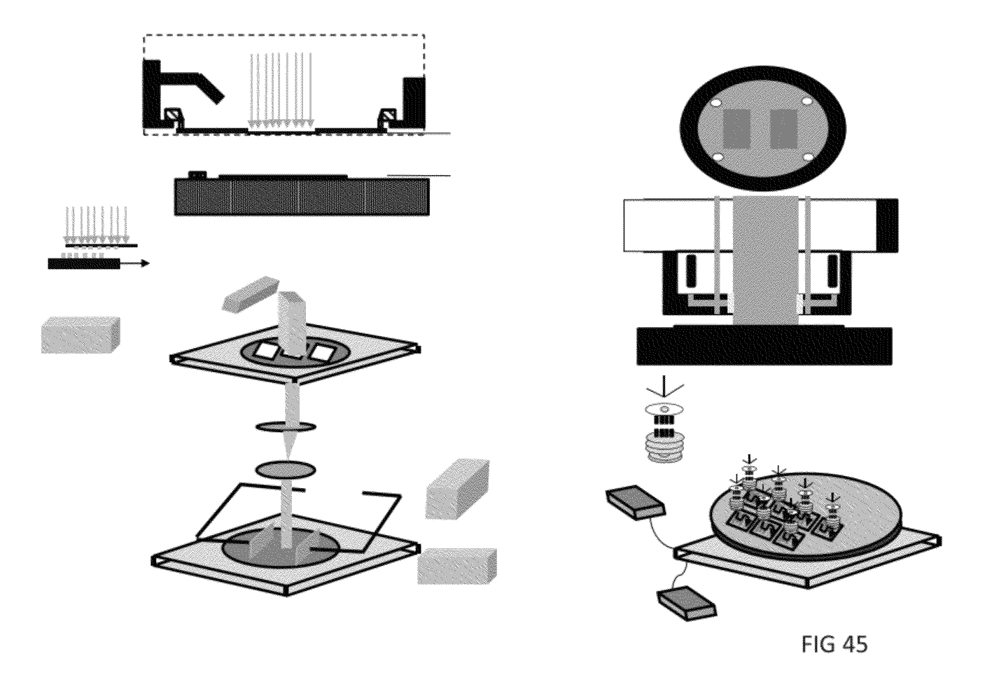

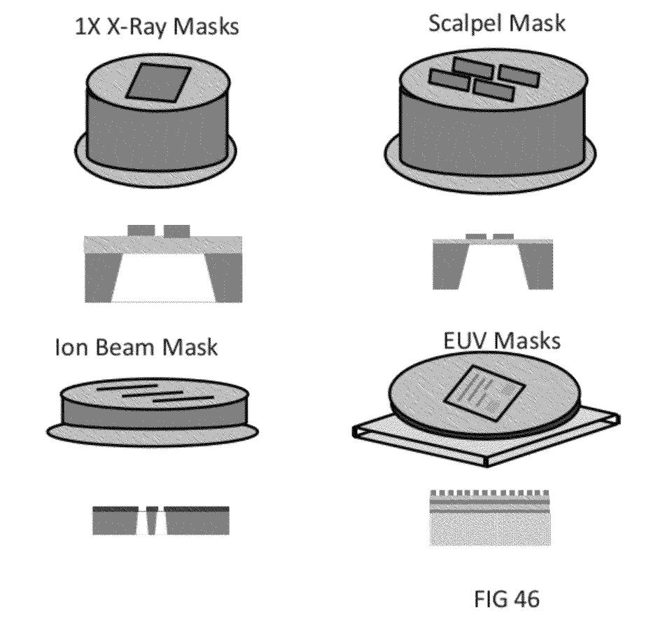

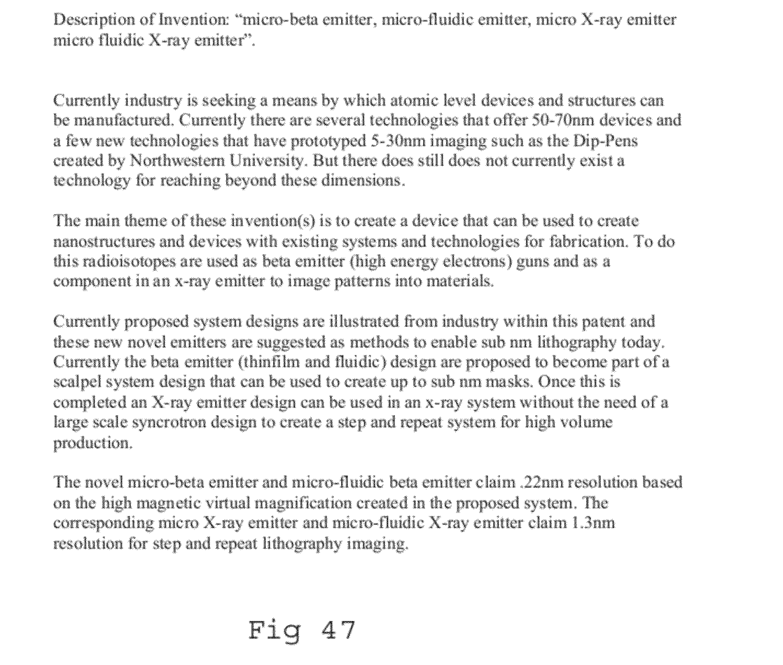

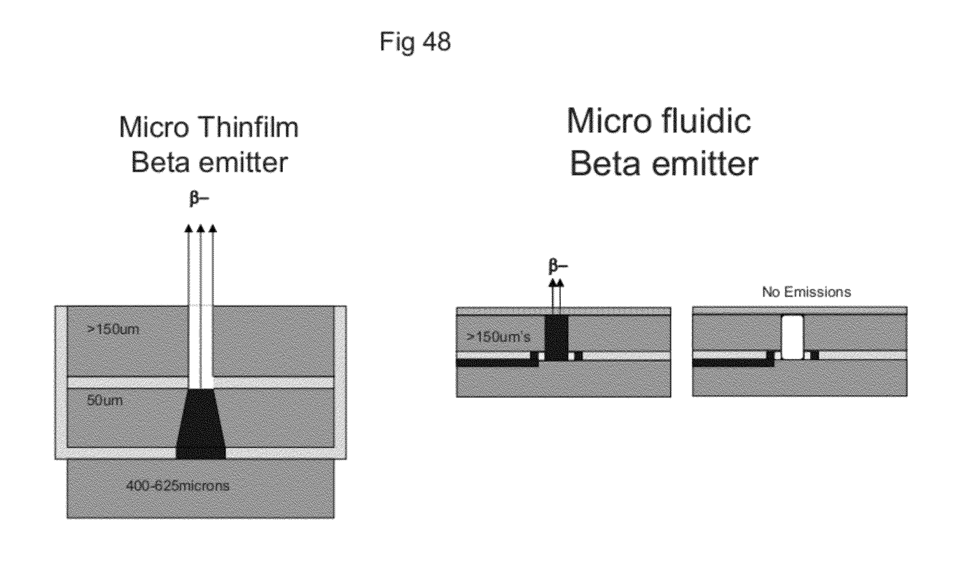

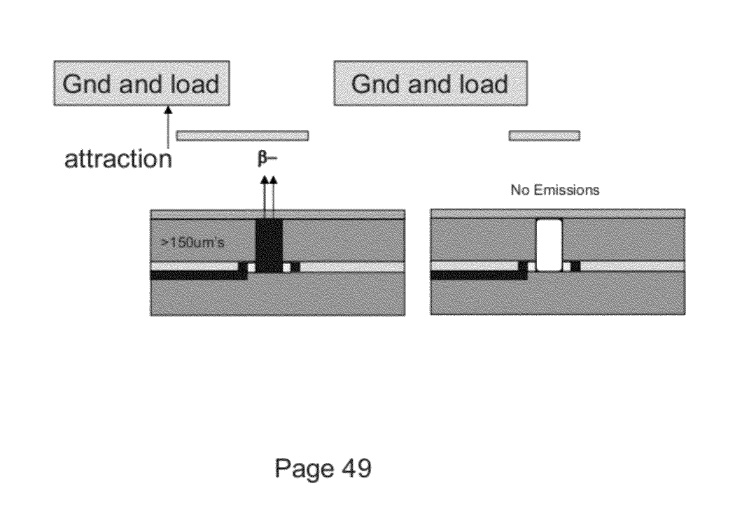

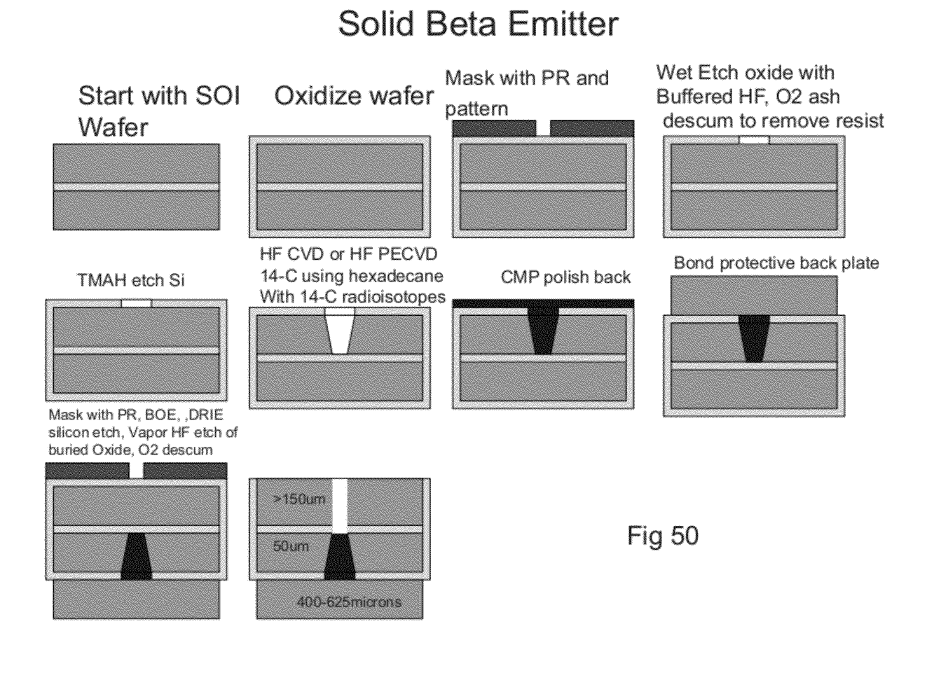

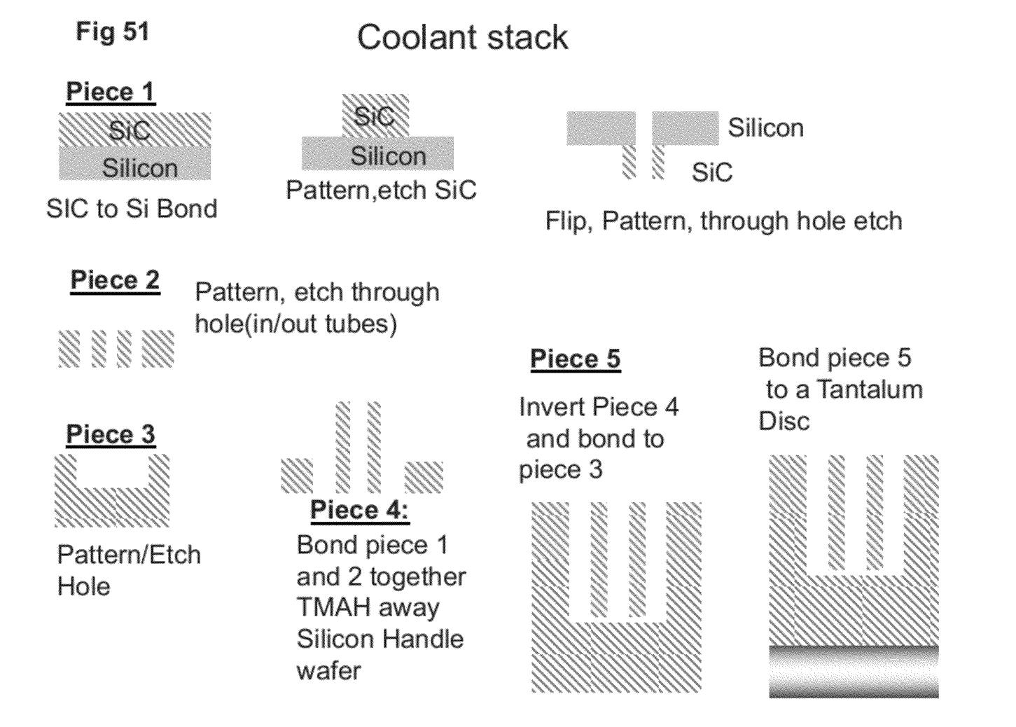

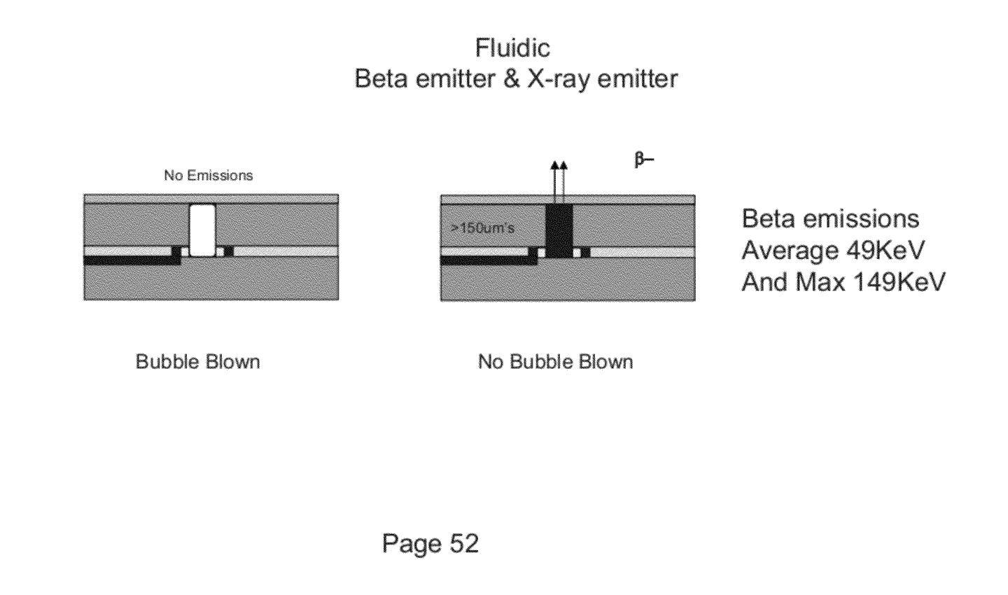

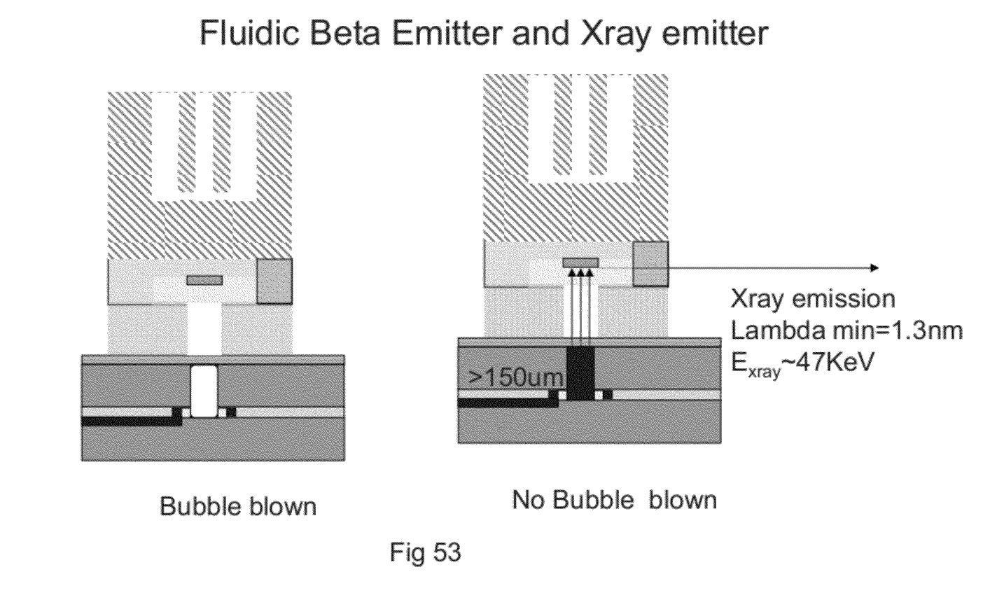

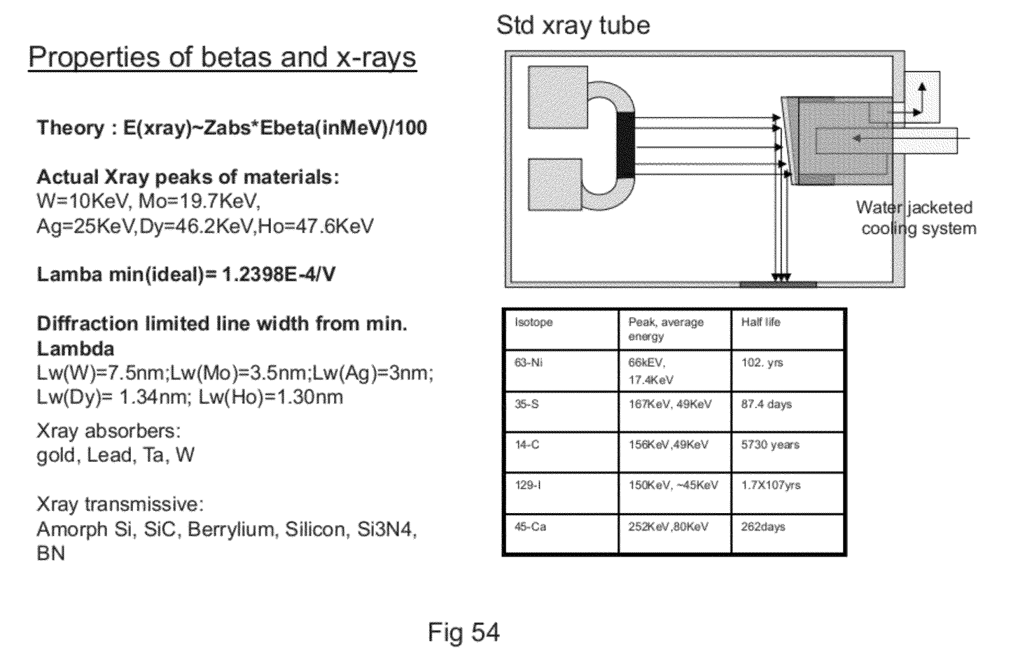

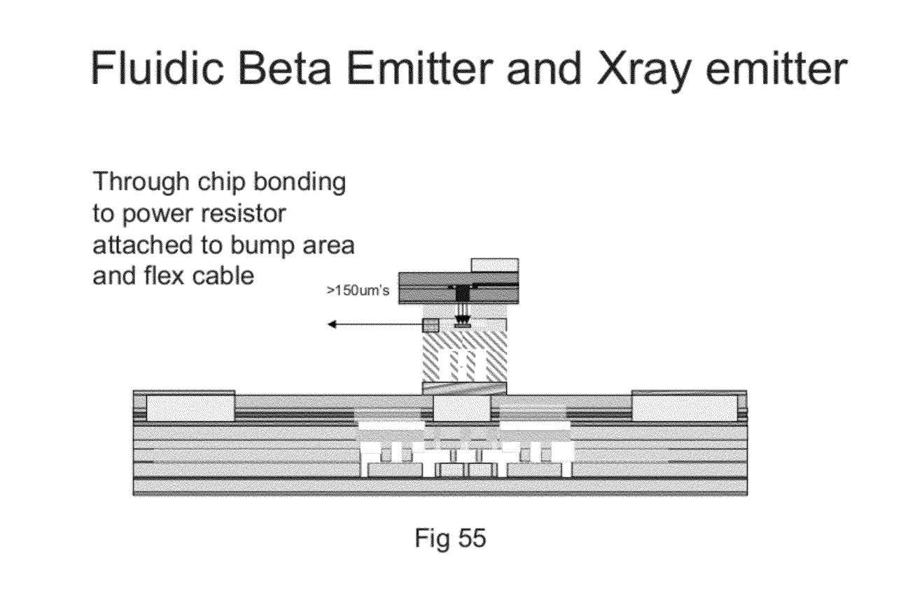

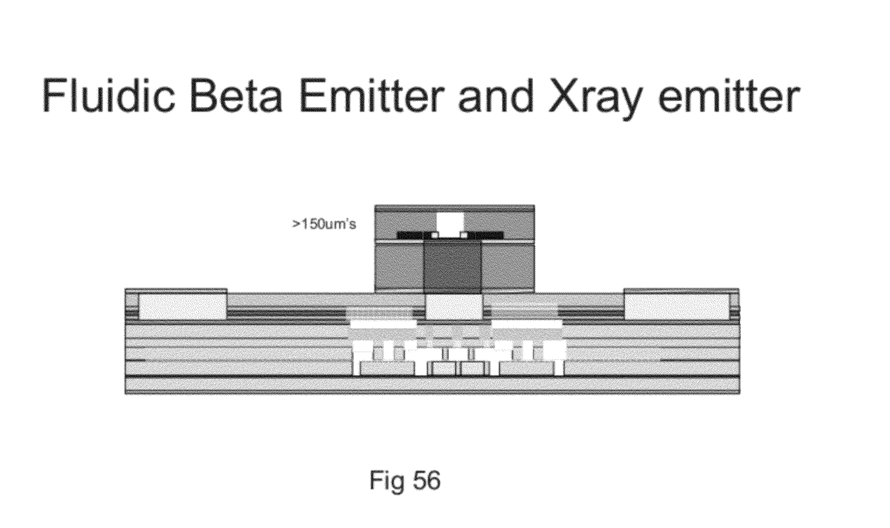

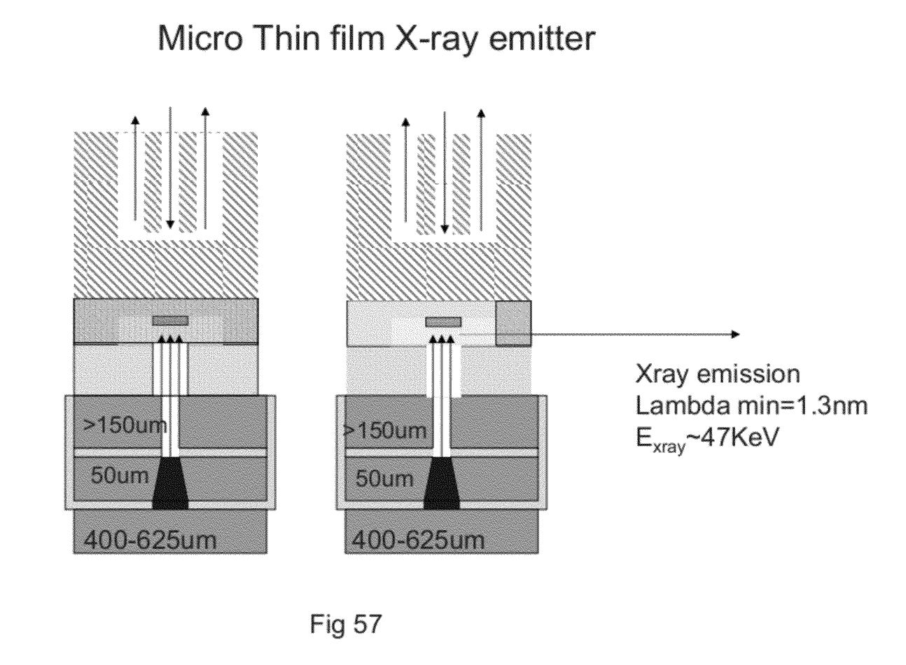

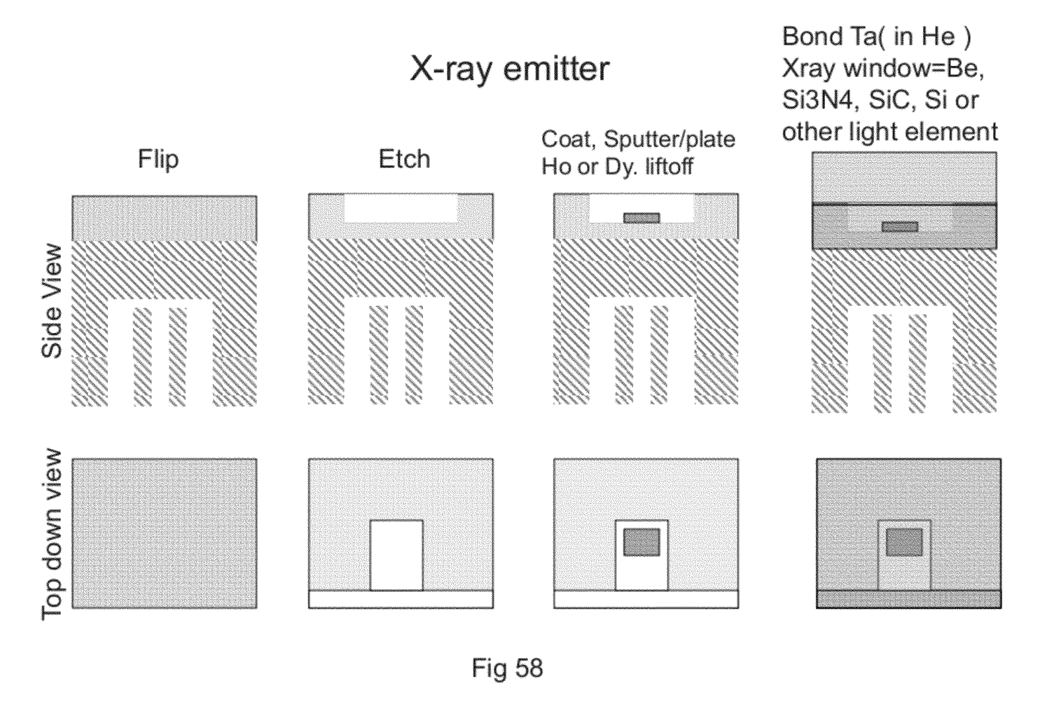

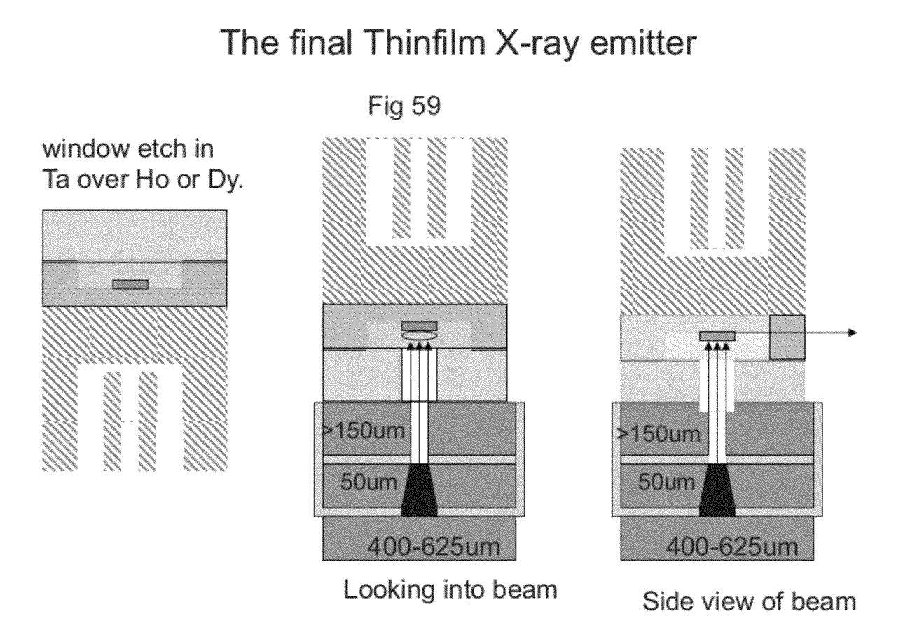

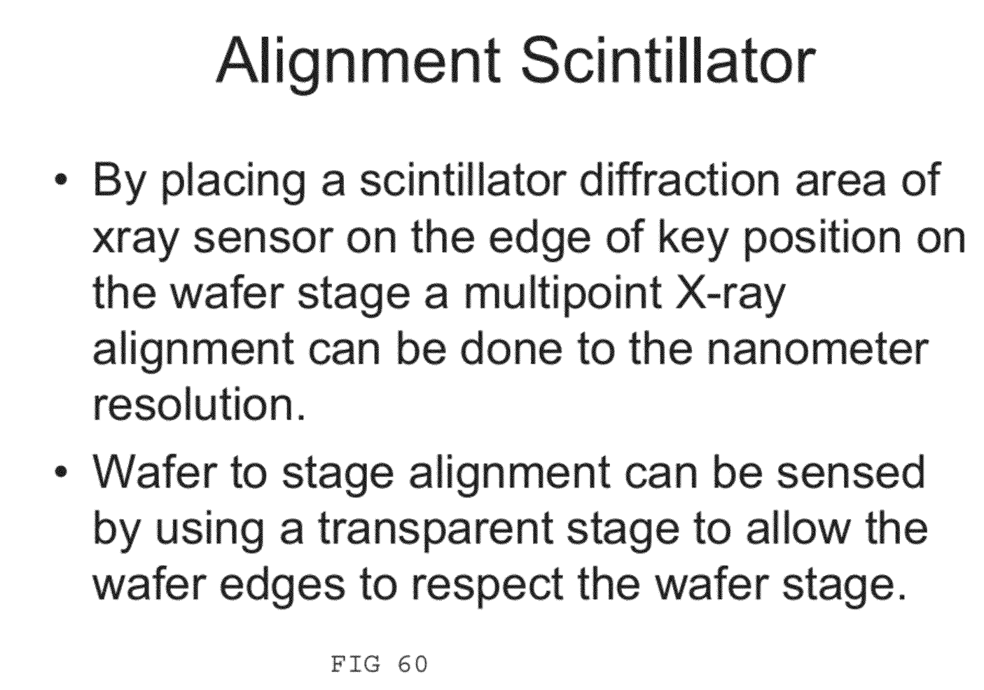

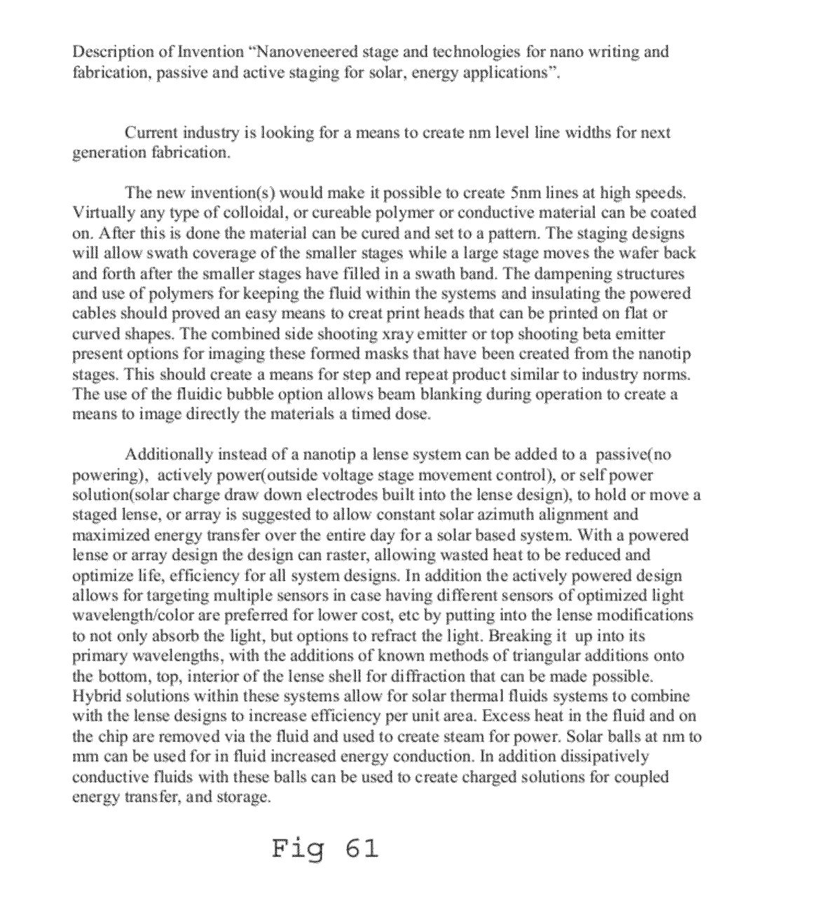

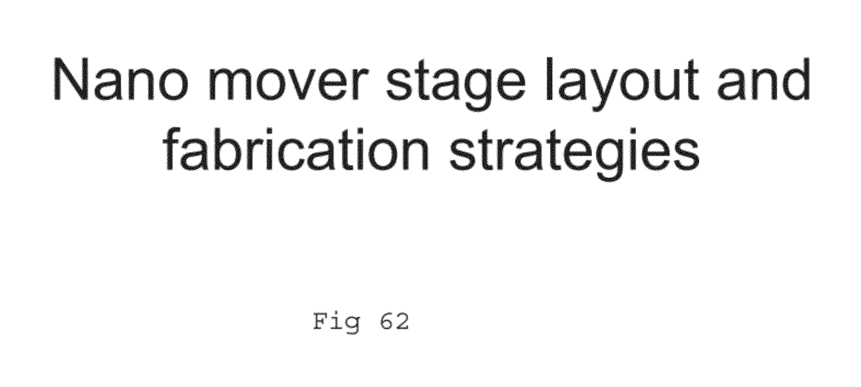

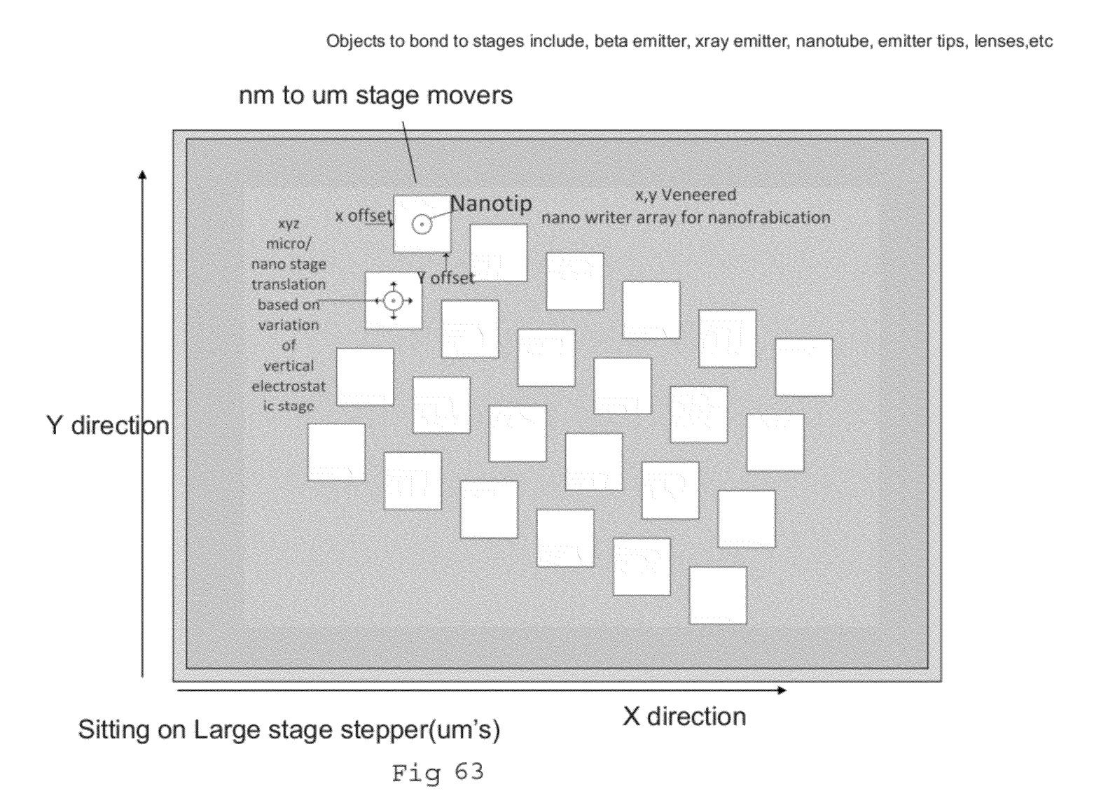

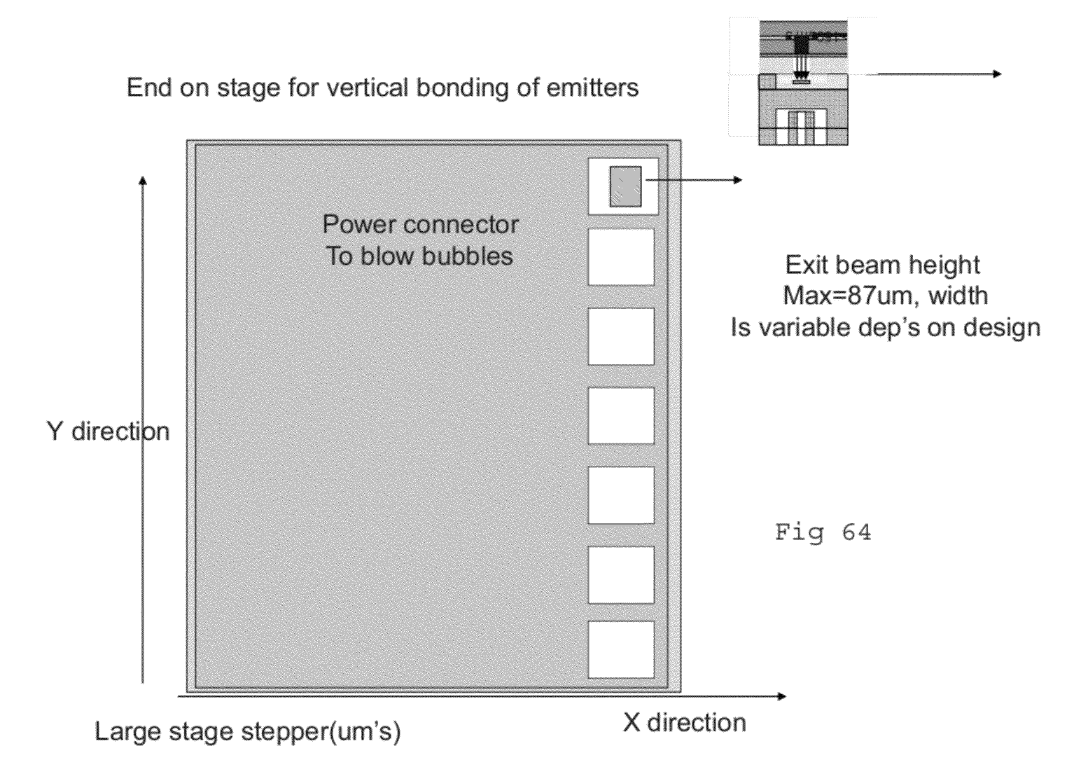

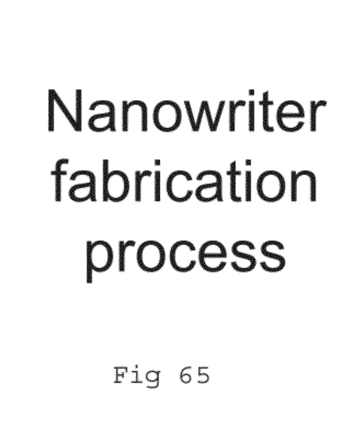

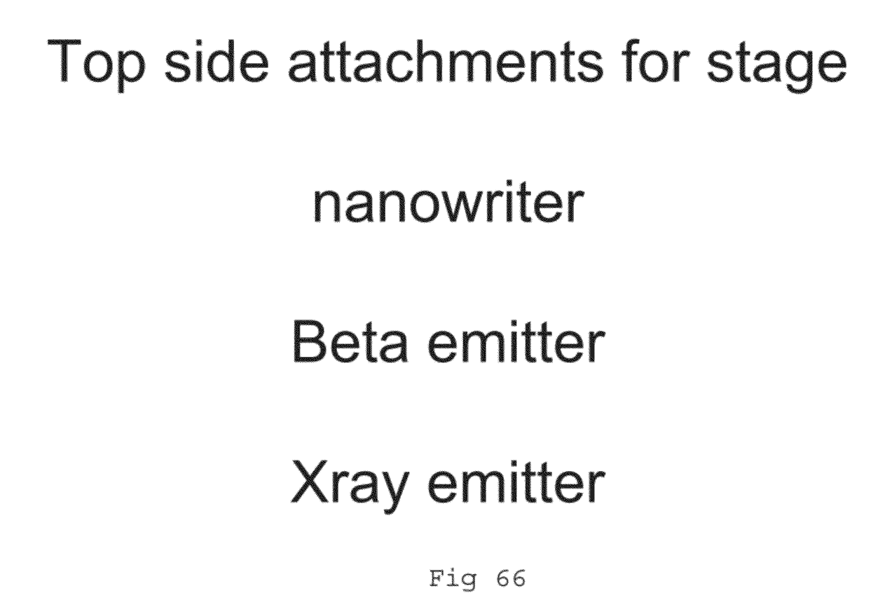

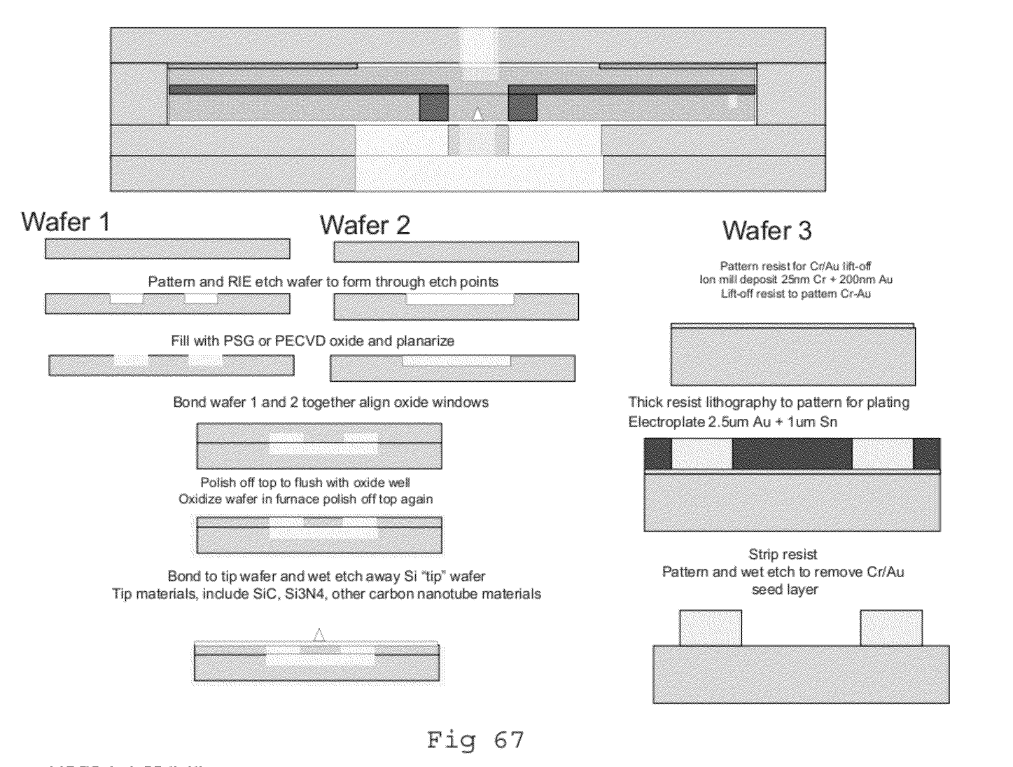

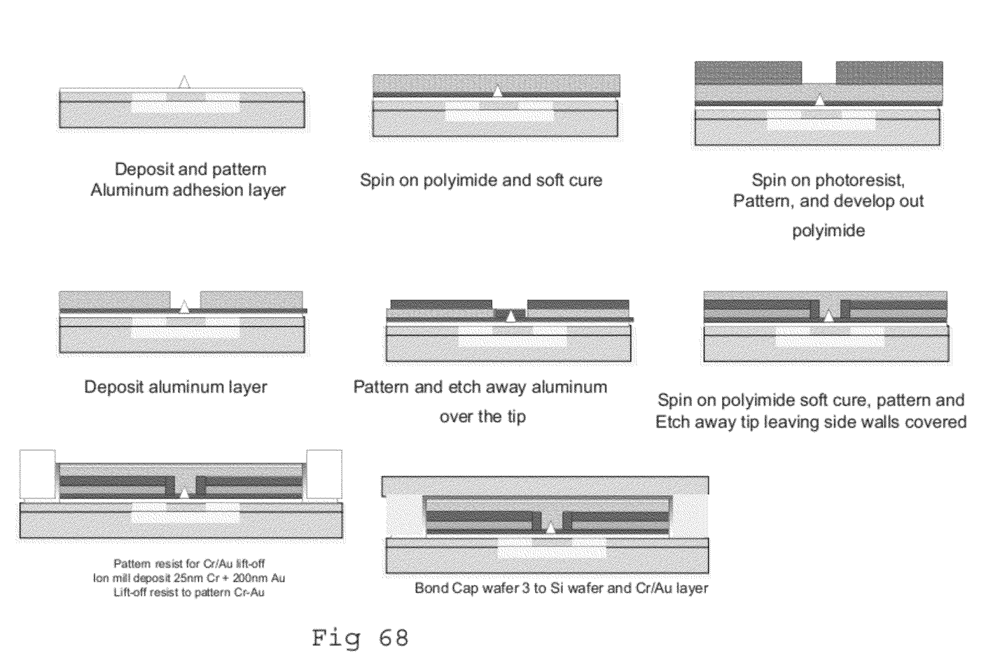

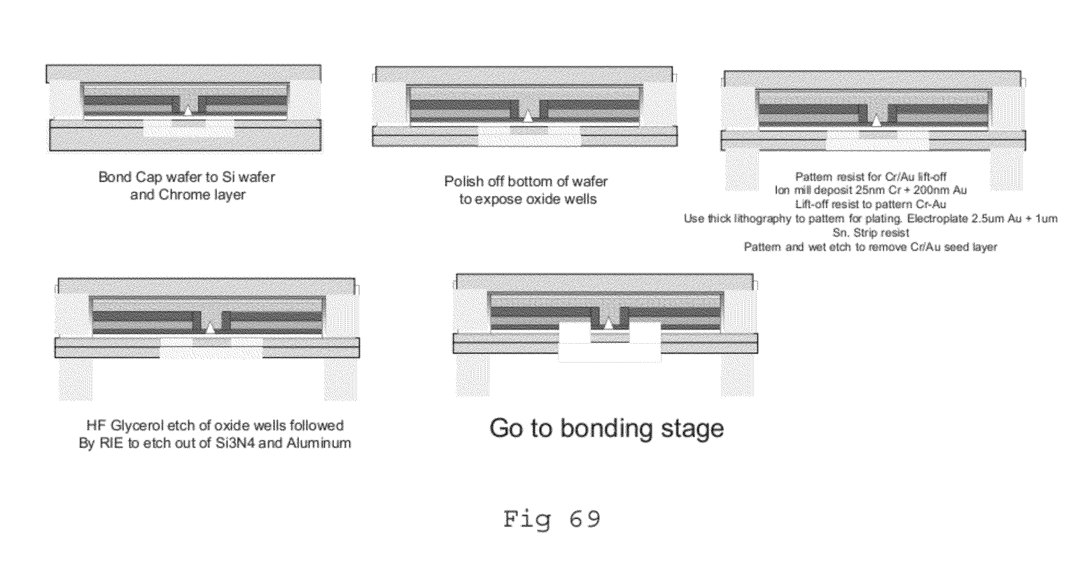

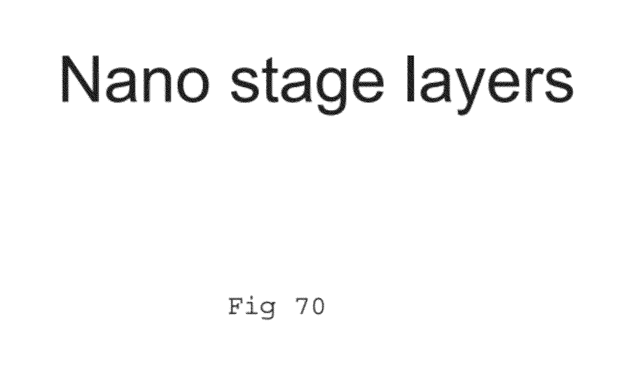

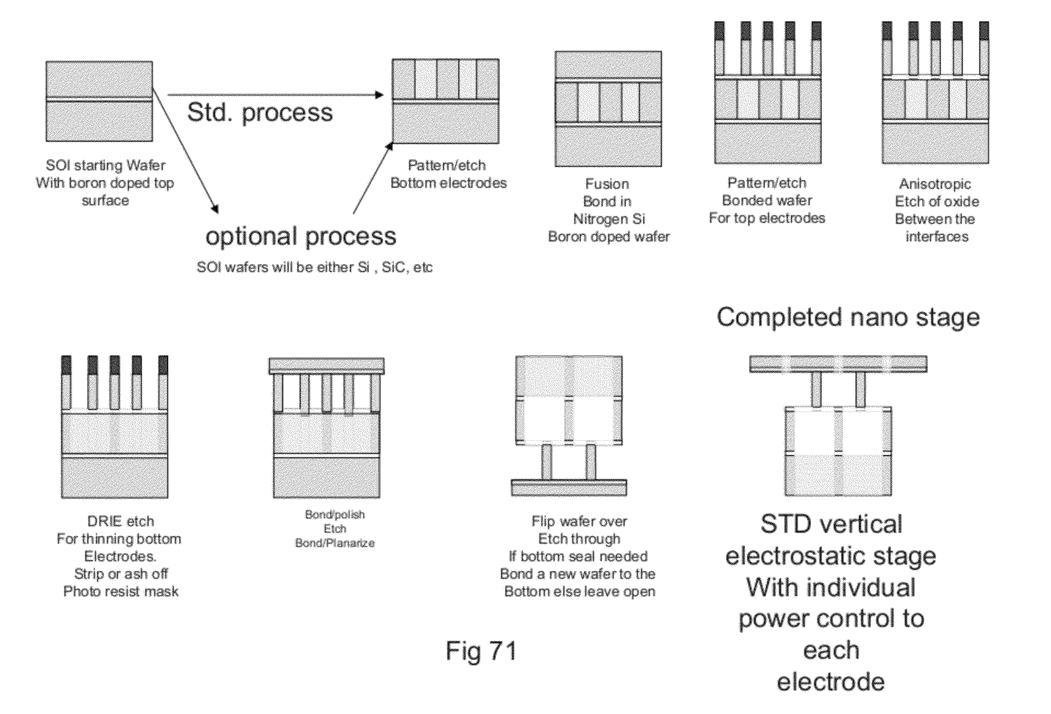

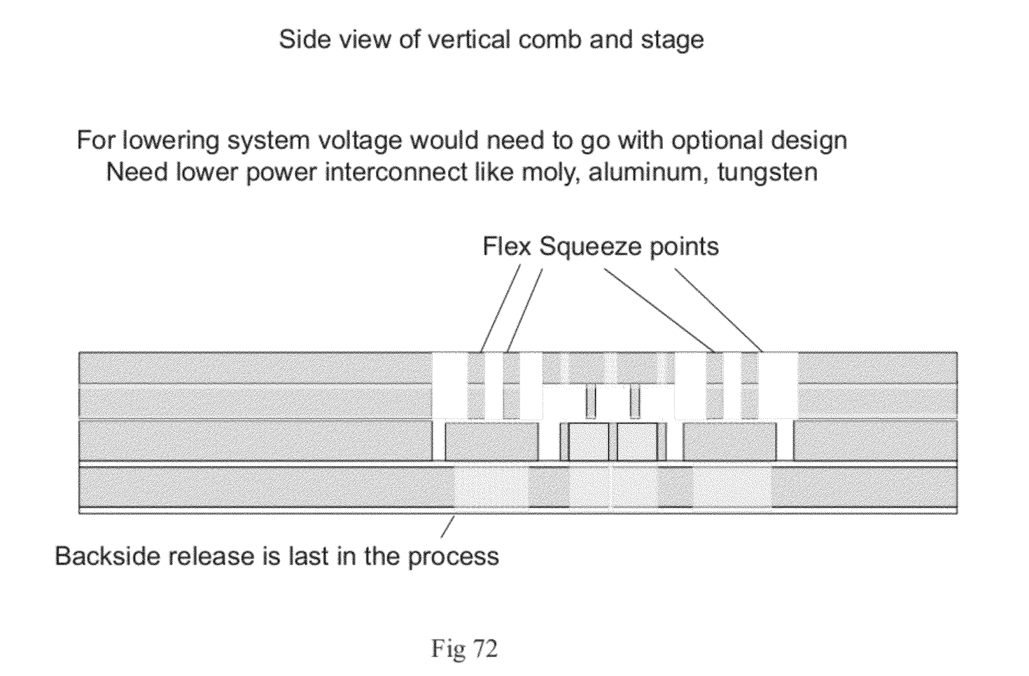

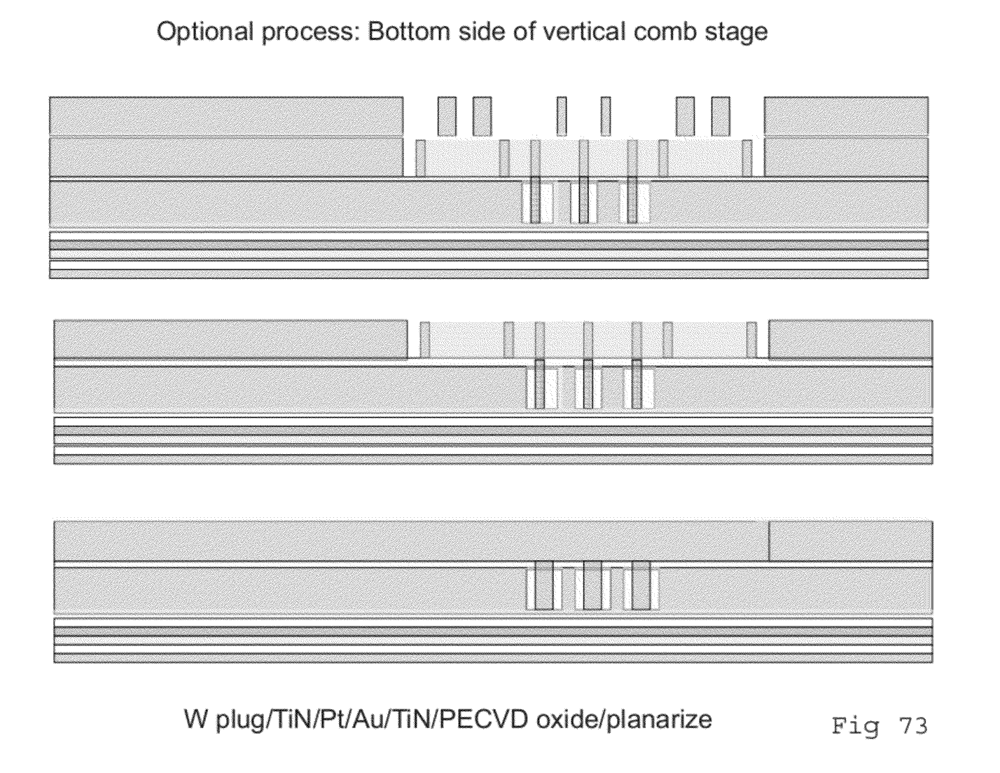

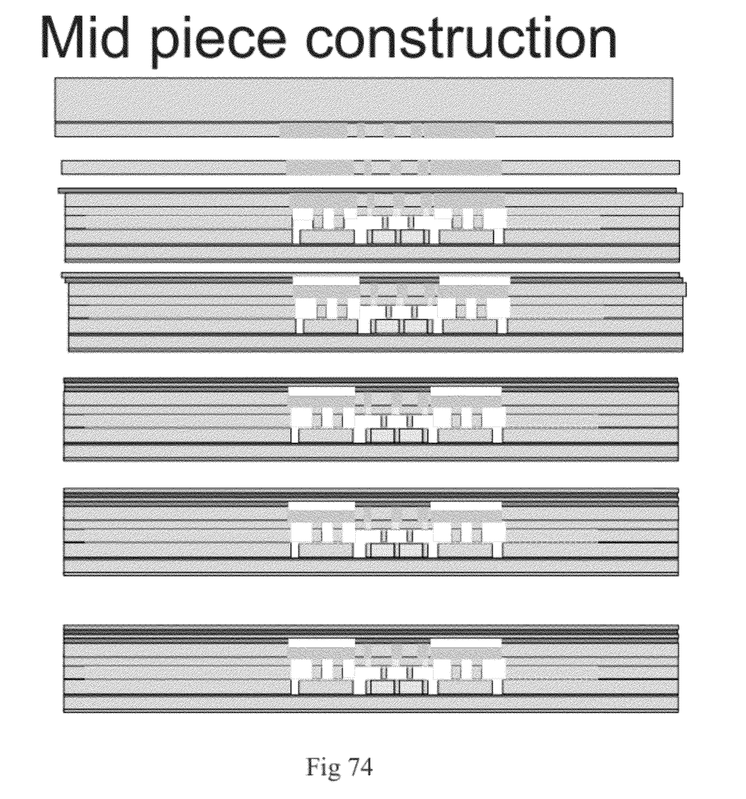

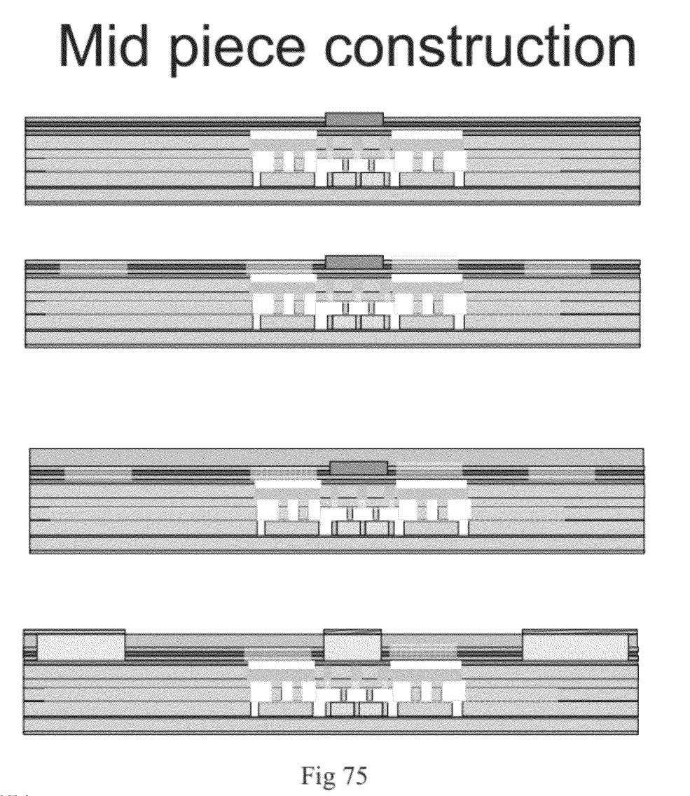

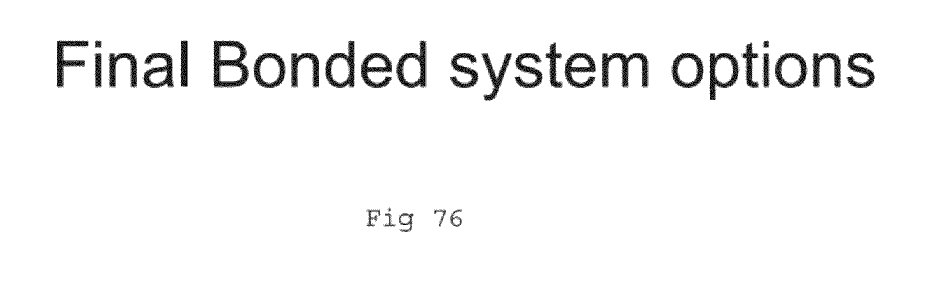

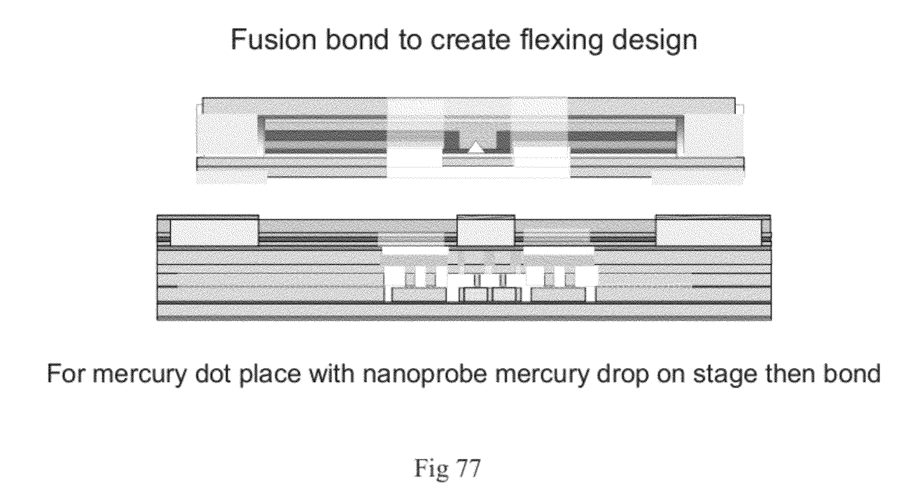

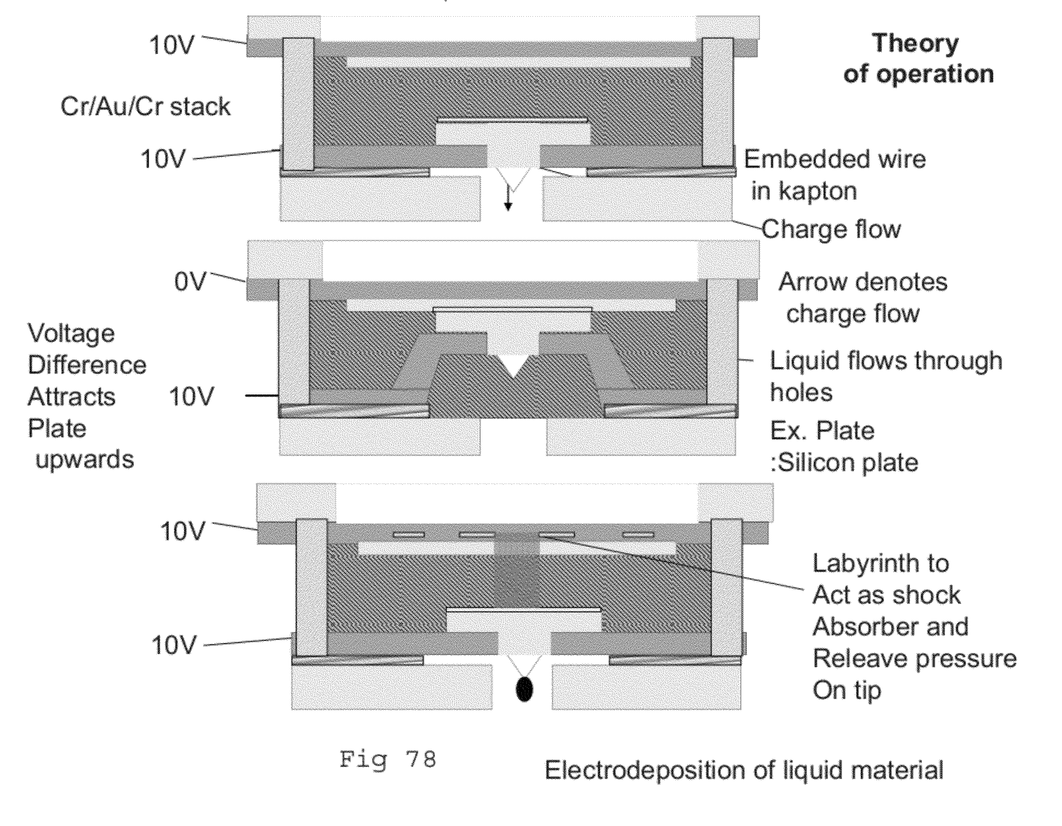

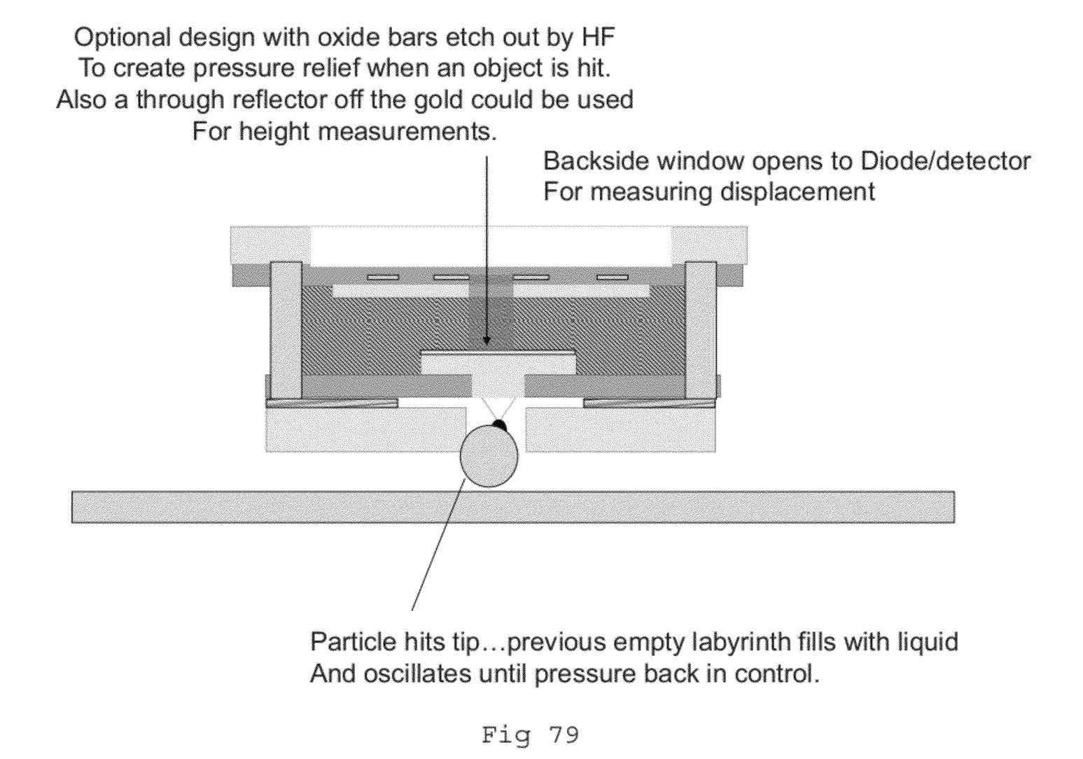

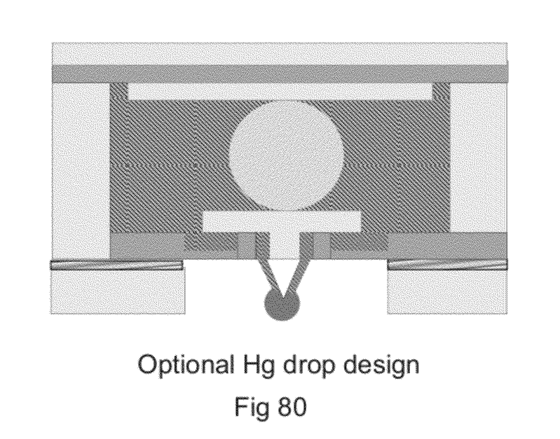

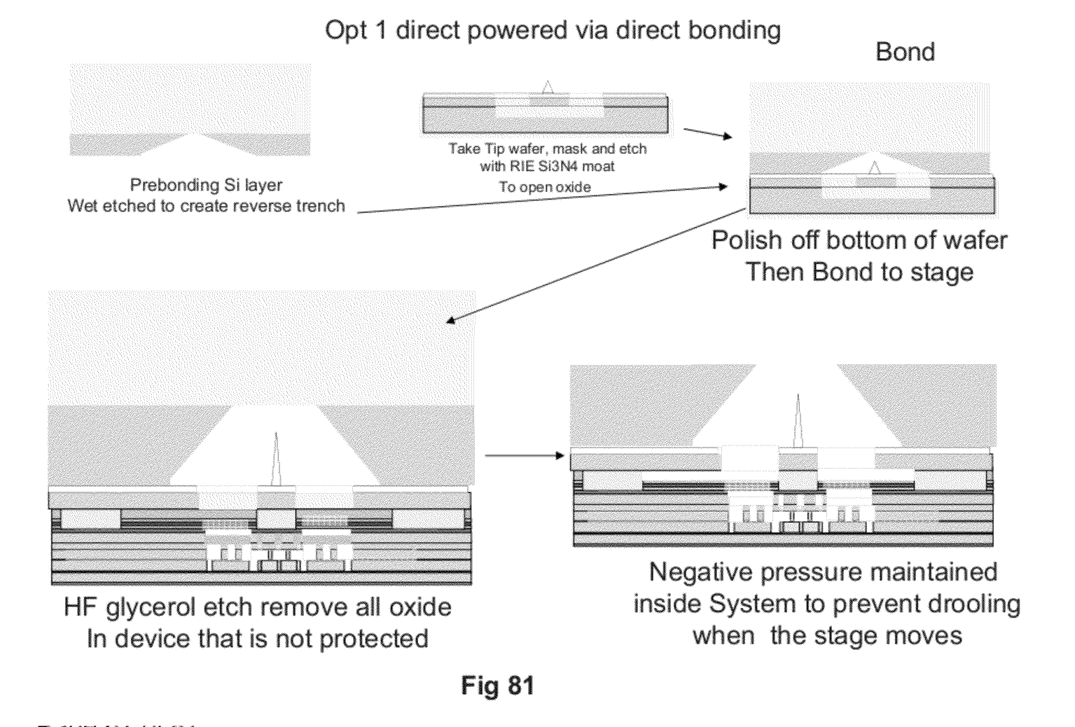

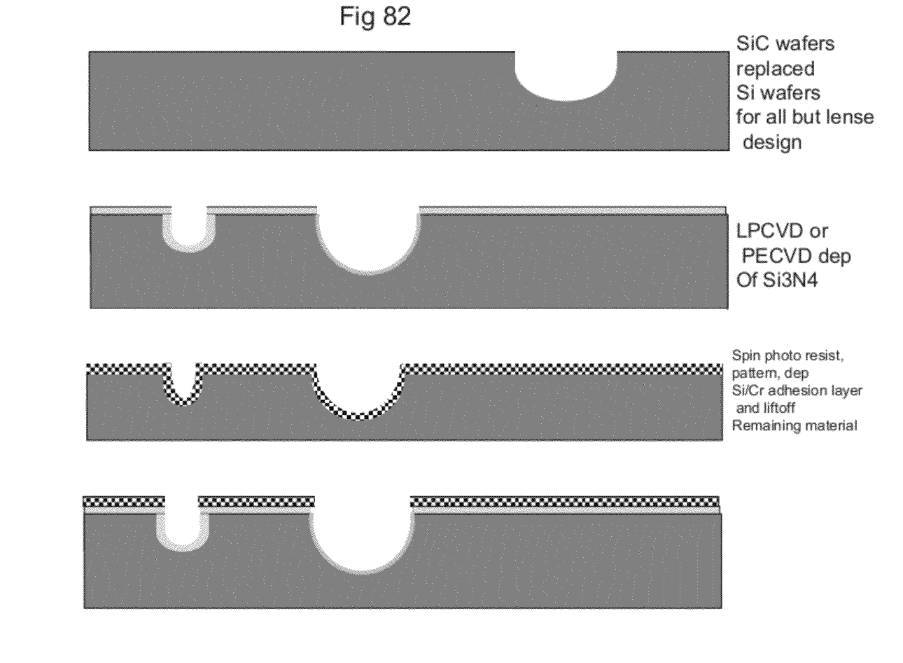

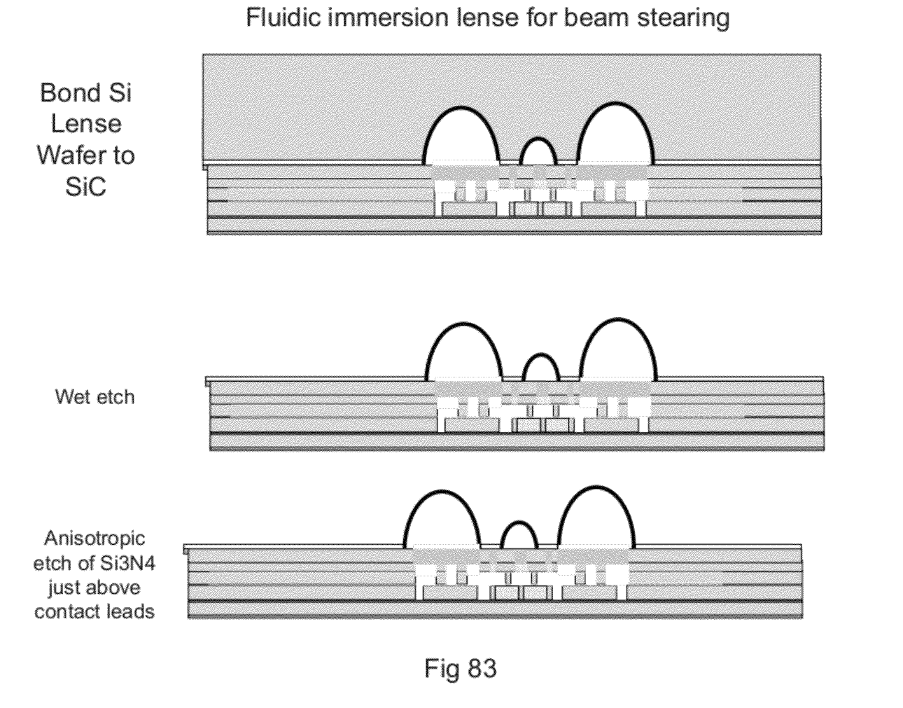

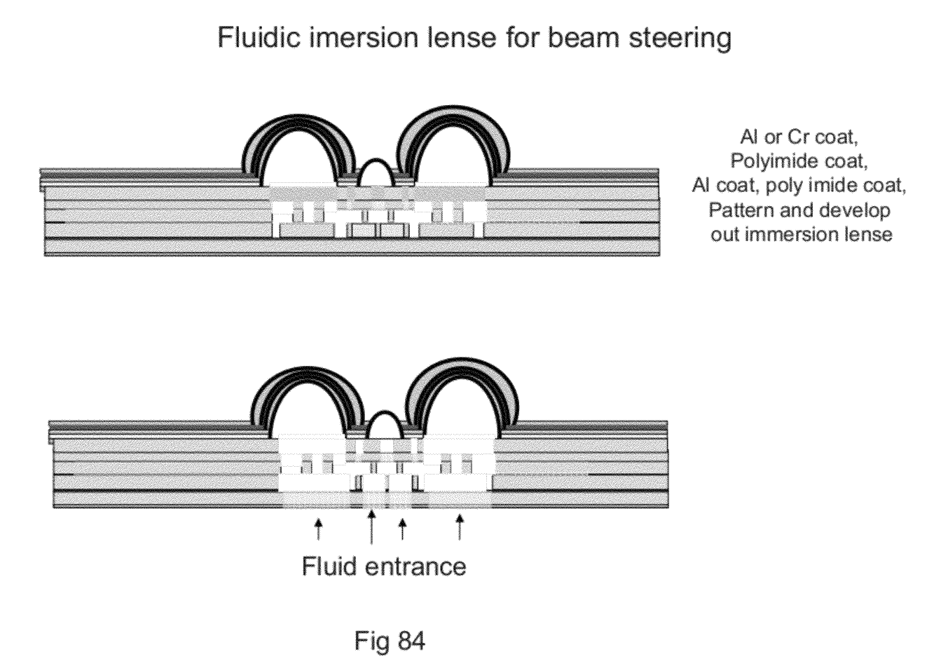

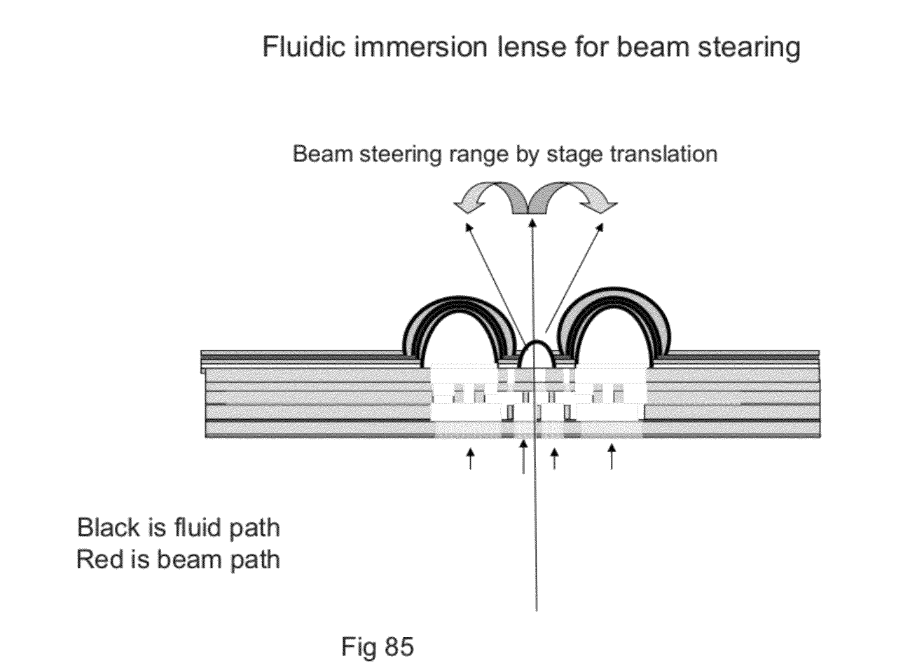

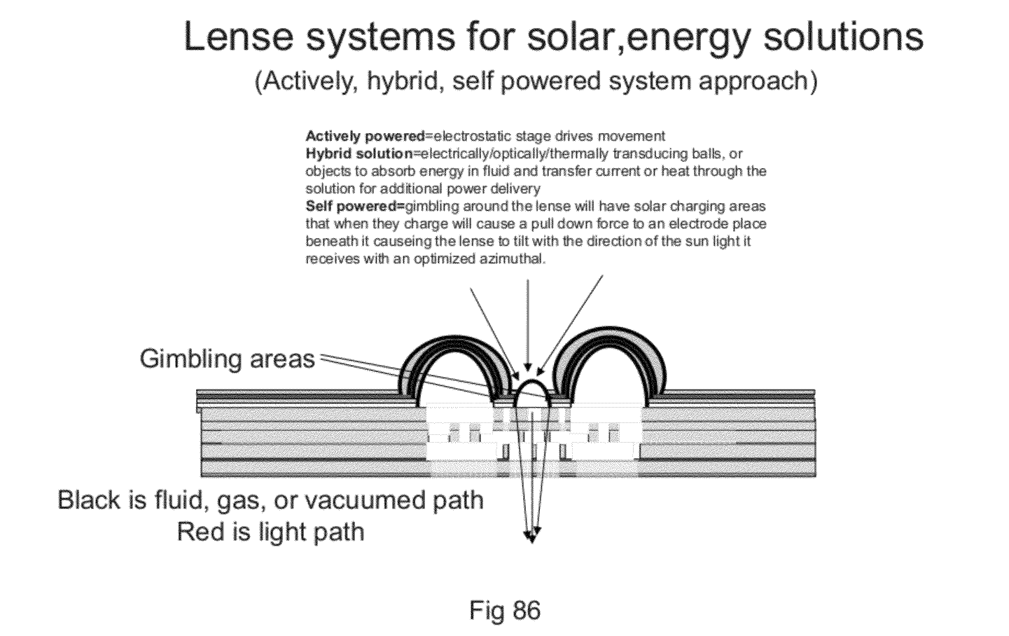

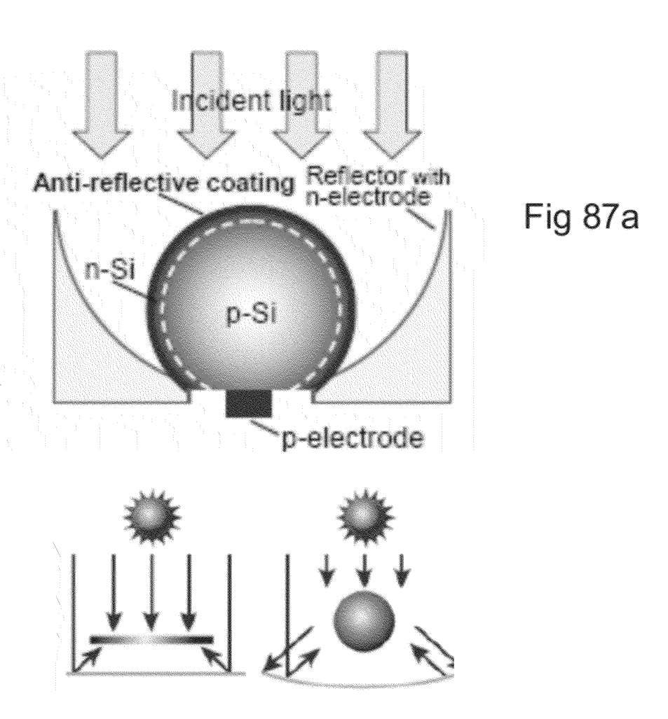

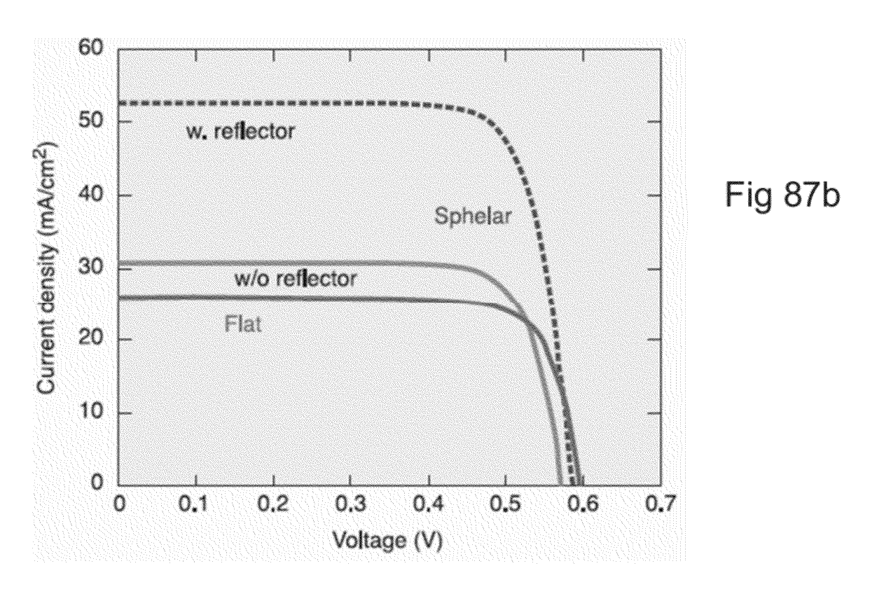

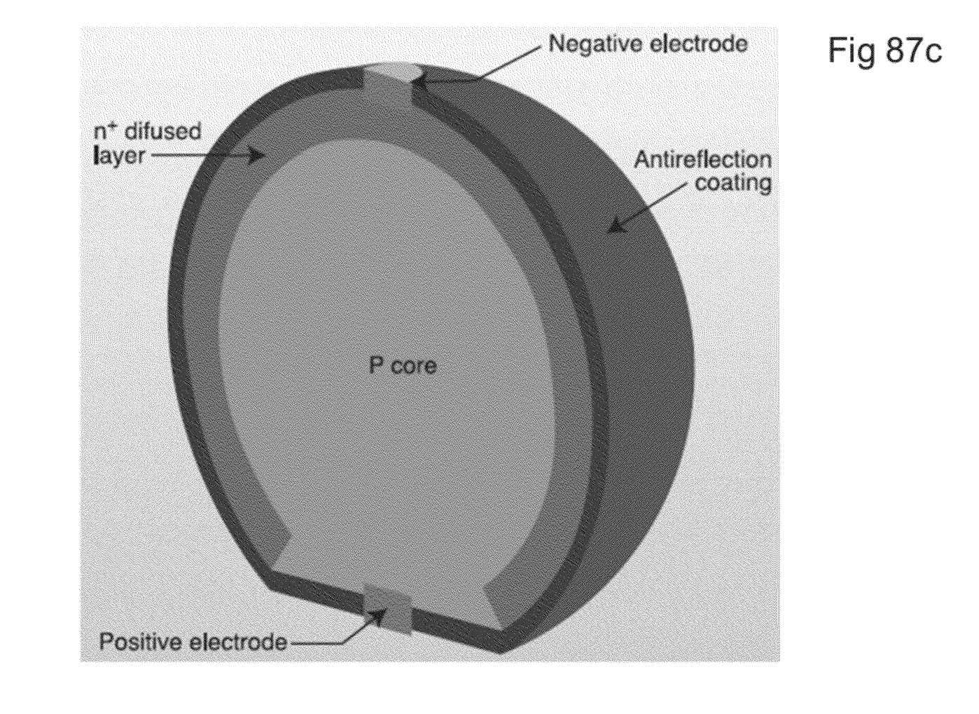

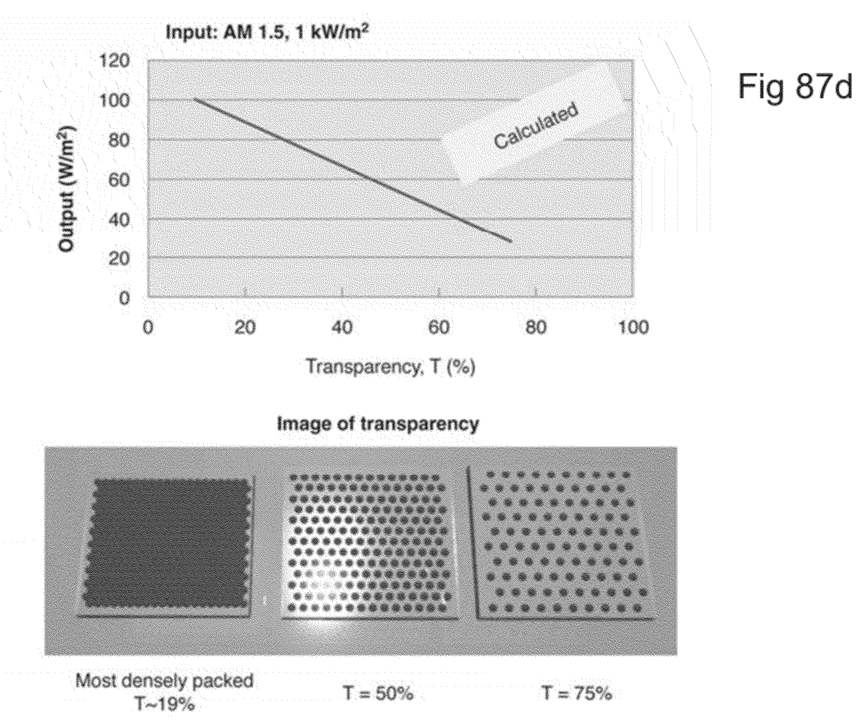

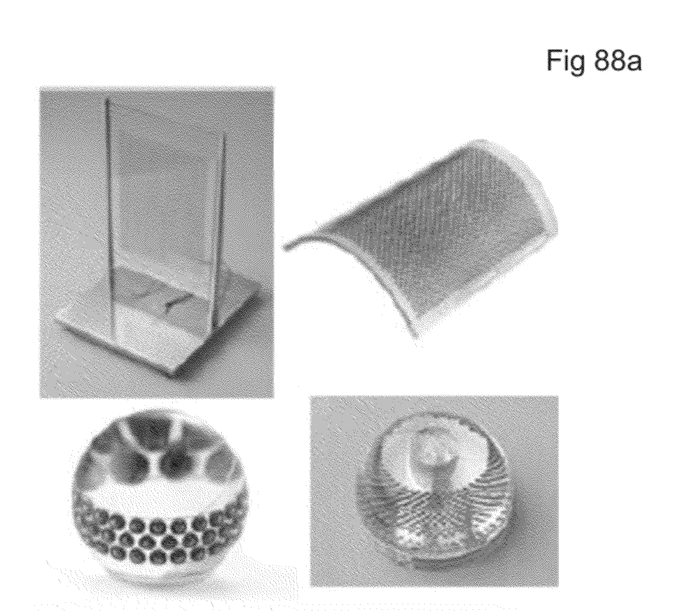

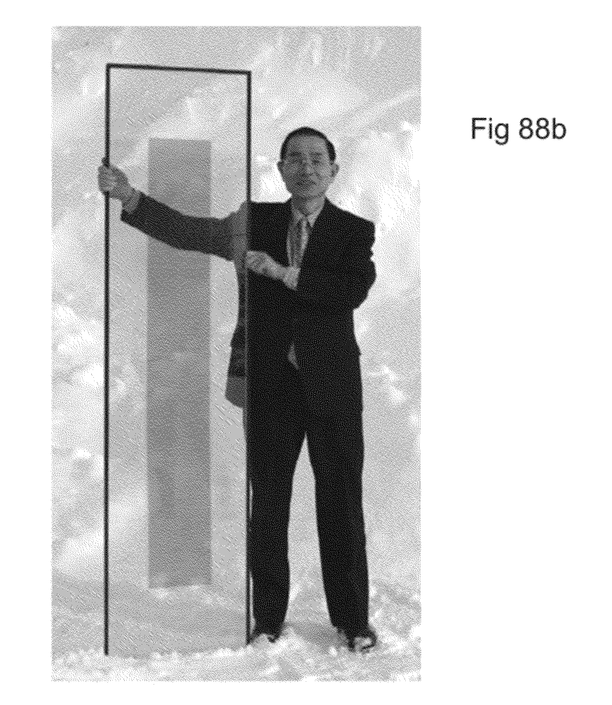

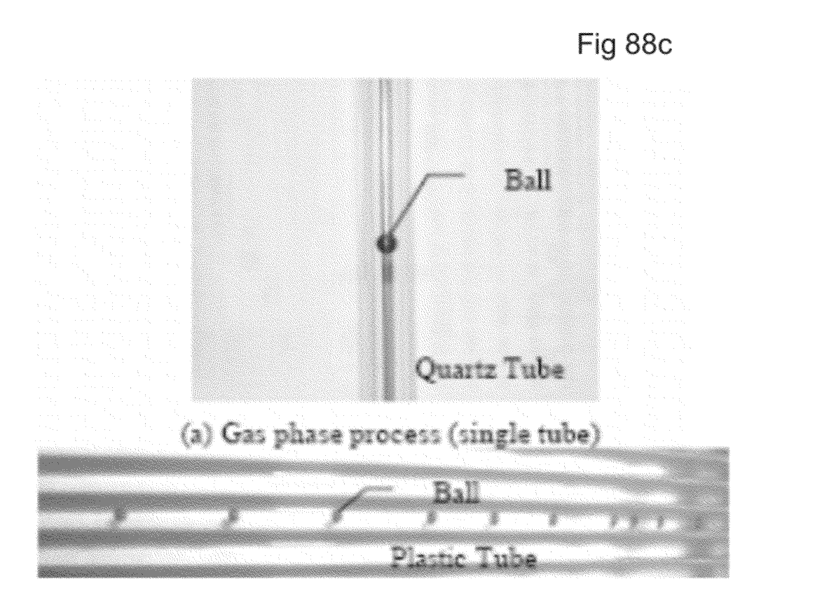

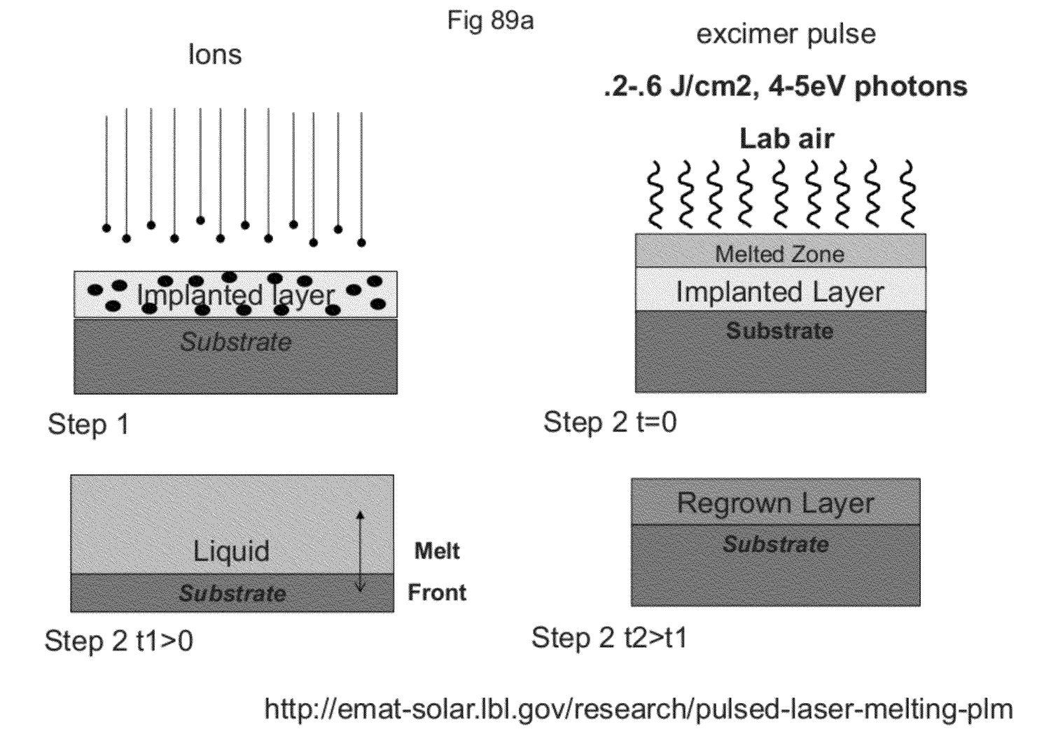

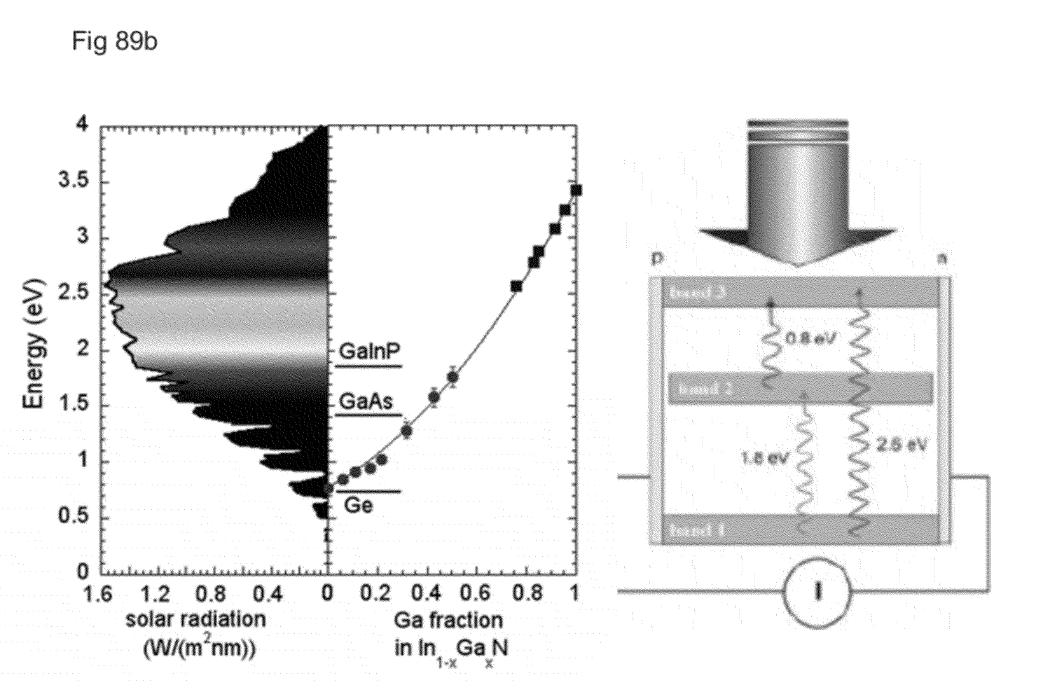

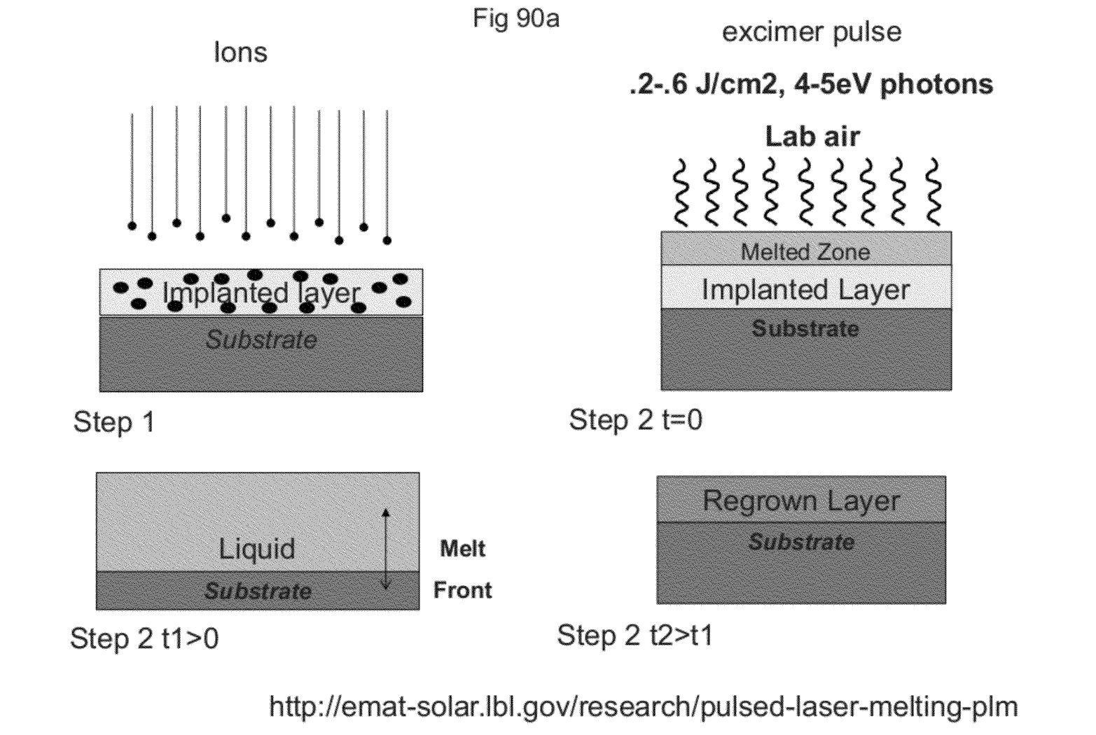

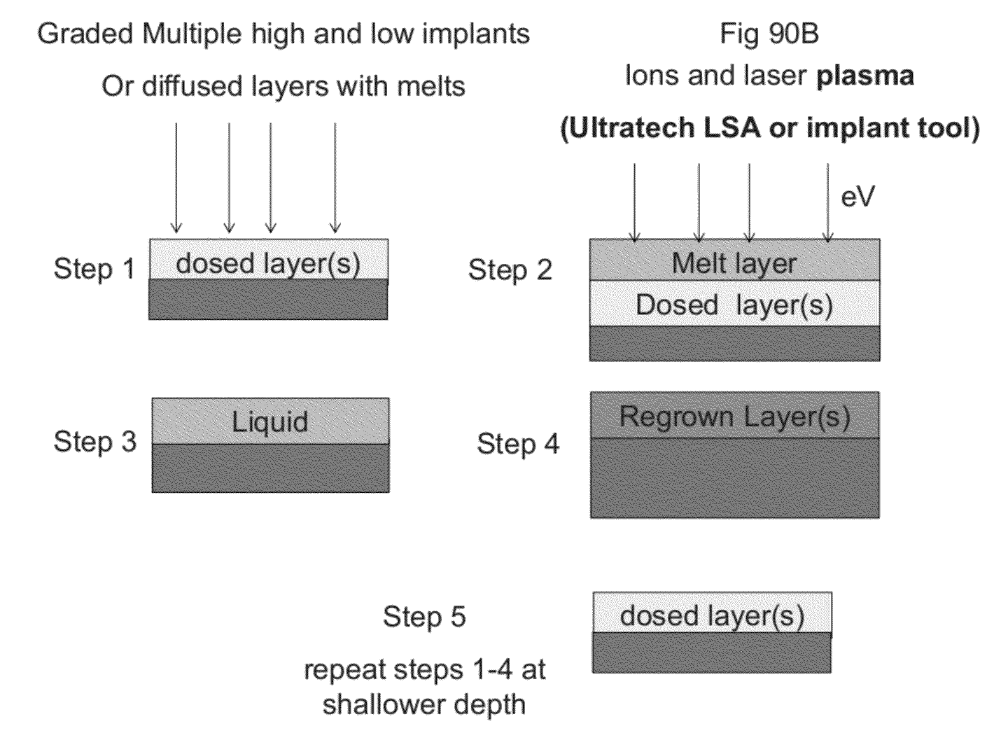

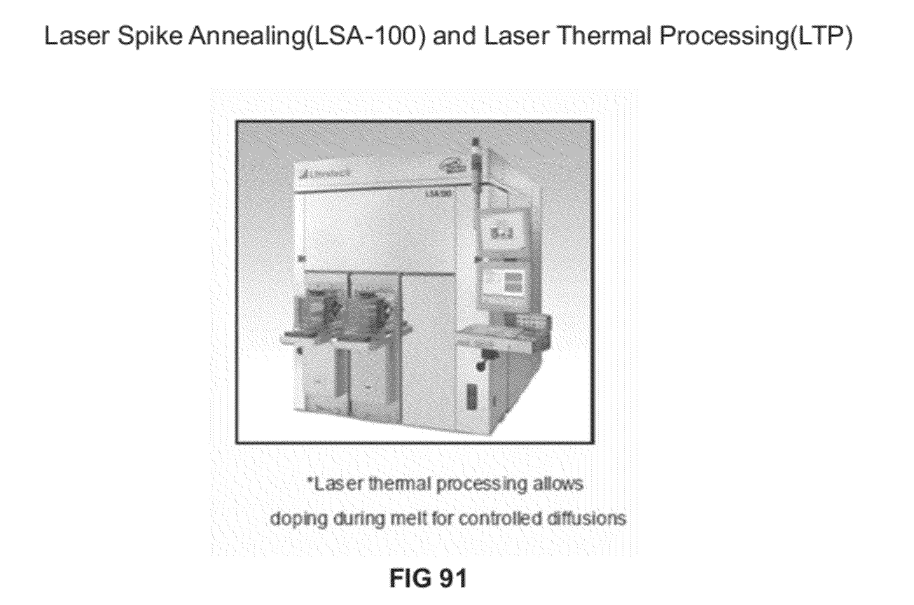

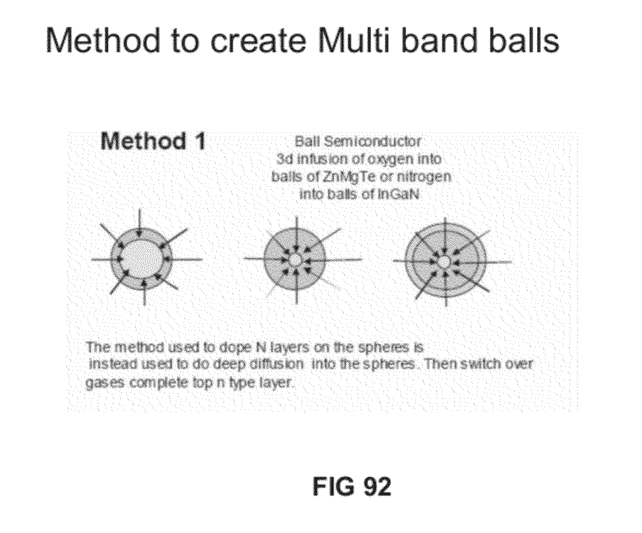

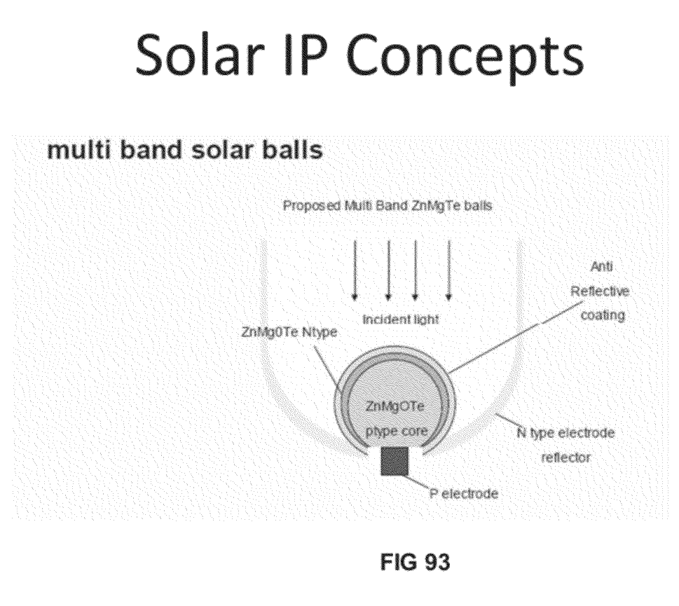

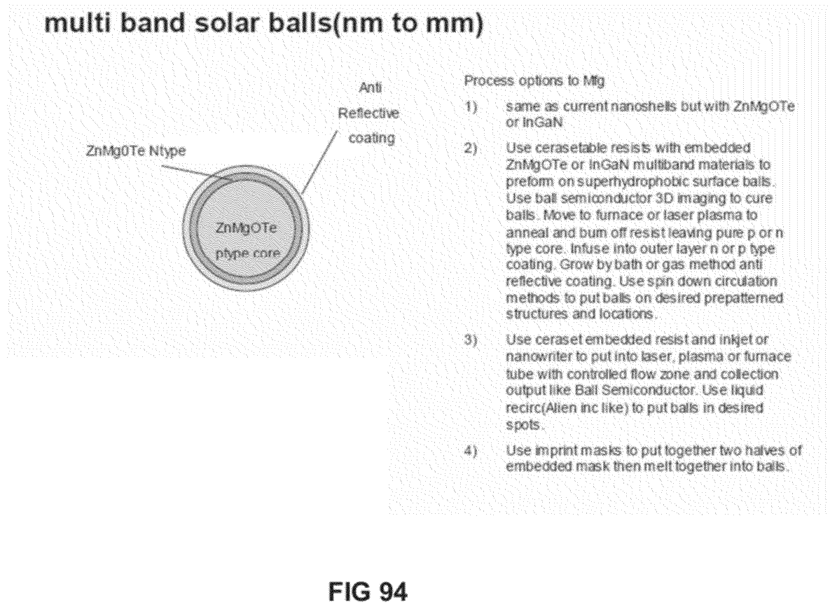

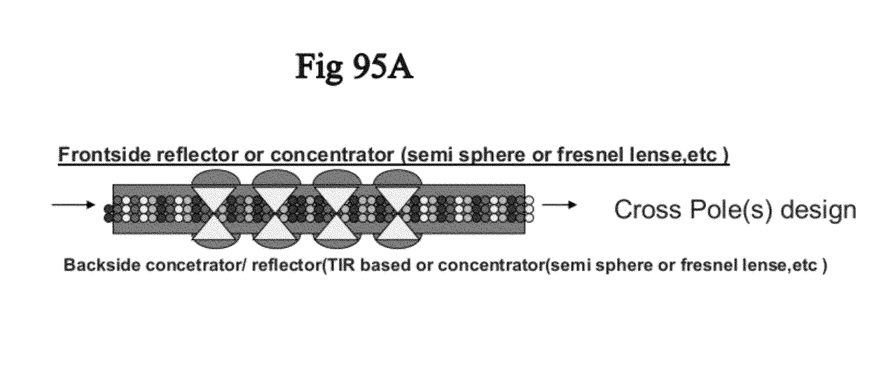

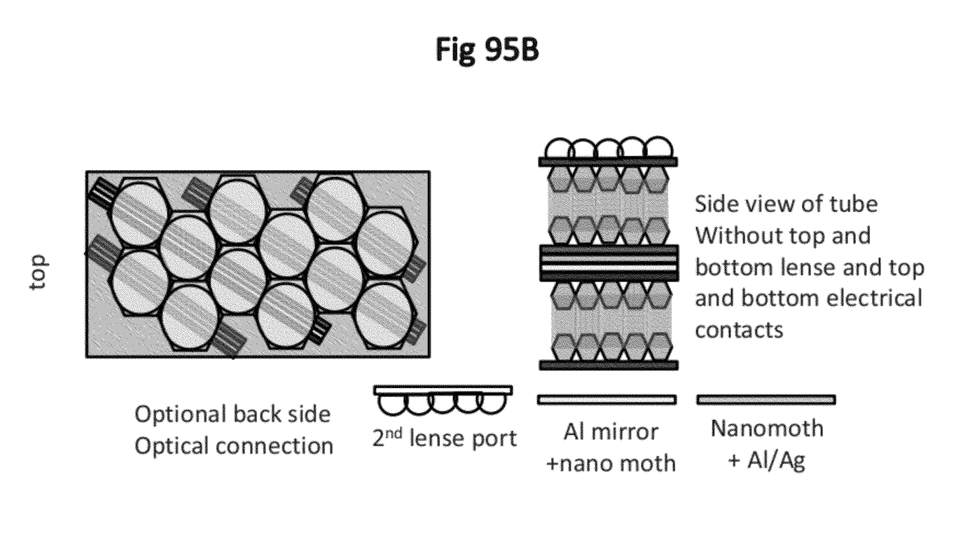

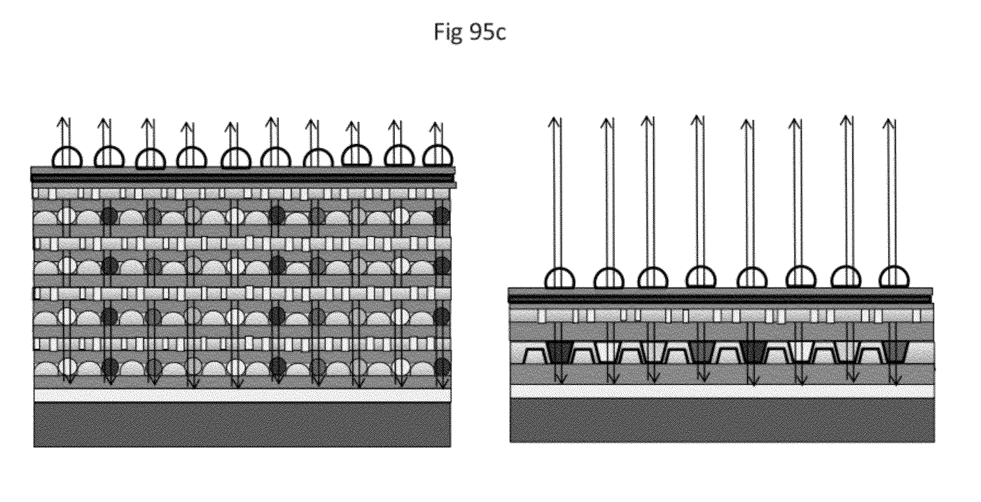

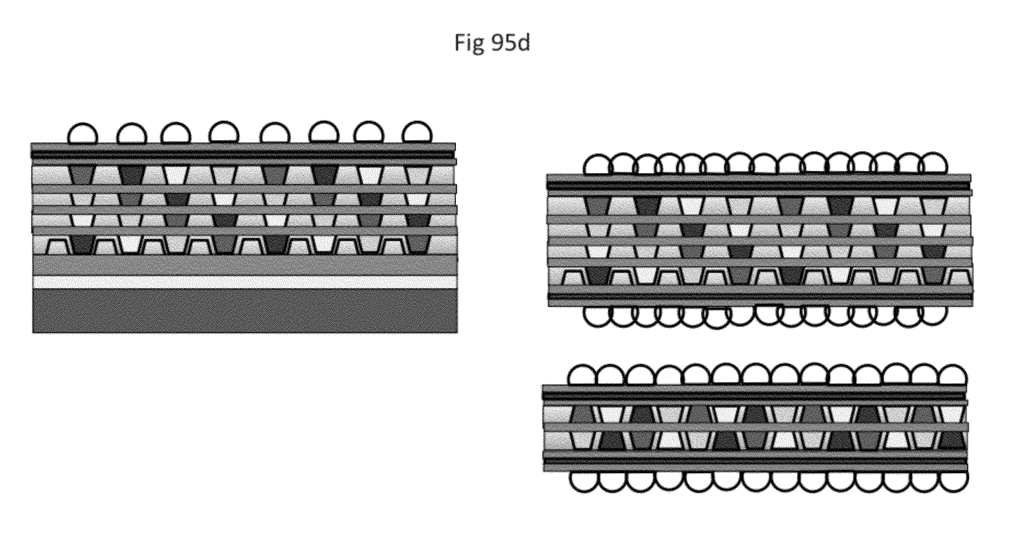

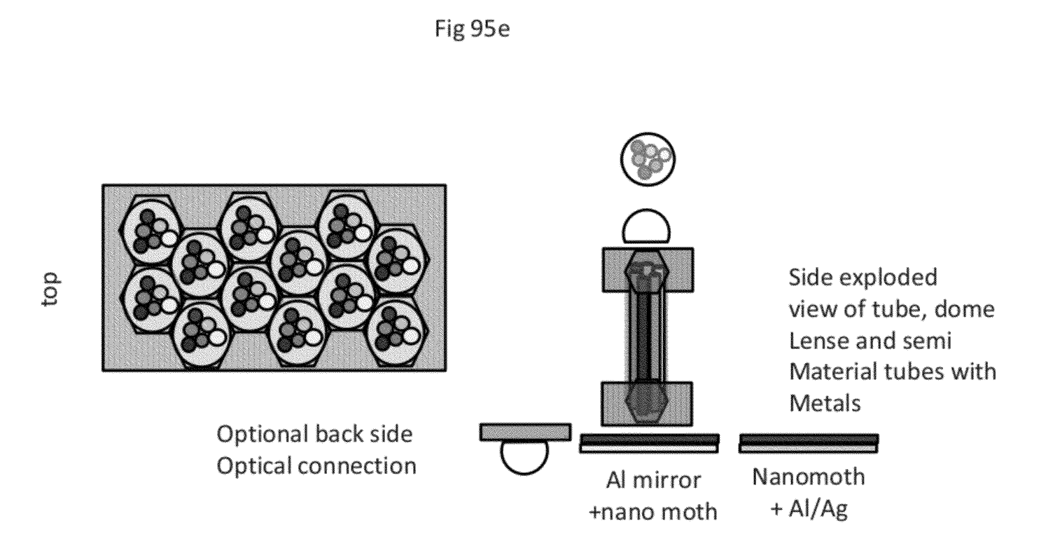

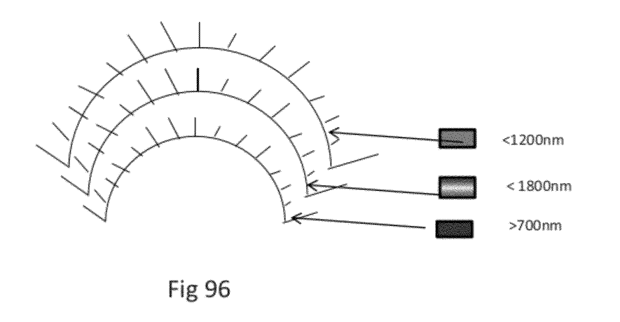

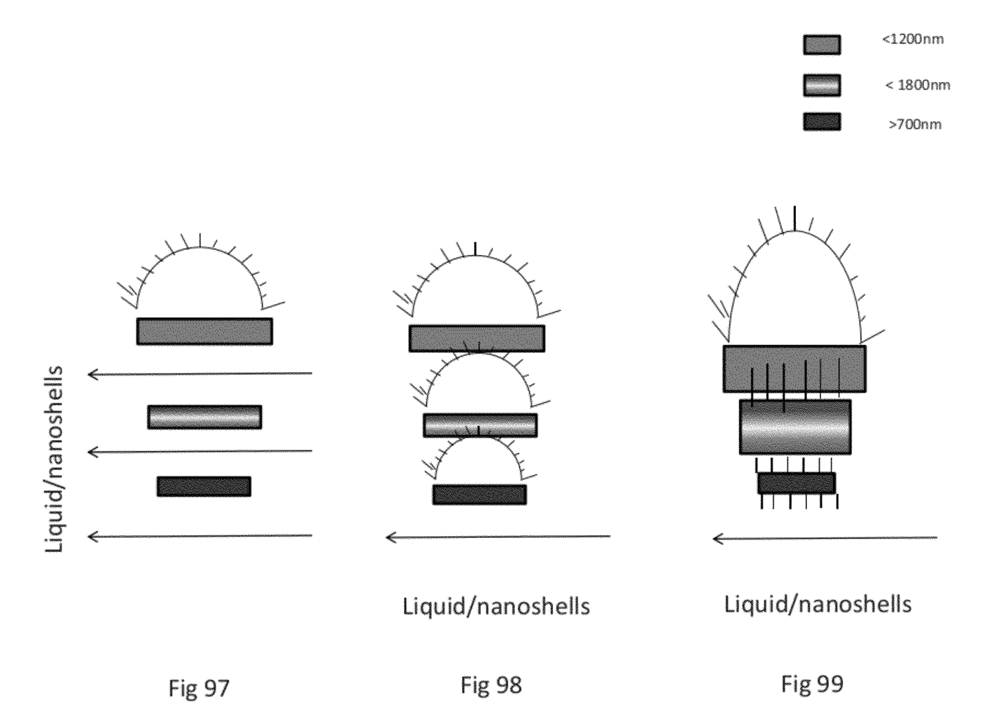

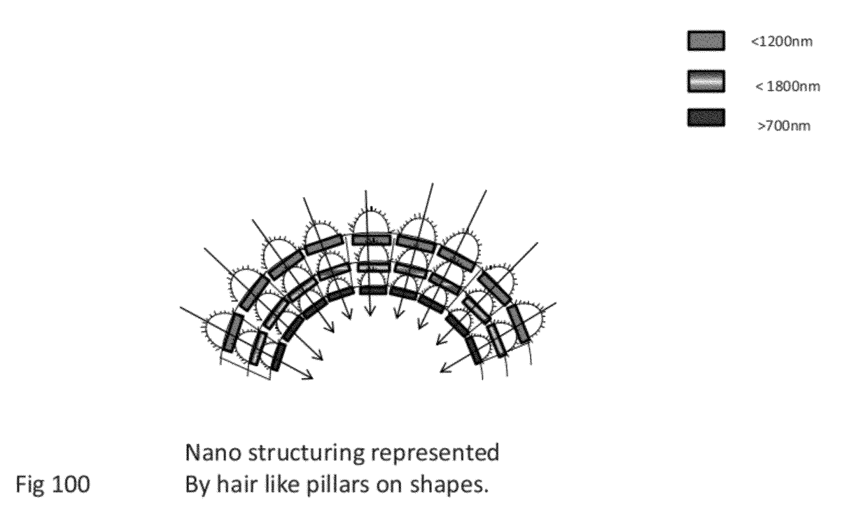

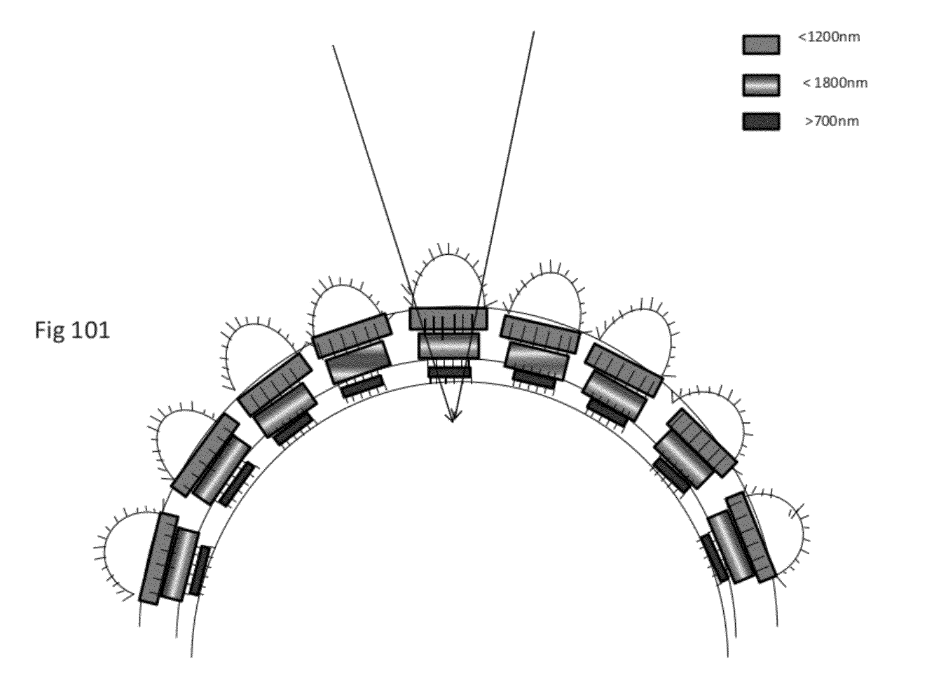

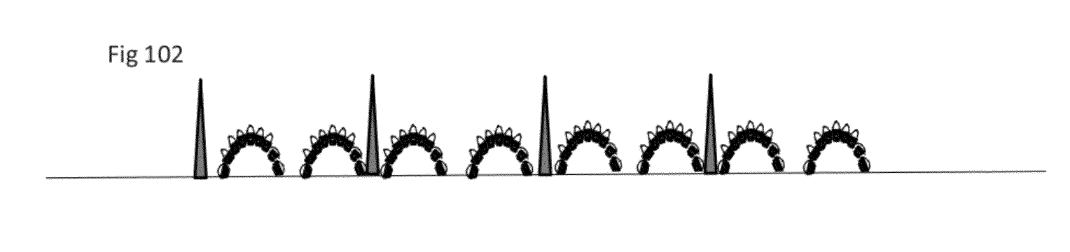

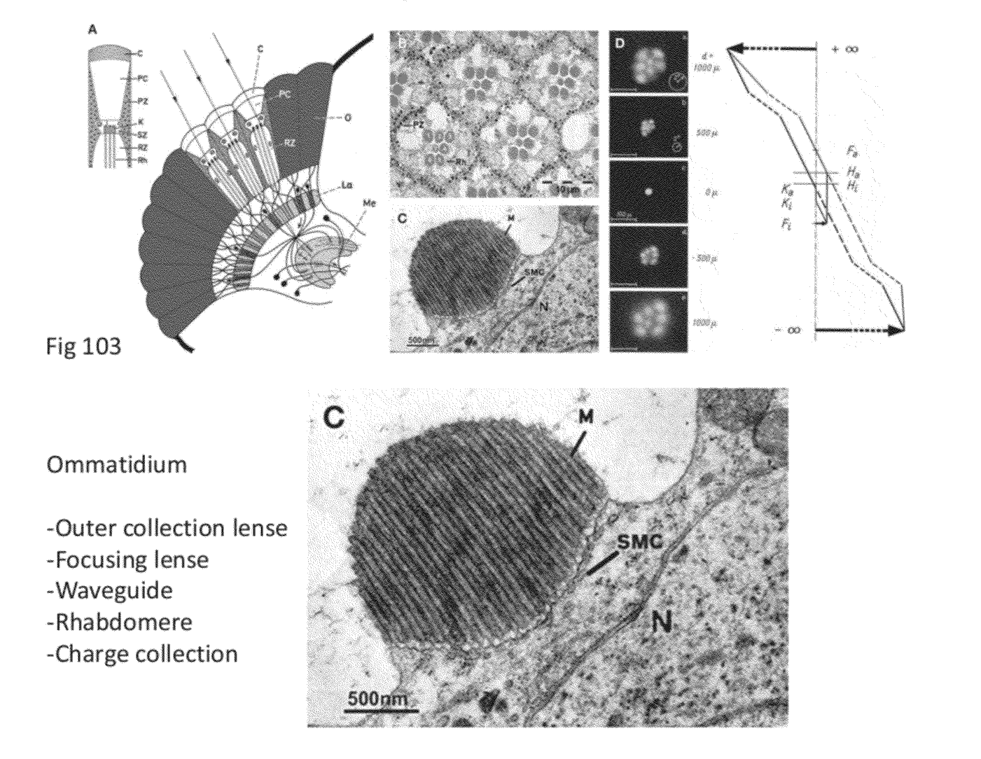

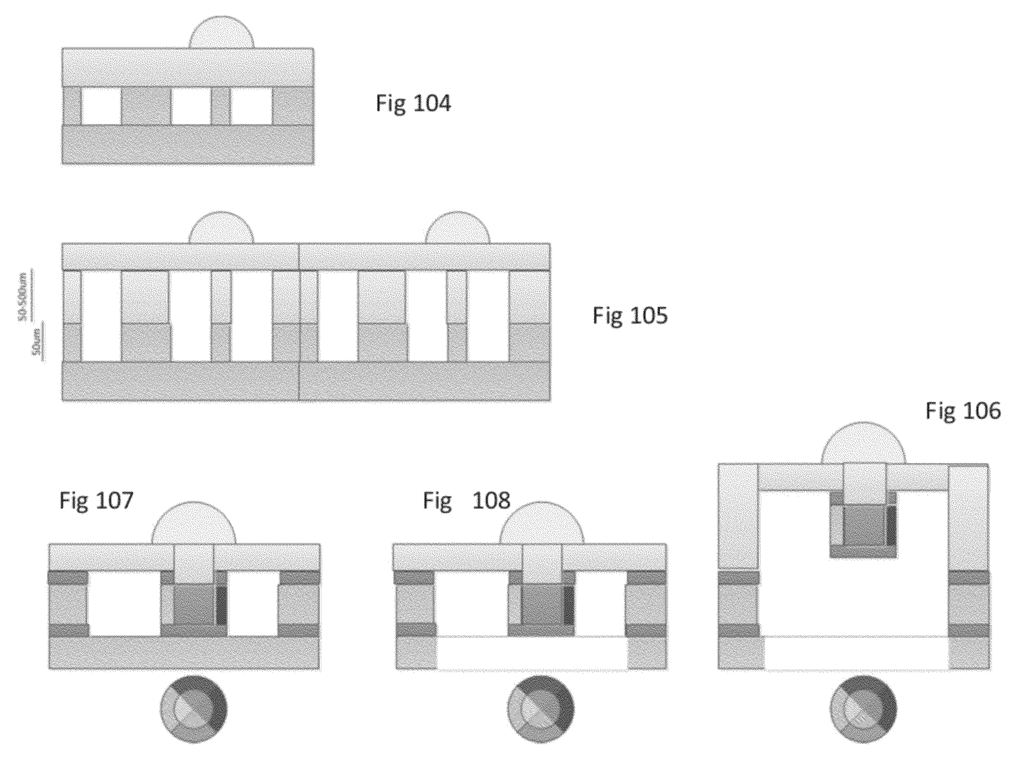

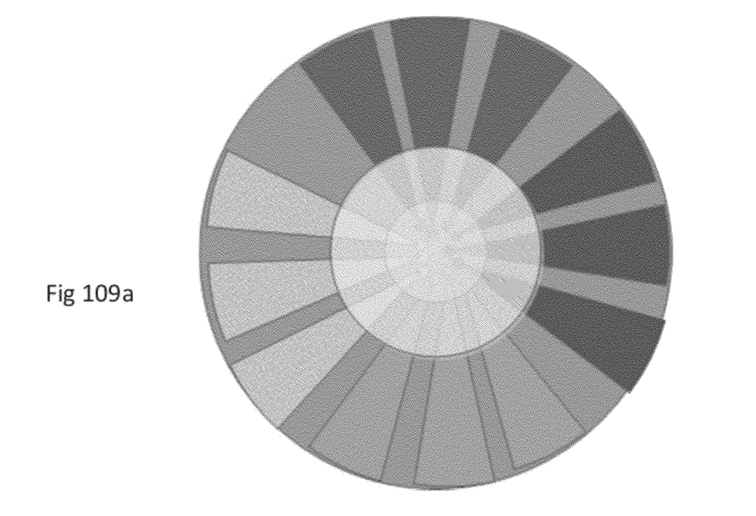

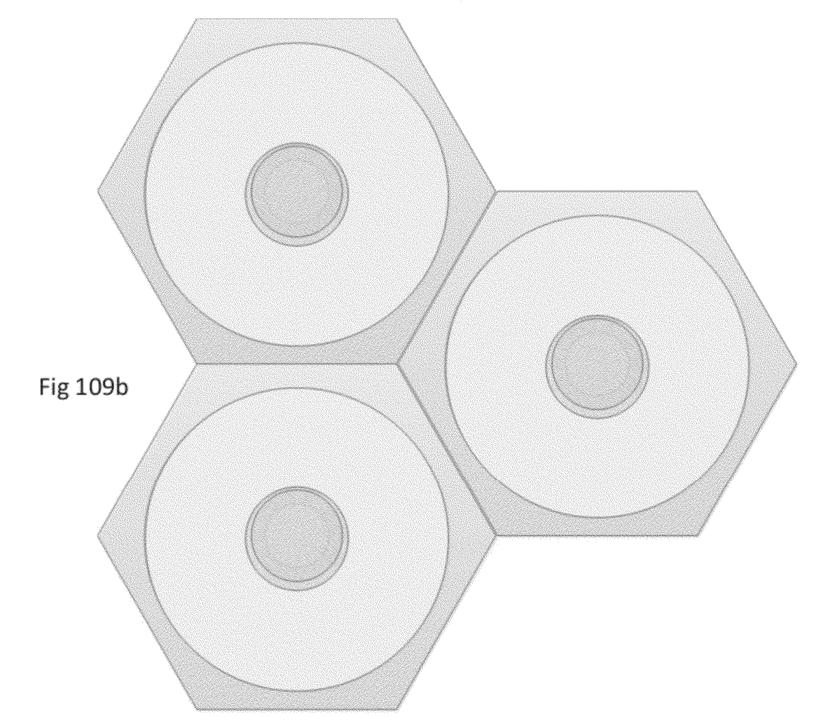

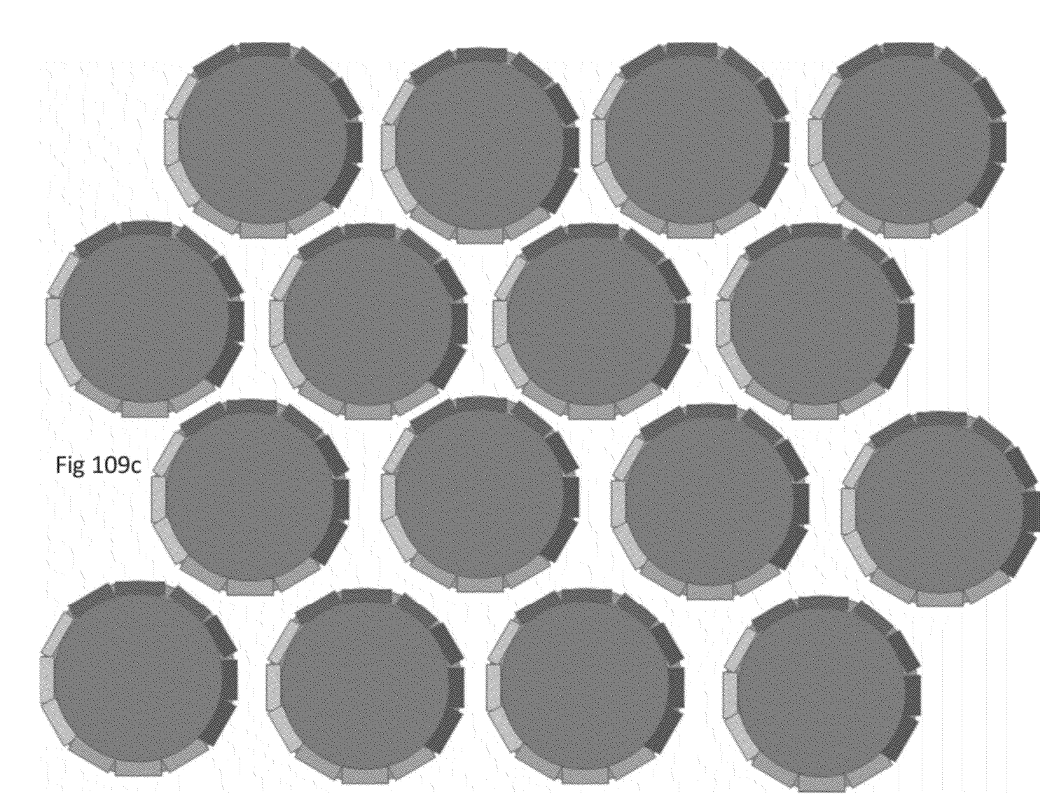

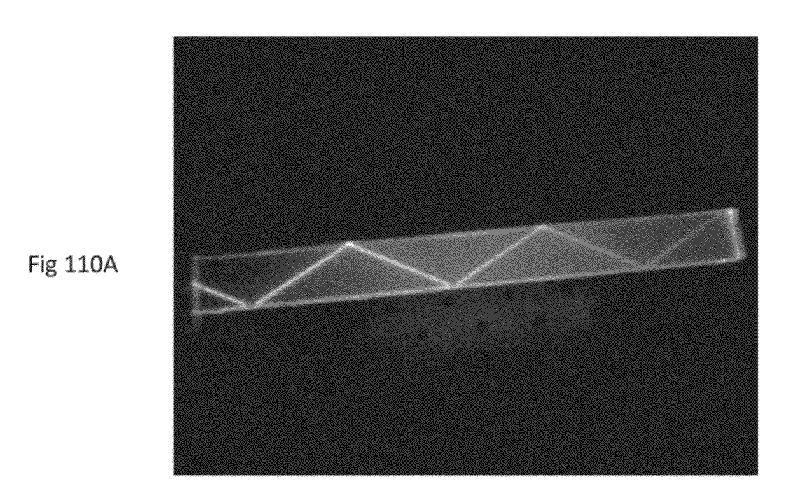

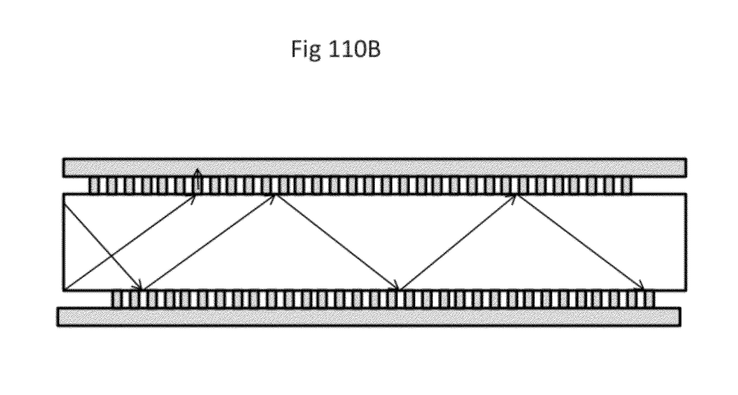

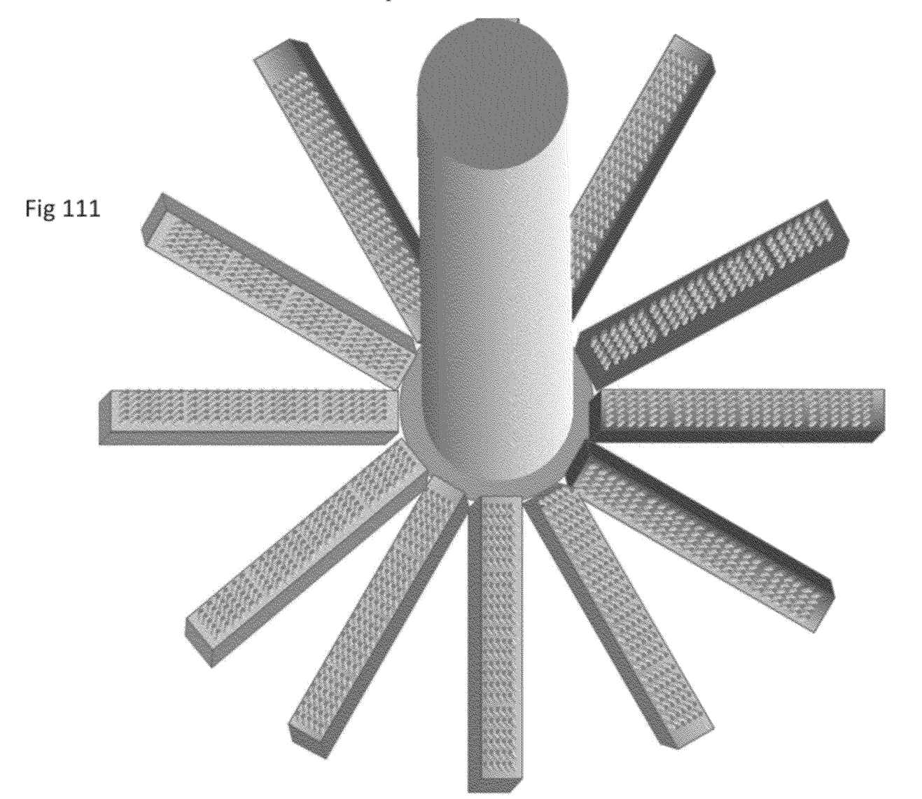

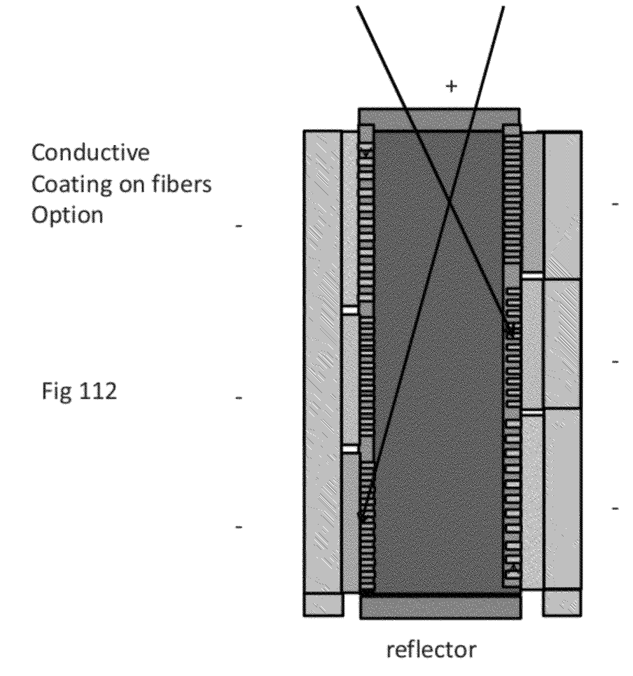

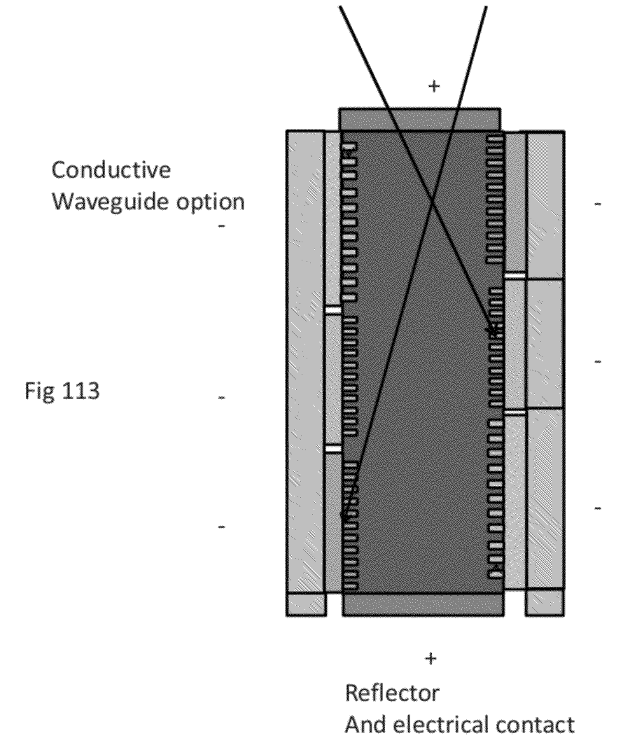

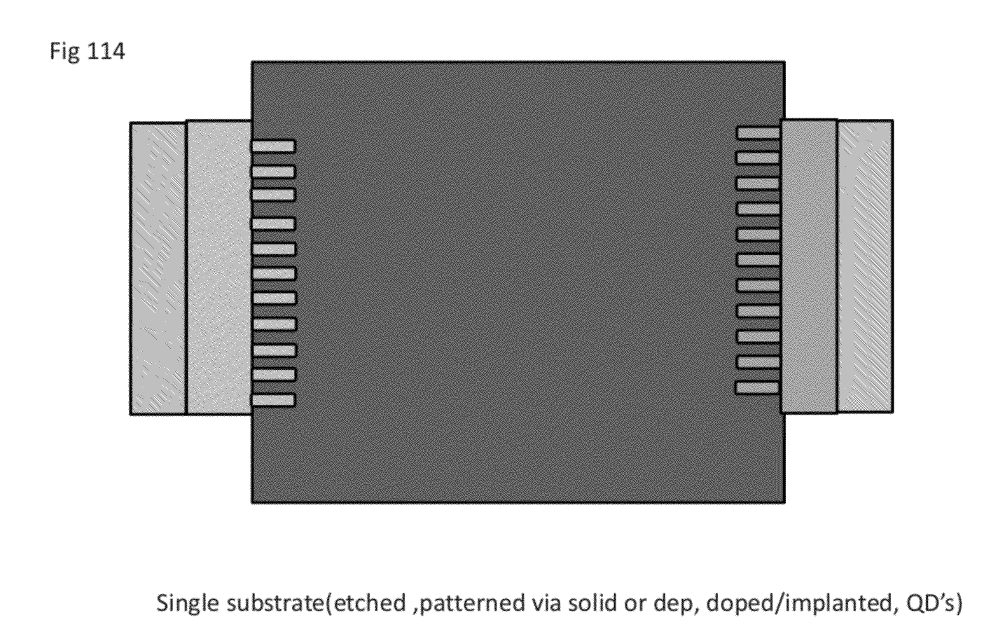

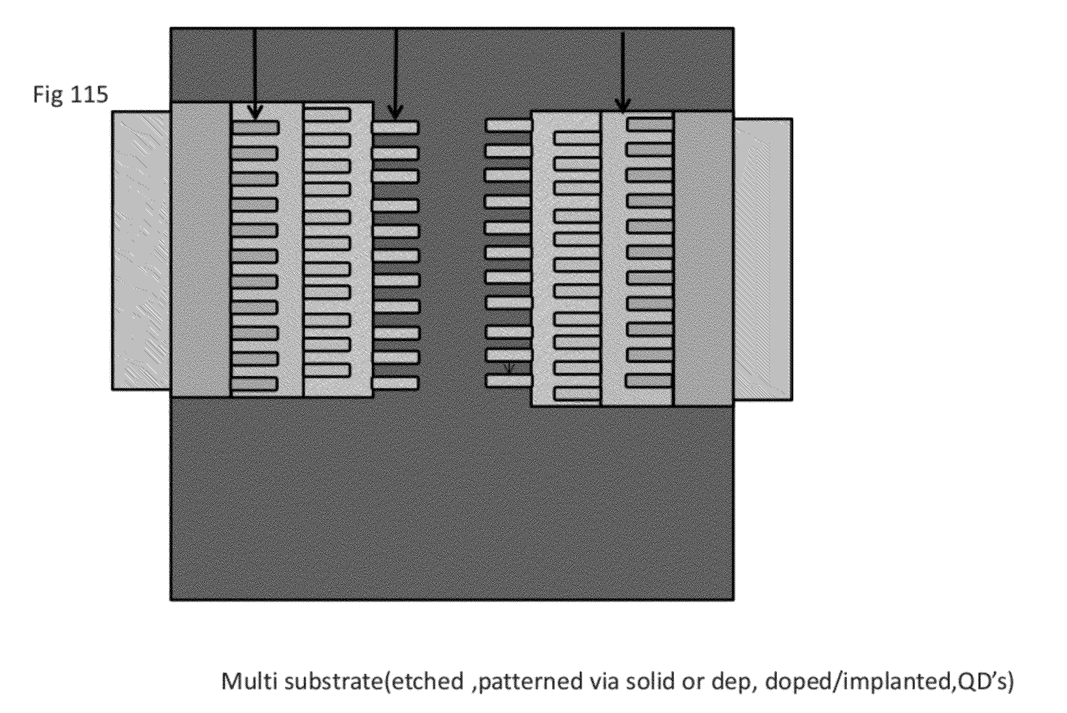

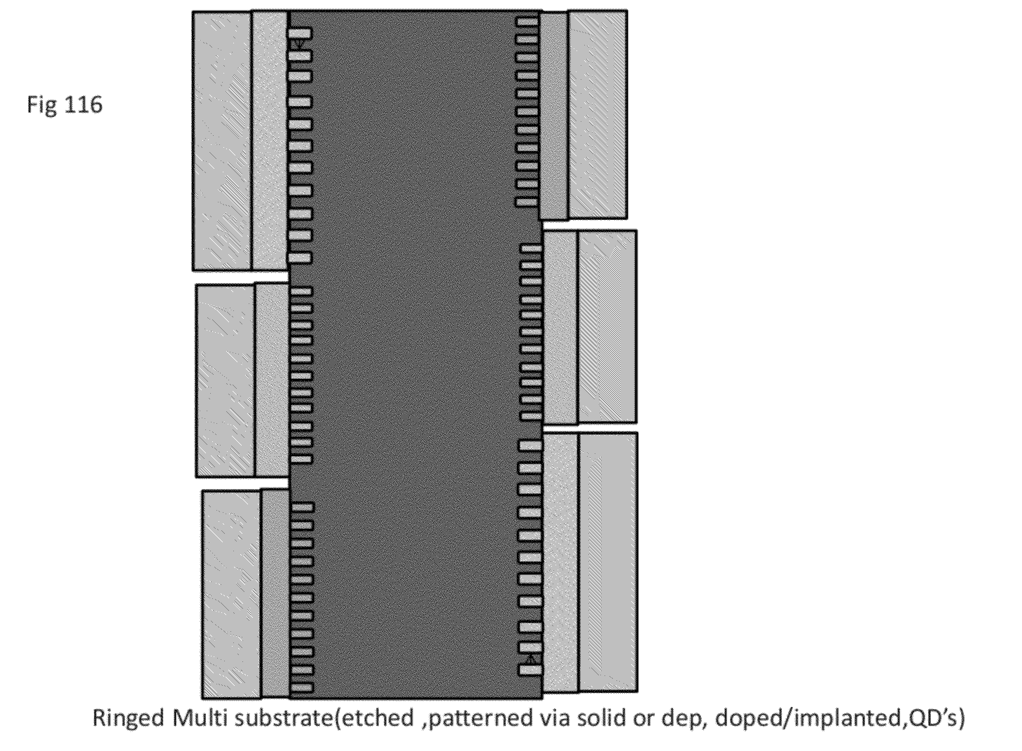

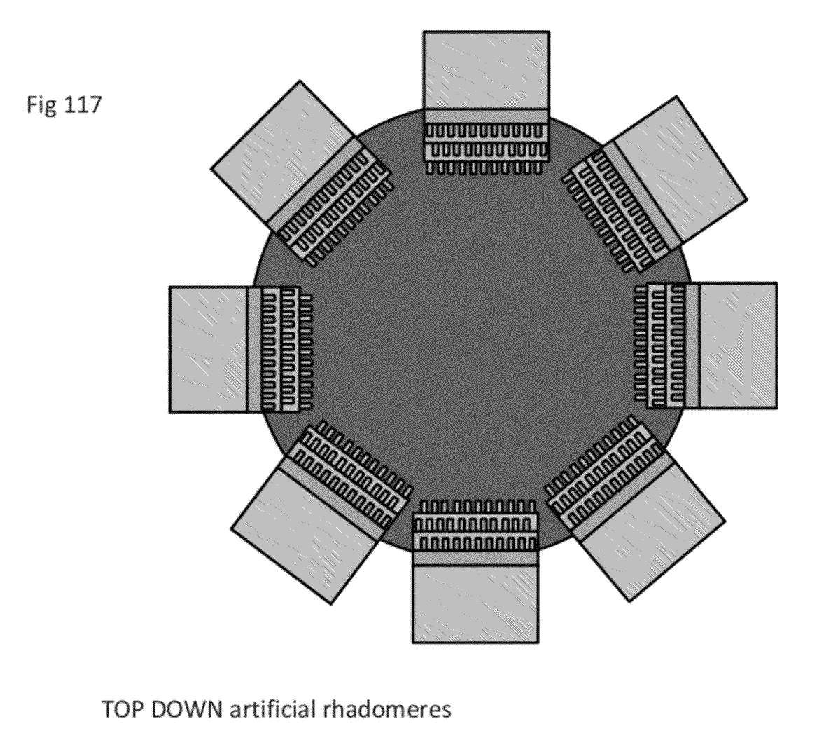

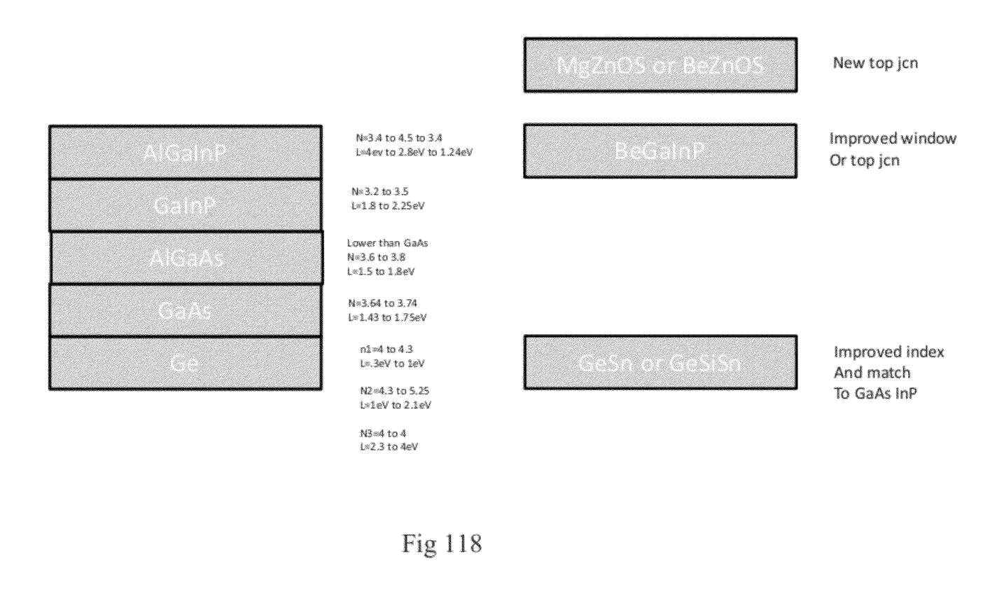

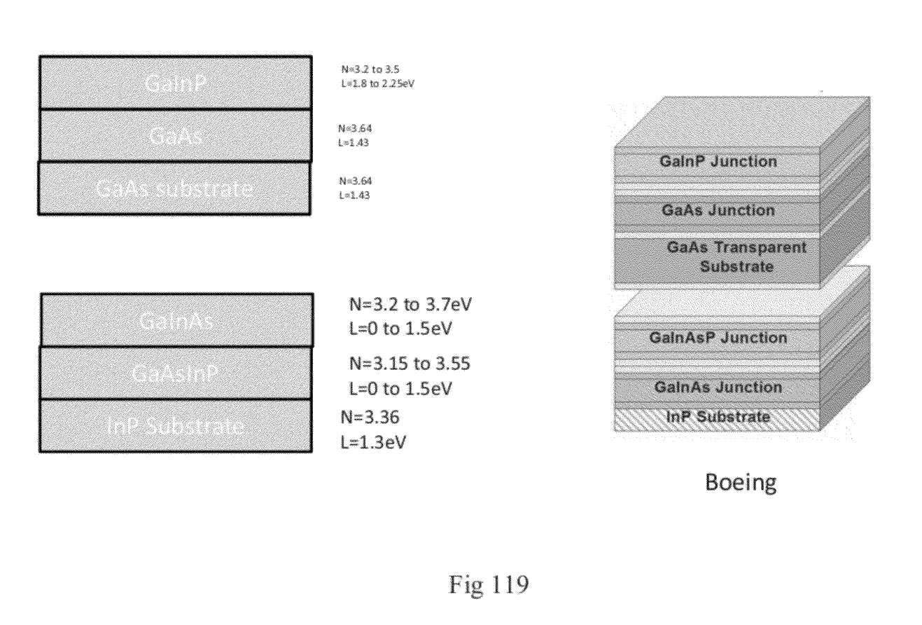

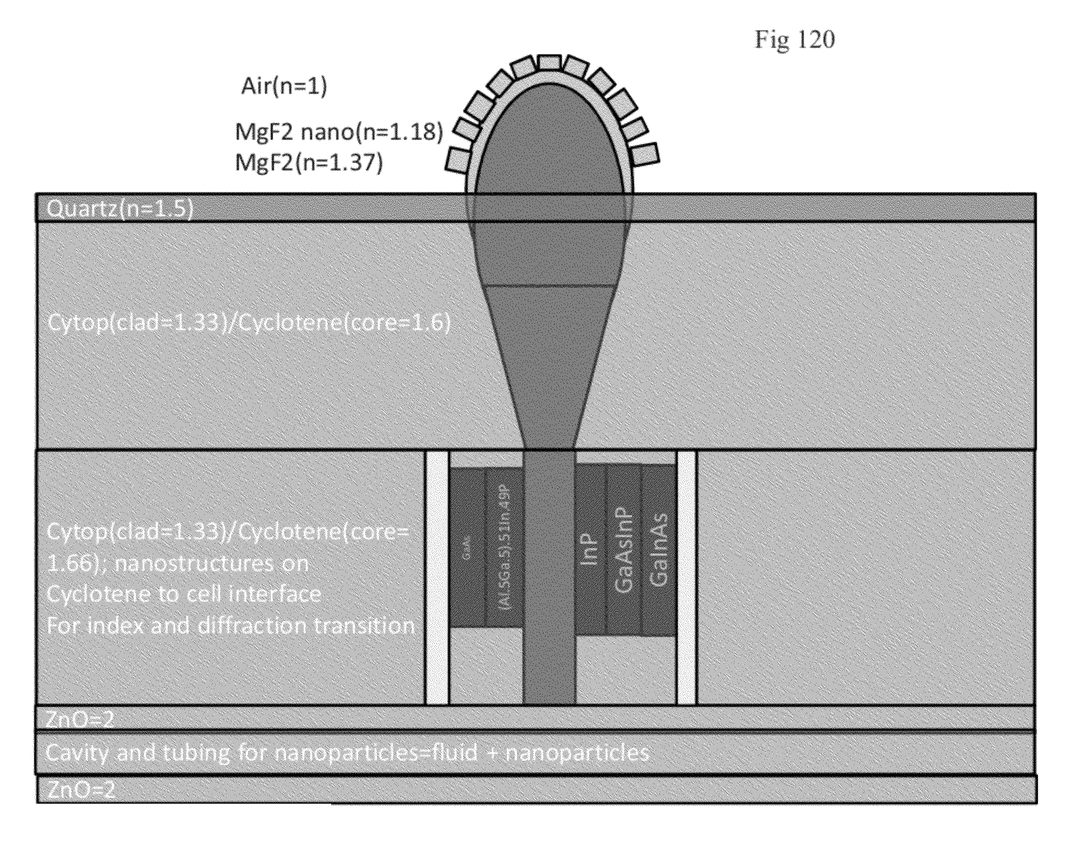

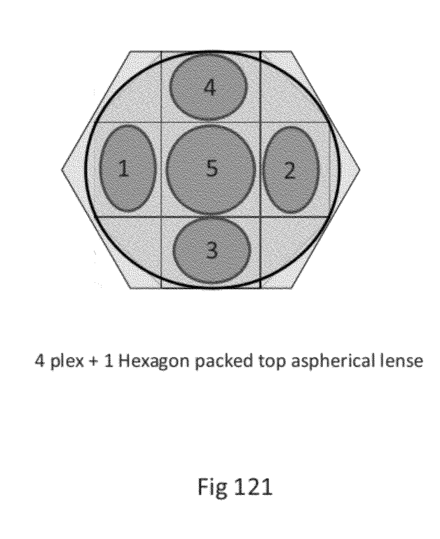

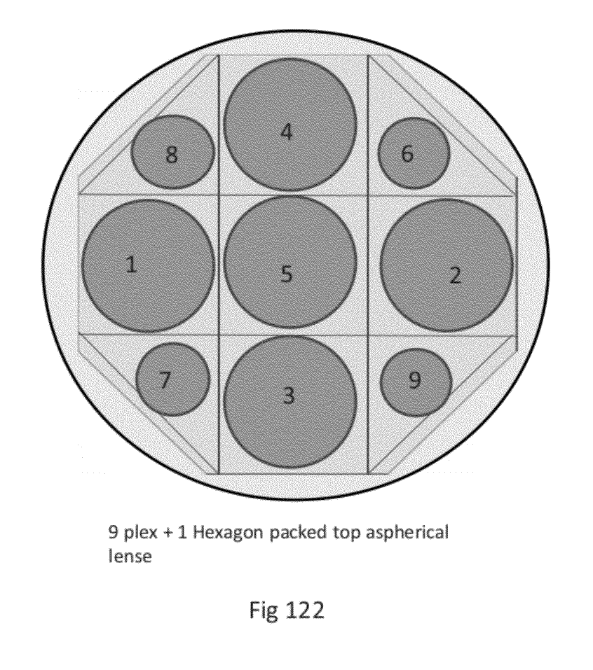

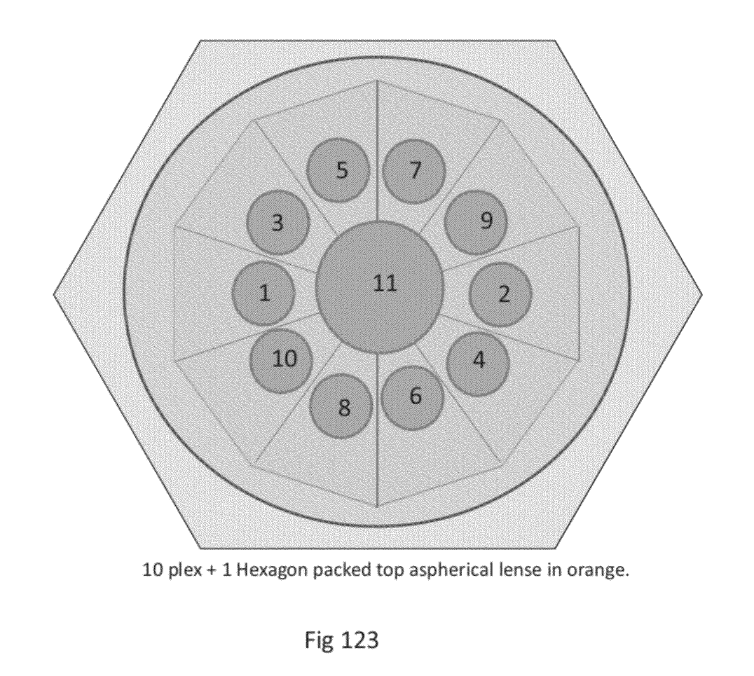

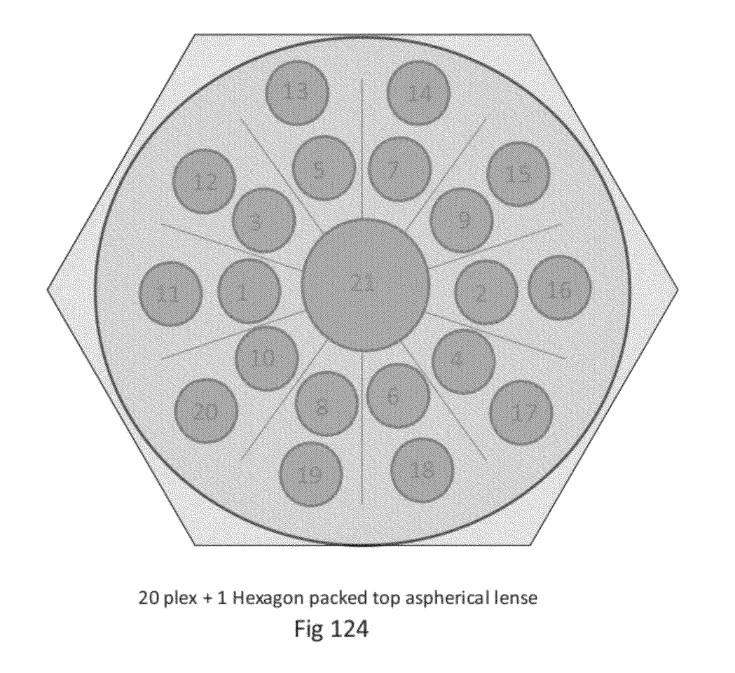

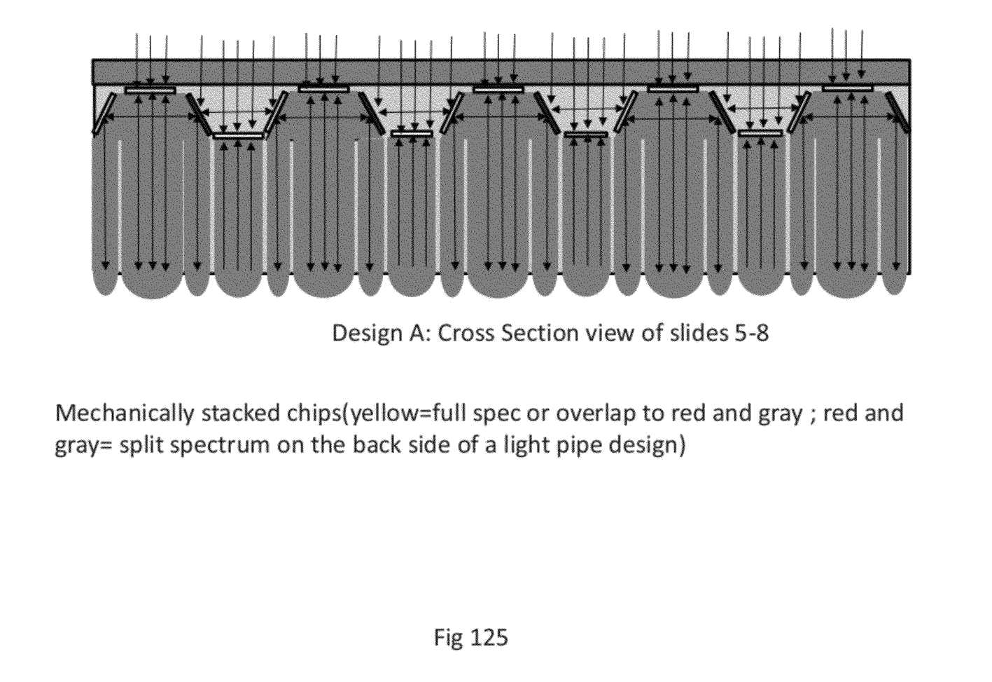

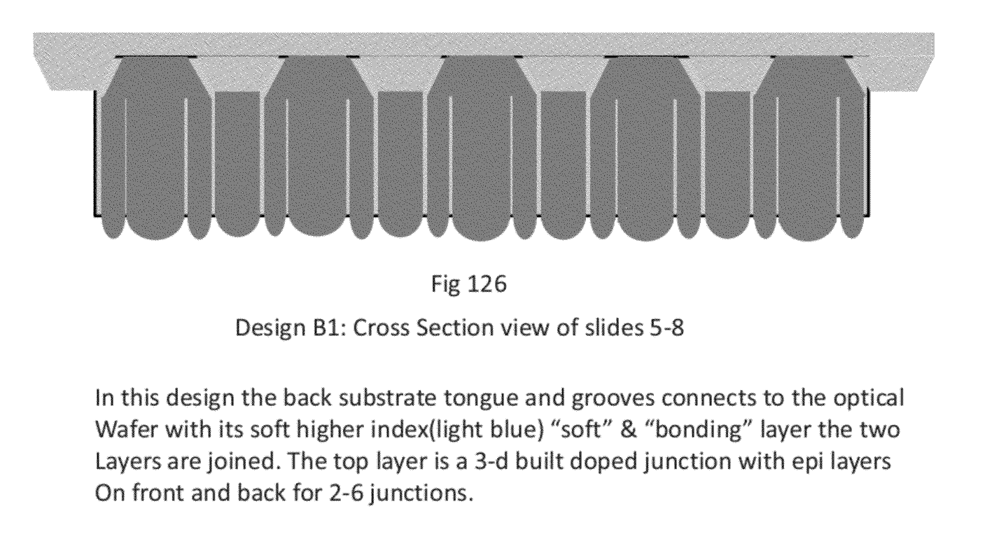

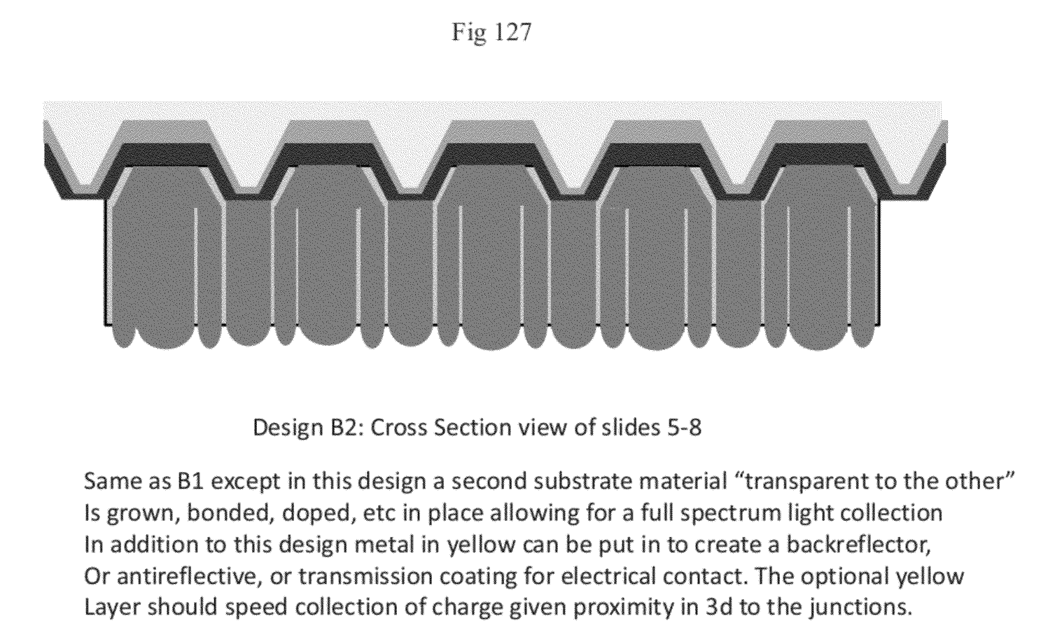

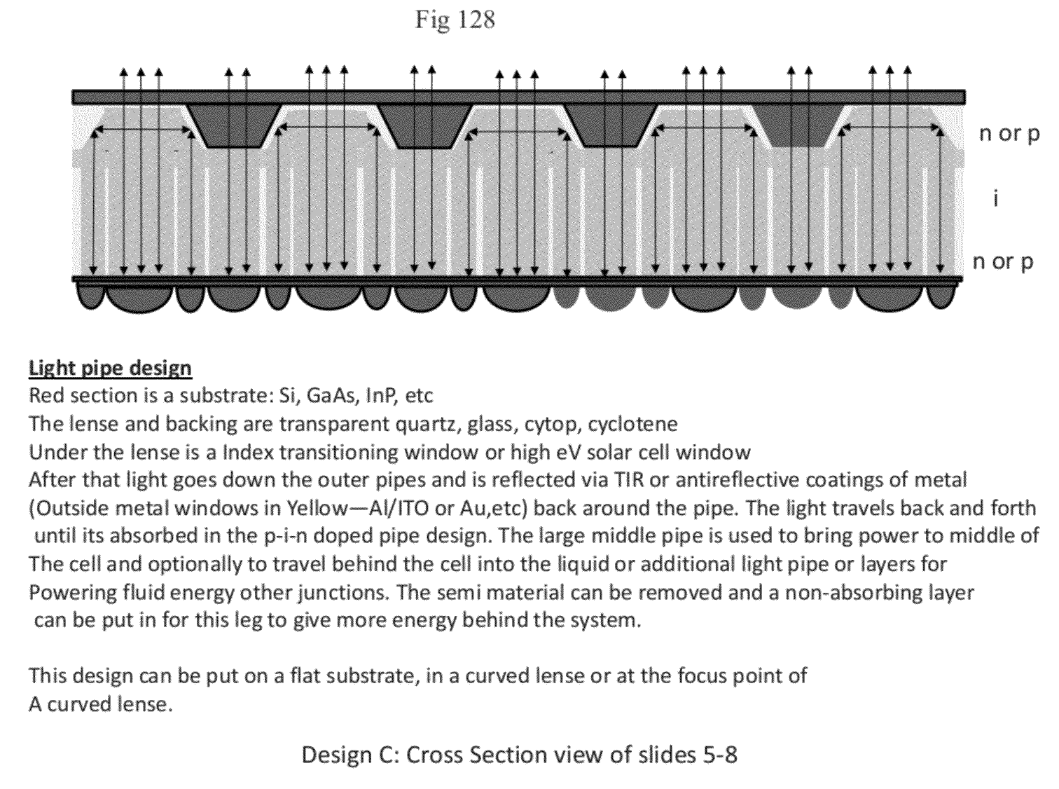

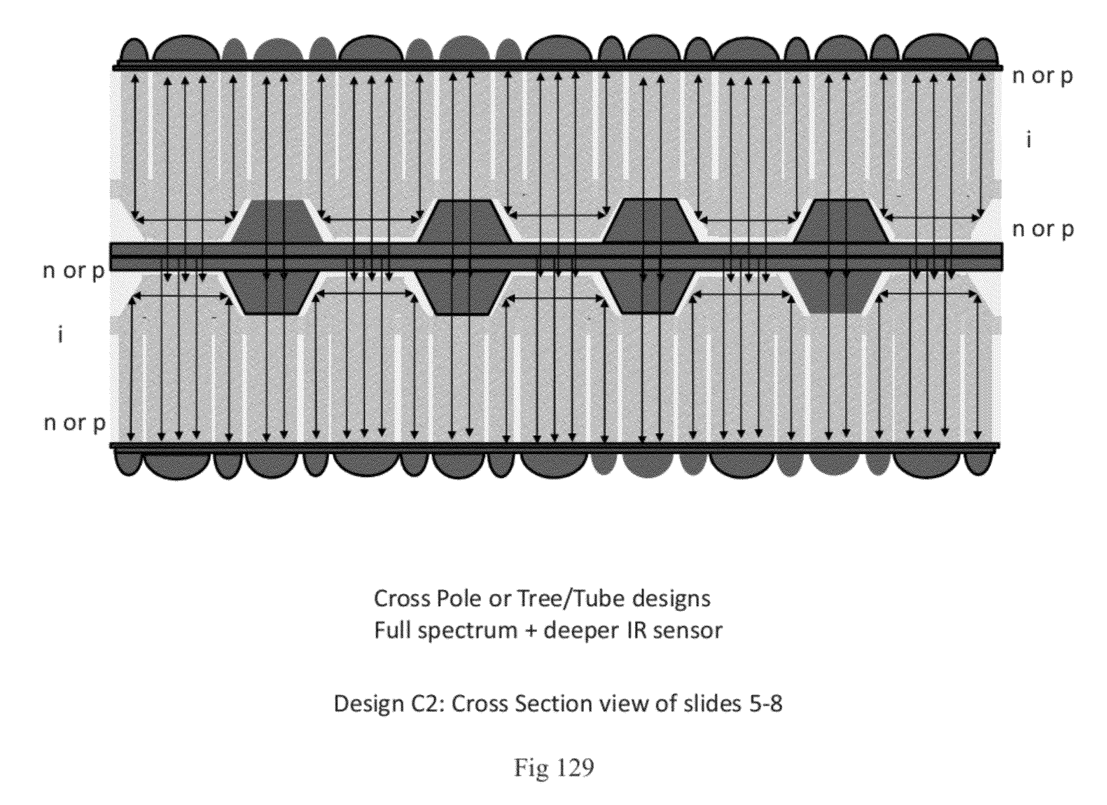

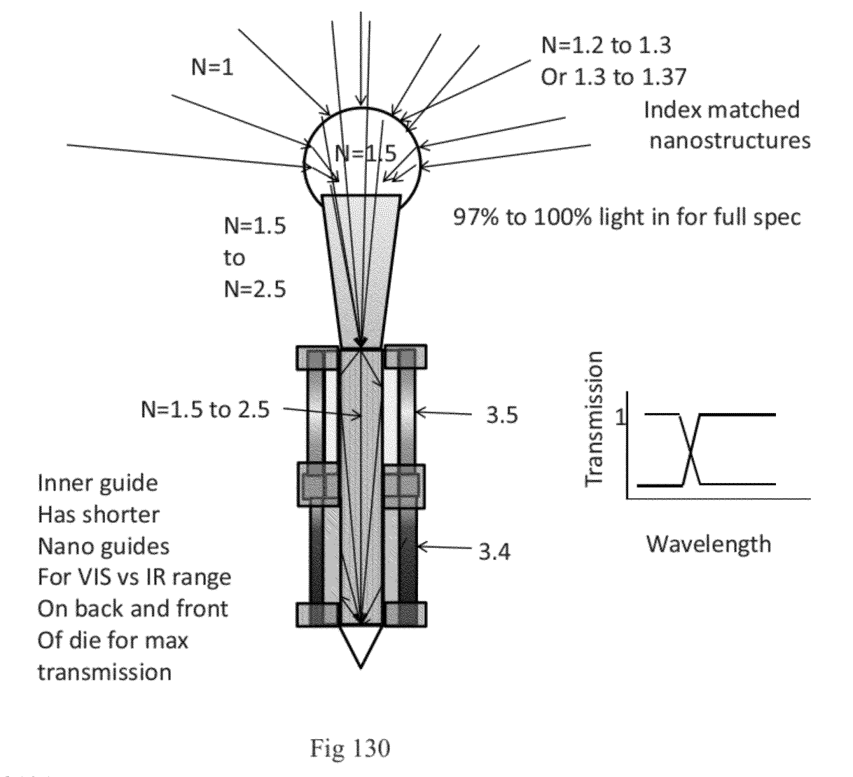

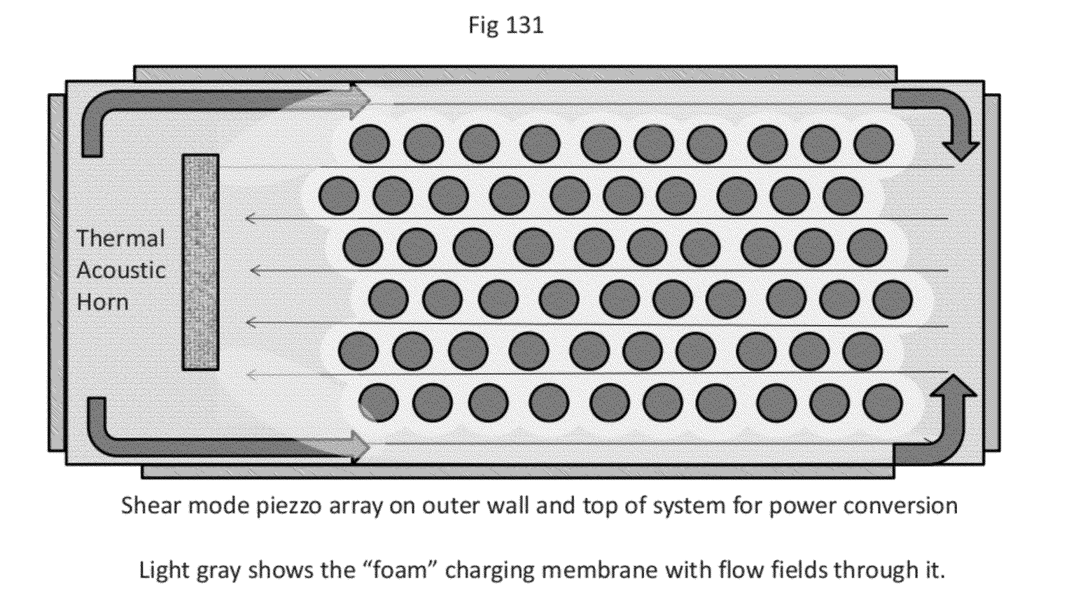

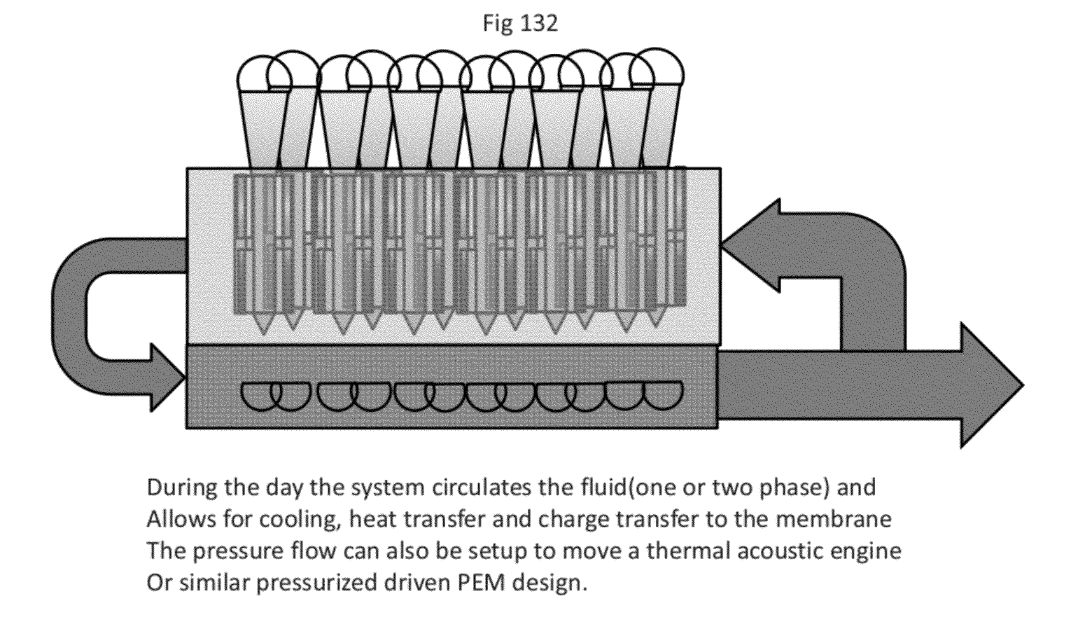

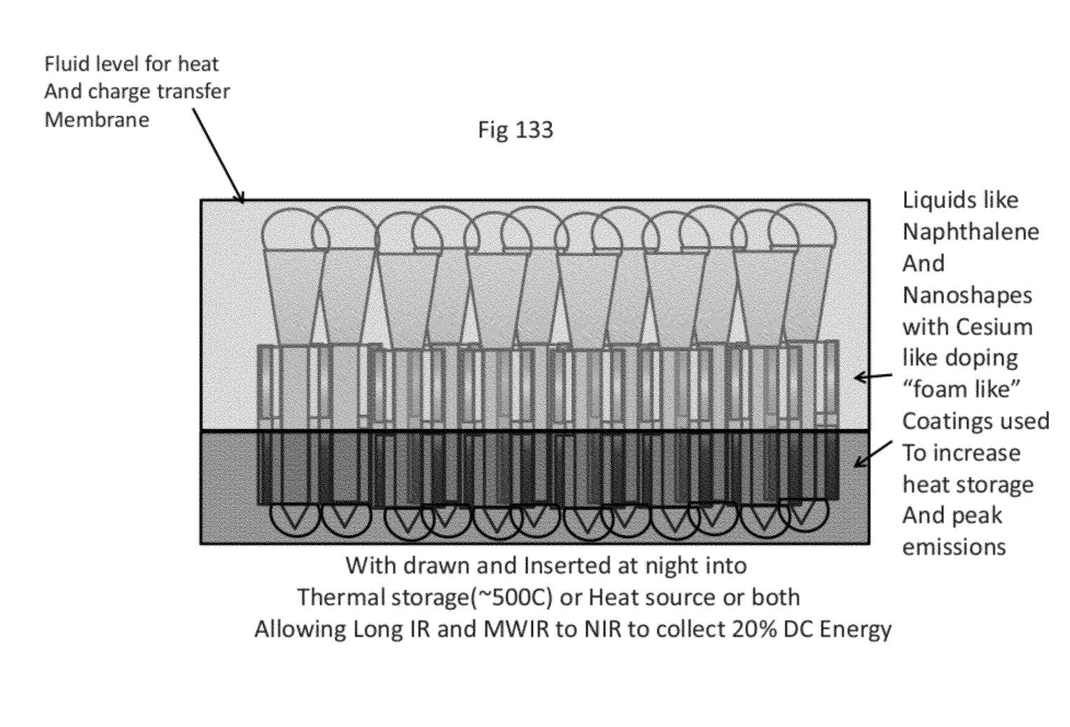

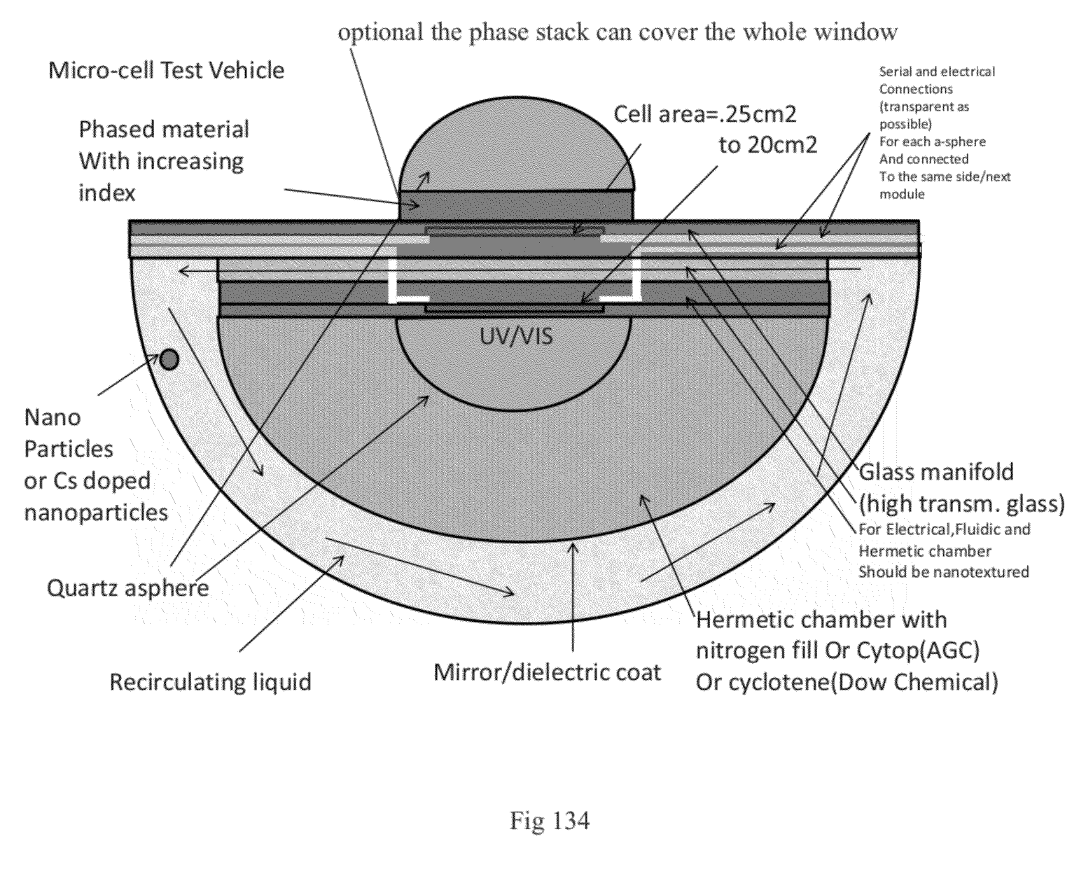

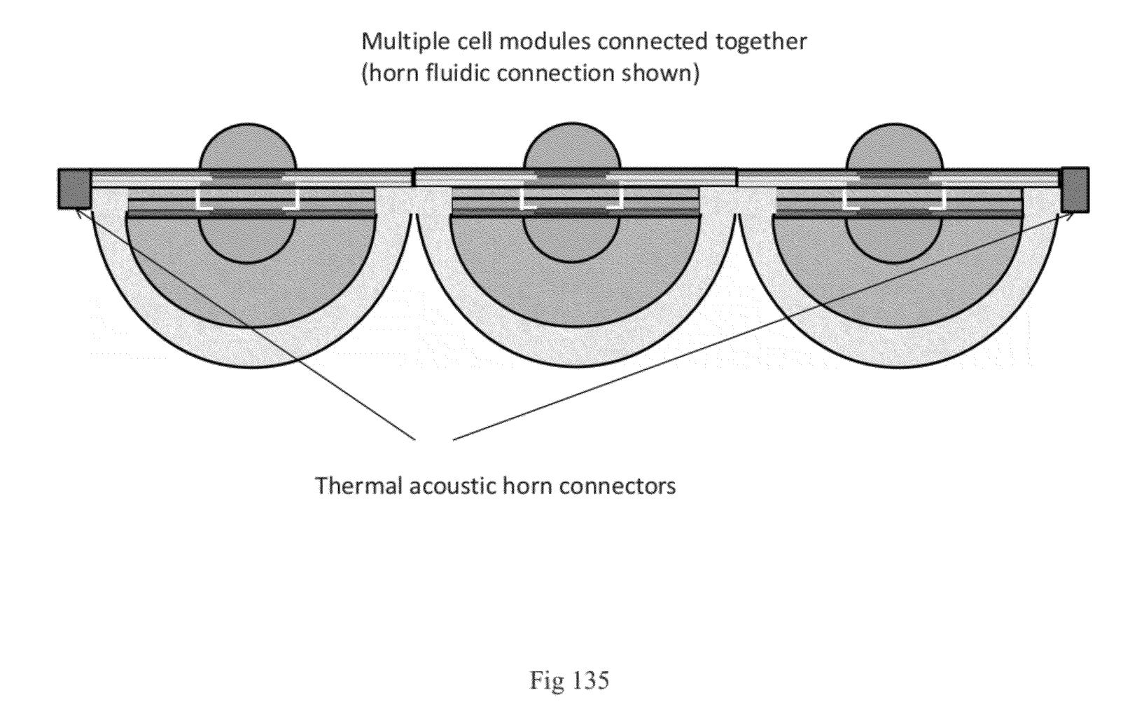

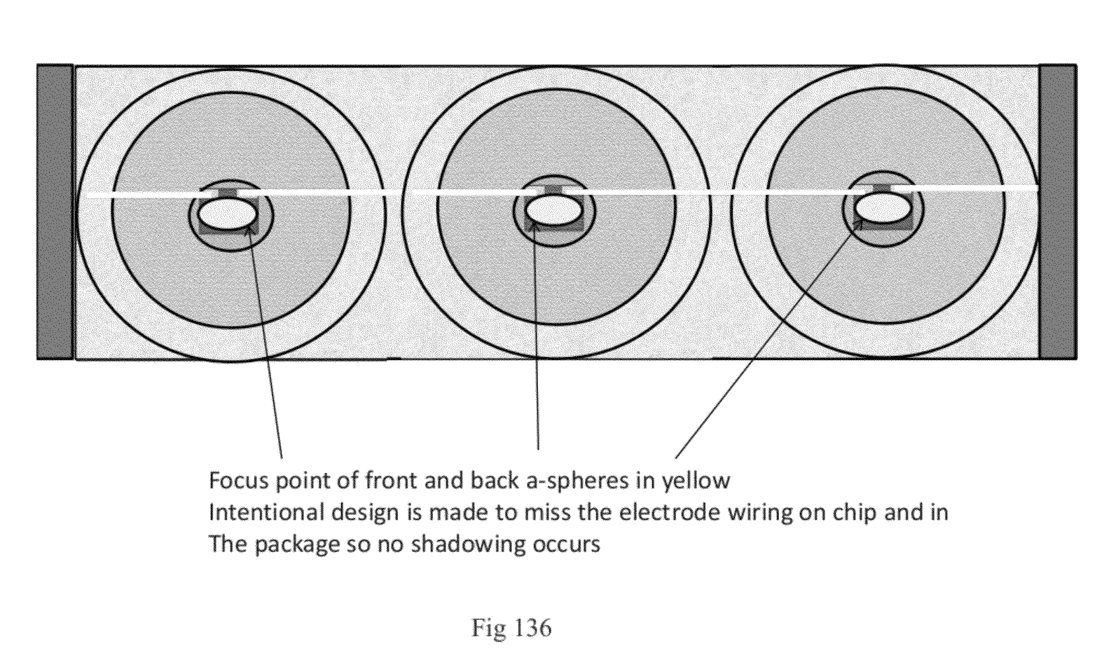

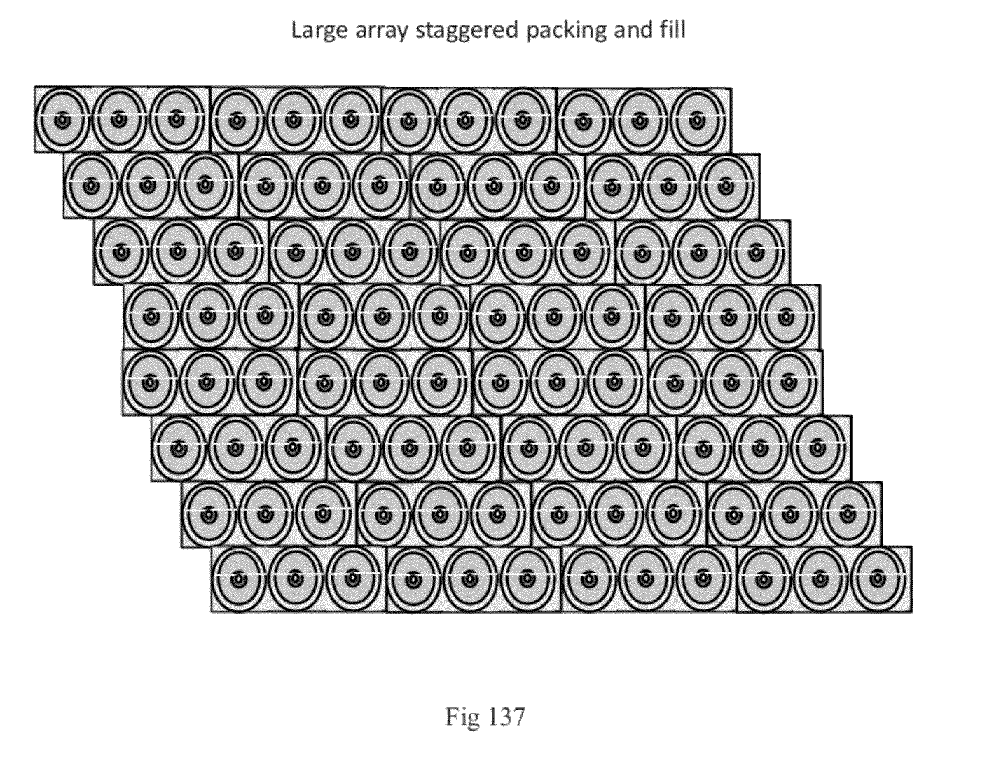

FIG. 14, 49, 57-67, 68-75, 82-86 shows an integrated lense, fluid and or solid, and electrostatic stage systems into an active or self scanning example and to compare the advantages. It is to replace the large and expensive tracking systems used in solar systems today and to optimize peak sun light tracking from sunrise to sunset. Usually large and expensive tracking stations are used to tilt mirrors or lenses all day long to optimize the amount of light into the system as compared to the height of the sun across the day sky. As noted previously the gimbaling, lense, top sides pn junction diodes for charging on the substrate or on the flexible and transparent membrane move the gimbaling and towards the side that sees the light given the charging effect creates and attraction or repulsion force to the offset electrostatic stage down below. The main lense in addition “shades” the other electrode on the surface or the membrane on the opposite side to the lense and the sun. This creates a charge misbalance that will correct and balance similar to a wheatstone bridge design as the sun moves across the sky. Effectively tracking the lense to the ideal position for bringing light into the system. If needed mirrored/reflective or (TIR) standoffs can be shaped around the sensor below the lenses to reflect the off angled steered light back to the center sensor else that light can be moved to additional sensors, fluid charging, heating, etc. This system is also used for raster scanning of the absorbing device (balls, substrates, etc below). The idea here is to minimize all wasted energy. Usually in the art people dump so much energy into the sensor that it turns to wasted heat. The device then can never overcome this limitation and begins to become less and less efficient the higher the energy flux and thermal heat it creates. By raster scanning the device you put a time domain transfer rate into this action so that just the right amount of energy to maximize the device is put in, but not so much that the device is running super hot and starts become less and less efficient. This is a core element to the active tracking invention. Allowing it to achieve in concentrated environments higher efficiencies. Additionally a larger 3d surface area of cells can now be energized that was not possible in a 2d design. As well as non-normal light would allow for a diffractive light valve (see FIG. 17) to be used for splitting the spectrum up for maximized efficiency by wavelength. Diffracted light that is not needed in hot cells would be guided into cool areas, while the needed spectrum would be put into the cells. Further the addition of the liquid media and solar balls in the lense designs allows for extremely efficient heat transfer designs (thermal acoustic, superfluid heat pipes, nanotube nucleate boiling, etc) to be implemented that not only absorbs solar energy but regulates wasted heat in the system and allows for a higher system efficiency for energy conversion. As saw in the previous art by this inventor for FIGS. 35-41 resonator cavities/“horns” with sense systems can be put in to monitor temperature and pressure in the system if active feedback is needed. Acoustic thermal pressure horns similar to this inventors horn designs that could be used with toroid shaped fluidic amplifier designs within a system of flow tubes to cool the solar cell and increase the rate of collection from charging and heat exchange techniques. In addition capacitive, piezoelectric, or other energy harvesting tube linings, or extreme surface area “fuel cells/capacitors” can be used or multi-turn coils, to induce charge flow and charge up of the materials as the liquid flows through the system. If higher pressure “horns” as are built in thermal acoustic systems are put in the system then “shear mode” designs, ala HP designs are recommended. Piezzo based transducers can be placed in a jacketed wall of the tube to allow for a large surface area with little to no drag, nanotube will be put on the interior of the tube to lower drag as well around the tube openings. As the pressure ways travel down the main tube the capillary tubes will have strong low pressure sites form and draw on the piezzo sensors similar to the effect of the wind blowing over a chimney and drawing the air up the chimney. With all of these hybrid energy solutions this energy that is absorbed into the balls and the liquid allows for then other work to be done and collected from the solution for heating water or the like to generate electricity. In the charge solution design versus thermal transducing balls this allows the full solution to be circulated and constantly kept charged getting around limitations of diffusion and making possible a very large surface area Fuel Cell/capacitor/battery/“Foam” cell design for maximum current draw in minimal space.

FIG. 95A-95E shows a series of cross pole concentration designs that allow for multi-sided light concentration into the solar transducing material or liquid with nanoballs. The designs allows for flexible materials to be created that will allow for higher multi directional stress and higher radius of curvature then possible from std thinfilm and substrated liftoff.

FIG. 96-102 shows a series of stacked active, passive, and mixed solar lense designs. In addition in FIG. 102 a standoff is recommended to allow for protection and prevention of direct buildup on the surface.

FIG. 103-117 shows a series of biologically simulating ommatidum. These structures allow for light to be trapped and with maximum efficiency pulled out of the light traps into the best matched substrates, diffraction/index disrupting structures and their substrates. The stacked nature of the probes within the probes should assist in carrier lifetime by reducing the distances.

FIG. 118-127 shows a series of biologically simulating ommatidum. FIG. 121-123 simulate the optics of such creatures and does adaptions with joined beam paths and light trapping paths to allow increased power to both sides of the cell without back and or front side cassagrein like mirrors which can decrease the packing density while increasing the concentration only for one side of the junction(s). FIGS. 124-127 show different designs in which the substrates are used as light trapping guides in 3d and also act as the solar junctions. This effective increase in path length increases the energy that is collected without increasing substantially the chip area.

FIG. 128-131 shows a columnar system in which light is trapped similar to FIGS. 118 and 127. The rods are contained in a system in which the lense and rod can extend and retract to allow for energy collection in the day (light) or at night (heat). The system can be designed with energy regenerative systems such as thermal acoustic horns, pressurized pem membrane like fuel cells, foam like charged membranes with liquid in them and balls. These systems allow for fluid to be recirculated and to gain higher system efficiency. The liquid that is heated in the system can be used to drive steam generation at night In addition the system can be evacuated to allow for a charged membrane to act as a super capacitor to balance the energy being produced at night to increase the available power to the system.

FIG. 132-135 shows a hybridized cassegrain design in which a cross pole design is integrated in front of the main concentrating lense. In addition thin lenses are put in to allow for cheaper cost and more junctions (>4 jcns) this effective reflective/refractive optics design allows for higher power density and higher optical efficiency than a std 2 stage cassegrain reflective mirror design. In addition the liquid and regenerative system allow for higher system efficiency and higher power density per module. This design effectively should increase the power output by 70% of a std single cell design. This will dramatically lower the LCOE of the system and make it cost competitive with natural gas systems.

### TECHNICAL ADVANTAGES

The lense itself absorbs energy, whatever is not absorbed inside the shell of the lense, or the outer coating of the lense, is focused or reflected onto either a second transducer or the particle (shapes) in solution, or the particle (shapes) and a 2^{nd} or additional transducers. The design is meant to couple a hybrid solution for collecting energy between semi materials, resonance heating, and/or charge collection, or a combination of all the formentioned in some set. The designs unique vertical hybrid coupling of several methods of solar transducing allow the vertical stack of transducing methods to be tunneable given each system (lense coating, balls (shapes), non covered wavelength sensor) optimally as a set to have different ways to optimize them independent of the other, grabbing more energy than they can separately. In addition for the fluid filled cases, and the active staging designs the additional sensor(s), which normally, are thermally limited from achieving optimum solar cell efficiency can be kept cool and the input energy can be rastered at a maximum rate for energy transference of the system. In theory vertical wall space or greater horizontal area/volume can also be used in a 3d design to pack more charge/heat creation capability into the design since the rastering lense can move the light around on a wide angle. This allows for fluid vs the additional sensor(s) to be heating multiple channels of different transducing, thermal conductivity, and charging to be energized or waveguided away to do other work and not wasted as is done in macro systems. Finally the lense on the stage in this design as well gets rid of the need of tracking. See FIG. 14, 49, 57-67, 68-72 for an example design. Thus a gimbaled lens system will track passively (gimbaled arms are charged as light hits diode structures on their support structures versus shadowed sides don't receive as much energy causing a miss balance in charge creation on the arms. This difference of voltage then in opposition to the electrodes below the lens stage have an electrostatic force that will realign the stage until the voltage ratios (ie optimal angle to get the maximum energy into the lense) are balanced in the gimbaling arms. As the sun moves across the sky the gimbaled lense rebalanced the pull of the charged diode designs above with the electrostatic bars below automatically. This prevents the need for programming and complex electronics. Else if needed and more complicated tracking is need the electrodes and the gimbaling can be actively energized to tilt and move the lens around to optimize energy transfer. Besides electrostatic comb structures a pull down design is additionally contemplated to tilt the lense when the diodes on the arms are charged.

FIGS. 15-94 depict additional preferred embodiments of the invention.

FIG. 95A addresses the use of FIGS. 1-94's design concepts. In this design a dual mated lense design is shown in which a solid or fluid lense, or combination thereof will focus light into channels from both sides of the design and or one side being a reflector. The design allows for an increase in concentration, additional energy to inputted into a stack of cells that normally could not be mated together due to stress mismatch. Additionally the balls between the system collect energy that is left over and turn it into useful work to increase the system efficiency. A design such as this is contemplated for a plate or cylindrical structure. In the case of the cylindrical structure matched pairs of lenses will fill the outer interface to maximize light input into the core.

FIG. 95B adds to the concept of 95A and previous designs with allowances for ways to prevent light shadowing of the electrical interconnect in the packaging other than light focus of the lense. Additionally it's noted that rather than a solid substrate lense or segmented chips as in previous designs. 95B suggests the use of semiconductive solar strips, nano to micro layers, or other structure patterns to allow for multi-axis bending of the materials that normally could not be bent in more than one axis unless deposited originally in that shape as is the case with the lens designs in previous discussions. Additional the exit port of the system has three optional fittings. Either a 2^{nd} lense port, a reflective port of Al with nanostructures, or a Al/Ag layered structure with or without dielectric layers assumed as options in such multi metal layered reflective structures.

FIG. 95C allows for tongue and groove assembly of round or patterned substrate materials of nano to micron sizes.

FIG. 95d allows for multi band solar cells based on single pass or dual directional light piping in the stack. The left drawing shows single directional light guiding. While the right 4 junction and 2 junction designs per path show multi directional and maximum packing density.

FIG. 95e shows a vertical tube design with different dimensional structured guides with the option of each guide tuned to material bandgap across the solar spectrum or having structures attached to these guides to absorb in a range of the E&M spectrum. The vertical structures should allow for maximum bending of the design. Light will be guided into each of the guides and into the top and bottom cells that cover the guides.

FIG. 96 shows the concept of stacking curved substrate carrier or substrate based cell. This allows for maximum angular light collection and addresses the challenges of stress and power balancing since cells can be maximized per layer.

FIG. 97-99 address different configurations of FIG. 96. In FIG. 97 there is only one lense and there are gaps between each cell underneath this lense to allow for cooling, heat transfer and energy collection by the balls in the fluid. FIG. 98 allows for tongue and grooved recepticles and dome lenses to be mated together with separate cells per lense. This effectively makes possible a mechanical alignement and a greater in line magnification with each stage. Finally FIG. 99 shows a direct bonded stack of nanostructured materials or attached with materials such as cyclotene between cells. This design allows for maximum heat transfer between cells but is challenged by mismatch in stresses and power balancing that may occur.

FIG. 100 is a system sketch of a domed structure with FIG. 98 design attached to it. Inherent to this design is the option for any or all stages to have active stage control to optimize light into and through the system electronically or with a hybrid passive charging diode structures per level.

FIG. 101 is a system sketch of a domed structure with FIG. 99 design attached to it. Inherent to this design is the option for a stage per lens to be moved hybrid passively with a diode feedback action or with active electronic stage control or pulled downs to optimize energy delivery into the shell of the system and secondary targets.

In FIG. 102 the design purposely optimizes the placement of transparent standoffs to prevent mechanical damage, dirt build up and water to the lenses. Additionally this is to aid cleaning of the system.

FIG. 104 through 108 show a method of putting in place self-aligned lens's and waveguides to cells via pre-patterned substrates and or post lamination evacuation by etch of the underlying substrates. The simplicity and ability to foot (pattern in the stretcheable material into the substrate or on the substrate in some locations but not others creates a quick and reliable means to mfg 3d structures similar to the eye of an insect.

FIG. 109a shows a 3d stacked kaleidoscope/pizza pie like design for the structures on the outside or stuck within the guide for light trapping and transducing. Such a structure allows for greatly increased efficiency and low loss since the layers are so thin and large power absorption given there are so many connections. It also lends itself to get around the shadowing issues that currently exist with std cell design that has a 5-10% loss effect on power loss in most cells.

FIG. 109b shows the hexagonal dome shaped packed structures that will guide light down into FIG. 109a.

FIG. 109c shows the top or bottom of the guide for FIG. 109a prior to reaching any of the absorbing layers. But showing the externally connected substrates and or electrodes on the outside of the guide. This design shows a strip like design of the substrates or electrodes. In later embodiments rings by absorption band stacked vertically on the outside will be shown. Additionally tree ring link stacked multi-junction like structure designs will be shown. In some cases the later design will have substrates split between different holders such two rings will be needed since the passivation and coatings will be different on each ring to optimize absorption. This is done in additional to minimize stress mismatch of the materials on these flexible curved shapes.

FIG. 110 shows std TIR transmission of light in a guide

FIG. 110B shows a cross sectional concept of this concept for light escape only where energy is to be converted.

FIG. 111 shows a 3d view of FIG. 109C pre assembly of the strips with the tens of thousands of planned electrodes to touch or enter into the substrates.

FIGS. 112-117 address the differ combinations of waveguide core, electrodes connections and stacking options for the simulated rhabdomere structures to be connected together by and for different options of the nano to micro structures to sit adjacent, stacked, or interdigited on the substrates that touch or go into the guide.

FIGS. 118 and 119 address short falls in the junctions in industry to date and suggest UV to blue junction/windows as well as splitting up IR and VIS junctions to maximize performance and allowing for ease of assembly with better known processes as show in FIG. 119. This should make possible 40-50% efficient thin junction systems and 50-60% percent efficient thick junction substrate systems to be possible.

FIG. 120 addresses a simple adaptation to FIGS. 110 to 117 by showing the outer lens and one of several liquid guide options for the exit of the lightpipe.

FIGS. 121-123 look at different lightpipe guided structures based on the concept of the insect eye and the original 3d shaped junctions and epilayers of FIGS. 1-94. In the design space is left for a main lense to heat through to the backside where fluid will be and or for allowing pressure to be placed on the manifolds to be drawn down or pushed up to “package” assemble the chips or 3d solar junctions to the face of the light pipes. As saw in FIG. 124-127 adaptations are introduced that allow for light steering from multiple paths into a cell to increase its power absorption capability. In addition on FIGS. 124-127 reintroduced is the tongue and grooved bonding options, with or without cyclotene adhesion materials, and the use of pressure drawn and stretchable materials to pull down or push up solar cells into the proper faces of the light pipe walls to allow for assembly of a 3d solar cell structure that normally would not be possible to assemble at this scale. Also the option for thicker substrates with epi layers deposited on them with non-planar mesa's is shown to allow for tongue and grooved assembly to the walls of the lightpipes and or their adhesion layer like cyclotene. This again is to address the challenges with stress and assembly that make 2d assembly impossible for such designs. Of note fluidic self-assembly could be used by singulated chips with tongue and grooved shapes as an additional fall back for these shapes only.

FIG. 128-131 is an optional design that allows for a retractable system to push and pull the IR (bottom portion of the design) down into a heat source or the storage structure that was heated during the day to allow for around the clock power collection. Such a design allows for a larger macro or micro scale system, charging, thermal acoustic, and other recovery designs to be added. As suggested the fluid in the system can be changed allowing for inductive charging and a vacuum barrier to be created to maintain heat in the inner system. In addition the gases then heated from below in the system can be used to drive the horn assembly and compliment the power gained by the IR cells during the evening.

FIG. 132 through 144 shows again the concept of the hybrid fluid, cross pole designs. In this case a cassegrain dish is put under one side of the cross pole design. In addition a phased extender plate or standoff is considered to increase the concentration from light on the front side of the device. The purpose of this design is to improve on the losses of the std cassegrain design's multiple reflection losses. Only one large dish and reflection occurs in this design. This mirror is optimized therefore for a larger window and higher efficiency than the std aluminum mirror design. In addition the outer glass to take advantage of the improved mirrors and refractive vs reflective advantages of the cross pole design have broader spectrum and higher transmission glass with nanostructures put on the front face. On the backside of this glass low cost large area UV solar cells can be placed to ease the needs on the spectrum and efficiency of the mirror below. Optional lenses are contemplated to cover move light around the electrodes in the design and liquid pipe if is so desired. This design allows for a cheaper design given the thin cells, with much higher power output and efficiency than a std cassegrain design. The output port in the cassegrain design can instead by used as a circulating path to pull fluid through the system on the back or side of the modules. Of note the cells drawn within can be one or many stacks cells with curved or flat shapes as shown in FIGS. 1-94. This allows for a theoretical maximum efficient absorption of light without the current balancing issues on the back side of the cross pole design. Then on the front of the cross pole a lower magnification is needed to get to maximum efficiency. Thus for the same cost as one cell almost 50-70% more power can be collected per module without taking into account the additional spectrum absorption advantages that a std single junction cassegrain design cannot provide for thermal and current balancing limitation on performance.

Though the invention has been described with respect to a specific preferred embodiment, many variations and modifications will become apparent to those skilled in the art upon reading the present application. The intention is therefore that the appended claims be interpreted as broadly as possible in view of the prior art to include all such variations and modifications.

What is claimed is:

1. A solar cell, comprising:
a first layer comprised of a first material and having a recess;
a second layer compromised of a second material and forming a lens portion over the recess and a cavity there between; and
a fluid or fluid/solid composite in the cavity.

2. The solar cell as specified in claim 1 wherein the first material and the second material form a p-n, n-p, or p-i-n semiconductor junction.

3. The solar cell as specified in claim 2 wherein the fluid is a liquid.

4. The solar cell as specified in claim 3 further comprising particles disposed in the fluid.

5. The solar cell as specified in claim 4 wherein the particles are configured to absorb solar energy transmitted thereto through or reflected off the lens portion.

6. The solar cell as specified in claim 4 wherein the particles are configured to reflect solar energy transmitted thereto through or reflected off the lens portion.

7. The solar cell as specified in claim 4 wherein the particles comprise balls.

8. The solar cell as specified in claim 7 wherein the balls are micro emulsion balls.

9. The solar cell as specified in claim 7 wherein the balls have a coating.

10. The solar cell as specified in claim 7 wherein the balls are configured to absorb solar energy transmitted thereto through the lens portion.

11. The solar cell as specified in claim 9 wherein the balls have a reflective core.

12. The solar cell as specified in claim 9 wherein the balls have an antireflective or absorbing coating.

13. The solar cell as specified in claim 7 wherein the balls have substantially the same diameter.

14. The solar cell as specified in claim 4 wherein the particles are configured to be ionized.

15. The solar cell as specified in claim 4 further comprising a sensor configured under the lens portion and configured to react to received solar energy as a function of the particles.

16. The solar cell as specified in claim 15 wherein the particles are configured to improve the function of the sensor,

17. The solar cell as specified in claim 2 wherein the second layer is also disposed upon a portion of the first layer.

18. The solar cell as specified in claim 2 wherein the lens portion has a coating configured to absorb solar energy.

19. The solar cell as specified in claim 2 wherein the lens portion has a coating configured to reflect solar energy.

20. The solar cell as specified in claim 2 wherein the lens portion has a dichroic layer.

21. The solar cell as specified in claim 2 wherein the cavity has a fluid/solid composite of at least one additional said solar cell beneath or above the solar cell and within the cavity.

22. The solar cell as specified in claim 2 further comprising a light having a dual focus lens system configured to concurrently illuminate a front and a back of the solar cell.

23. The solar cell as specified in claim 2 wherein the lens portion comprises electrode connections for a top and/or a bottom electrode for the cell, the electrode connections configured to prevent light blocking or shadowing of the solar cell.

24. The solar cell in claim 2 further comprising transparent probes adjacent or on top of the lens portion configured to prevent objects from coming in contact or wetting the lens portion.

25. The solar cell in claim 2 further comprising a passive, active or hybrid stage control integrated into the lens portion and configured to optimize energy transfer and collection.
